(19) United States
(12) Patent Application Publication
(10) Pub. No.: US 2024/0395835 A1
(43) Pub. Date: Nov. 28, 2024

(54) SOLID-STATE IMAGING DEVICE AND ELECTRONIC DEVICE

(71) Applicant: SONY SEMICONDUCTOR SOLUTIONS CORPORATION, KANAGAWA (JP)

(72) Inventor: HIRONOBU FUKUI, KANAGAWA (JP)

(21) Appl. No.: 18/261,615

(22) PCT Filed: Jan. 12, 2022
(86) PCT No.: PCT/JP2022/000668

§ 371 Date: Jul. 14, 2023

(30) Foreign Application Priority Data
Jan. 26, 2021 (JP) 2021-010285

(51) Int. Cl. H01L 27/146; H04N 25/77

(52) U.S. Cl. CPC H01L 27/14612; H01L 27/14634; H01L 27/14636; H04N 25/77

(57) ABSTRACT

Photoelectric conversion efficiency is improved. A solid-state imaging device according to an embodiment includes: a first substrate (410) including a photoelectric conversion unit that generates a charge by photoelectrically converting incident light; a second substrate (420) bonded to the first substrate and including at least a part of a pixel circuit that generates a voltage signal based on the charge generated at the photoelectric conversion unit; and first metal wiring (M1) disposed on a side opposite to the first substrate with the second substrate sandwiched between the first substrate and the first metal wiring, in which the pixel circuit includes: a charge accumulation unit (FD) that accumulates a charge generated at the photoelectric conversion unit; an amplification transistor (33) that converts the charge accumulated in the charge accumulation unit into a voltage of a voltage value in accordance with a charge amount of the charge; a reset transistor (32) that releases the charge accumulated in the charge accumulation unit; a first through electrode (112a to 112d) that penetrates the second substrate from the first metal wiring to be connected to the charge accumulation unit; and first wiring (133) that connects a gate electrode of the amplification transistor with the first through electrode.

### FIELD

The present disclosure relates to a solid-state imaging device and an electronic device.

### BACKGROUND

In the field of image sensors, in order to increase an amount of charges that can be accumulated in a photoelectric conversion unit, there has been recently proposed a so-called 3D sequential technology in which the photoelectric conversion unit and at least a part of a pixel circuit for reading out the charges accumulated in the photoelectric conversion unit are disposed on separate substrates, and these substrates are bonded to form one chip.

### CITATION LIST

### Patent Literature

Patent Literature 1: JP 2018-174209 A

### SUMMARY

### Technical Problem

In a 3D sequential structure, however, no wiring is provided between a substrate of the first layer and a substrate of the second layer, and only a through contact is disposed. The through contact connects an element disposed on the substrate of the first layer with an element disposed on the substrate of the second layer. Thus, the wiring density (ratio of wiring area to cell size) of the 3D sequential structure differ little from that of a structure in which a pixel circuit, a photoelectric conversion unit, and a transfer transistor are disposed on a single substrate (hereinafter, also referred to as flat structure). Thus, the conventional 3D sequential structure has a small range of reduction in the parasitic capacitance caused by a decrease in the wiring density, and device characteristics may be deteriorated.

Therefore, the present disclosure proposes a solid-state imaging device and an electronic device capable of inhibiting deterioration in the device characteristics.

### Solution to Problem

To solve the problems described above, a solid-state imaging device according to an embodiment of the present disclosure includes: a first substrate including a photoelectric conversion unit that generates a charge by photoelectrically converting incident light; a second substrate bonded to the first substrate and including at least a part of a pixel circuit that generates a voltage signal based on the charge generated at the photoelectric conversion unit; and first metal wiring disposed on a side opposite to the first substrate with the second substrate sandwiched between the first substrate and the first metal wiring, wherein the pixel circuit includes: a charge accumulation unit that accumulates a charge generated at the photoelectric conversion unit; an amplification transistor that converts the charge accumulated in the charge accumulation unit into a voltage of a voltage value in accordance with a charge amount of the charge; a reset transistor that releases the charge accumulated in the charge accumulation unit; a first through electrode that penetrates the second substrate from the first metal wiring to be connected to the charge accumulation unit; and first wiring that connects a gate electrode of the amplification transistor with the first through electrode.

Moreover, a solid-state imaging device according to an embodiment of the present disclosure includes: a photoelectric conversion unit that generates a charge by photoelectrically converting incident light; and a pixel circuit that generates a voltage signal based on the charge generated at the photoelectric conversion unit, wherein the photoelectric conversion unit is disposed on a first substrate, at least a part of the pixel circuit is disposed on a second substrate bonded to the first substrate, the pixel circuit includes: a charge accumulation unit that accumulates a charge generated at the photoelectric conversion unit; an amplification transistor that converts the charge accumulated in the charge accumulation unit into a voltage of a voltage value in accordance with a charge amount of the charge; and a reset transistor that releases the charge accumulated in the charge accumulation unit, the amplification transistor is disposed on the second substrate, and the second substrate further includes: second metal wiring disposed on a side opposite to the first substrate with the second substrate sandwiched between the first substrate and the second metal wiring; and a shield electrode disposed at at least a part between the second metal wiring and a gate electrode of the amplification transistor.

### BRIEF DESCRIPTION OF DRAWINGS

FIG. 1 is a block diagram depicting a schematic configuration example of an electronic device mounted with a solid-state imaging device according to a first embodiment.

FIG. 2 is a block diagram depicting a schematic configuration example of the solid-state imaging device according to the first embodiment.

FIG. 3 is a circuit diagram depicting a schematic configuration example of a unit pixel according to the first embodiment.

FIG. 4 depicts an example of a stacked structure of the solid-state imaging device according to the first embodiment.

FIG. 5 is a cross-sectional view depicting a cross-sectional structure example of the solid-state imaging device according to the first embodiment.

FIG. 6 is a circuit diagram depicting an FD shared circuit configuration example according to a first example of the first embodiment.

FIG. 7 is a plan view depicting a layout example of a light receiving chip according to the first example of the first embodiment.

FIG. 8 is a plan view depicting a layout example of a circuit chip according to the first example of the first embodiment.

FIG. 9 is a cross-sectional view depicting a structural example of an A-A′ cross section according to the first example of the first embodiment.

FIG. 10 is a cross-sectional view depicting a structural example of a B-B′ cross section according to the first example of the first embodiment.

FIG. 11 is a plan view depicting a layout example of a circuit chip according to a second example of the first embodiment.

FIG. 12 is a cross-sectional view depicting a structural example of an A-A′ cross section according to the second example of the first embodiment.

FIG. 13 is a cross-sectional view depicting a structural example of a B-B′ cross section according to the second example of the first embodiment.

FIG. 14 is a plan view depicting a layout example of a circuit chip according to a third example of the first embodiment.

FIG. 15 is a cross-sectional view depicting a structural example of a B-B′ cross section according to the third example of the first embodiment.

FIG. 16 is a plan view depicting a layout example of a light receiving chip according to a fourth example of the first embodiment.

FIG. 17 is a plan view depicting a layout example of a circuit chip according to the fourth example of the first embodiment.

FIG. 18 is a cross-sectional view depicting a structural example of an A-A′ cross section according to the fourth example of the first embodiment.

FIG. 19 is a cross-sectional view depicting a structural example of a B-B′ cross section according to the fourth example of the first embodiment.

FIG. 20 is a cross-sectional view depicting a structural example of a C-C′ cross section according to the fourth example of the first embodiment.

FIG. 21 is a circuit diagram depicting an FD shared circuit configuration example according to a fifth example of the first embodiment.

FIG. 22 is a plan view depicting a layout example of a light receiving chip according to the fifth example of the first embodiment.

FIG. 23 is a plan view depicting a layout example of a circuit chip according to the fifth example of the first embodiment.

FIG. 24 is a cross-sectional view depicting a structural example of a B-B′ cross section according to the fifth example of the first embodiment.

FIG. 25 is a plan view depicting a layout example of a light receiving chip according to a sixth example of the first embodiment.

FIG. 26 is a plan view depicting a layout example of a circuit chip according to the sixth example of the first embodiment.

FIG. 27 is a cross-sectional view depicting a structural example of an A-A′ cross section according to the sixth example of the first embodiment.

FIG. 28 is a cross-sectional view depicting a structural example of a B-B′ cross section according to the sixth example of the first embodiment.

FIG. 29 is a plan view depicting a layout example of a circuit chip according to a seventh example of the first embodiment.

FIG. 30 is a cross-sectional view depicting a structural example of a B-B′ cross section according to the seventh example of the first embodiment.

FIG. 31 is a cross-sectional view depicting a structural example of a D-D′ cross section according to the seventh example of the first embodiment.

FIG. 32 is a plan view depicting a layout example of a circuit chip according to an eighth example of the first embodiment.

FIG. 33 is a cross-sectional view depicting a structural example of a B-B′ cross section according to the eighth example of the first embodiment.

FIG. 34 is a cross-sectional view depicting a structural example of a D-D′ cross section according to the eighth example of the first embodiment.

FIG. 35 is a plan view depicting a layout example of a light receiving chip according to a ninth example of the first embodiment.

FIG. 36 is a plan view depicting a layout example of a circuit chip according to the ninth example of the first embodiment.

FIG. 37 is a cross-sectional view depicting a structural example of an A-A′ cross section according to the ninth example of the first embodiment.

FIG. 38 is a cross-sectional view depicting a structural example of a C-C′ cross section according to the ninth example of the first embodiment.

FIG. 39 is a cross-sectional view depicting a structural example of a D-D′ cross section according to the ninth example of the first embodiment.

FIG. 40 is a plan view depicting a layout example of a light receiving chip according to a 10th example of the first embodiment.

FIG. 41 is a plan view depicting a layout example of a circuit chip according to the 10th example of the first embodiment.

FIG. 42 is a cross-sectional view depicting a structural example of a B-B′ cross section according to the 10th example of the first embodiment.

FIG. 43 is a cross-sectional view depicting a structural example of a C-C′ cross section according to the 10th example of the first embodiment.

FIG. 44 is a cross-sectional view depicting a structural example of a D-D′ cross section according to the 10th example of the first embodiment.

FIG. 45 is a plan view depicting a layout example of a light receiving chip according to an 11th example of the first embodiment.

FIG. 46 is a plan view depicting a layout example of a circuit chip according to the 11th example of the first embodiment.

FIG. 47 is a cross-sectional view depicting a structural example of a C-C′ cross section according to the 11th example of the first embodiment.

FIG. 48 is a cross-sectional view depicting a cross-sectional structure example of a unit pixel according to a 12th example of the first embodiment.

FIG. 49 is a plan view depicting a layout example of a light receiving chip according to the 12th example of the first embodiment.

FIG. 50 is a plan view depicting a layout example of a circuit chip according to the 12th example of the first embodiment.

FIG. 51 is a cross-sectional view depicting a structural example of a B-B′ cross section according to the 12th example of the first embodiment.

FIG. 52 is a cross-sectional view depicting a cross-sectional structure example of a unit pixel according to a 13th example of the first embodiment.

FIG. 53 is a plan view depicting a layout example of a light receiving chip according to the 13th example of the first embodiment.

FIG. 54 is a plan view depicting a layout example of a circuit chip according to the 13th example of the first embodiment.

FIG. 55 is a cross-sectional view depicting a cross-sectional structure example of a unit pixel according to a 14th example of the first embodiment.

FIG. 56 is a plan view depicting a layout example of a light receiving chip according to the 14th example of the first embodiment.

FIG. 57 is a plan view depicting a layout example of a circuit chip according to the 14th example of the first embodiment.

FIG. 58 is a cross-sectional view depicting a structural example of an E-E′ cross section according to the 14th example of the first embodiment.

FIG. 59 is a cross-sectional view depicting a structural example of an F-F′ cross section according to the 14th example of the first embodiment.

FIG. 60 is a cross-sectional view depicting a structural example of a G-G′ cross section according to the 14th example of the first embodiment.

FIG. 61 is a cross-sectional view depicting a structural example of an H-H′ cross section according to the 14th example of the first embodiment.

FIG. 62 is a cross-sectional view depicting a structural example of an L-L′ cross section according to the 14th example of the first embodiment.

FIG. 63 is a plan view depicting a layout example of a light receiving chip according to a first example of a second embodiment.

FIG. 64 is a plan view depicting a layout example of a circuit chip according to a comparative example.

FIG. 65 is a plan view depicting a layout example of a circuit chip according to the first example of the second embodiment.

FIG. 66 is a partial cross-sectional view depicting a partial structural example of an X-X′ cross section according to the first example of the second embodiment.

FIG. 67 is a partial cross-sectional view depicting a partial structural example of a Y-Y′ cross section according to the first example of the second embodiment.

FIG. 68 is a cross-sectional view depicting a structural example of a Z-Z′ cross section according to the first example of the second embodiment.

FIG. 69 is a plan view depicting a layout example of a circuit chip according to a variation of the first example of the second embodiment.

FIG. 70 is a plan view depicting a layout example of a circuit chip according to a second example of the second embodiment.

FIG. 71 is a cross-sectional view depicting a structural example of a W-W′ cross section according to the second example of the second embodiment.

FIG. 72 is a plan view depicting a layout example of a circuit chip according to a third example of the second embodiment.

FIG. 73 is a cross-sectional view depicting a structural example of an A-A′ cross section according to the third example of the second embodiment.

FIG. 74 is a cross-sectional view depicting a structural example of a B-B′ cross section according to the third example of the second embodiment.

FIG. 75 is a block diagram depicting an example of schematic configuration of a vehicle control system.

FIG. 76 is a diagram of assistance in explaining an example of installation positions of an outside-vehicle information detecting section and an imaging section.

FIG. 77 is a view depicting an example of a schematic configuration of an endoscopic surgery system.

FIG. 78 is a block diagram depicting an example of a functional configuration of a camera head and a camera control unit (CCU).

### DESCRIPTION OF EMBODIMENTS

An embodiment of the present disclosure will be described in detail below with reference to the drawings. Incidentally, in the following embodiments, the same reference signs are attached to the same parts, so that duplicate description will be omitted.

In addition, the present disclosure will be described in accordance with the following item order.
0. Introduction
1. First Embodiment
1.1 Configuration Example of Electronic Device
1.2 Configuration Example of Solid-State Imaging Device
1.3 Configuration Example of Unit Pixel
1.4 Example of Basic Function of Unit Pixel
1.5 Example of Stacked Structure of Solid-State Imaging Device
1.6 Cross-Sectional Structure Example of Unit Pixel
1.7 Examples of Chip Layout and Cross-Sectional Structure
1.7.1 First Example
1.7.2 Second Example
1.7.3 Third Example
1.7.4 Fourth Example
1.7.5 Fifth Example
1.7.6 Sixth Example
1.7.7 Seventh Example
1.7.8 Eighth Example
1.7.9 Ninth Example
1.7.10 10th Example
1.7.11 11th Example
1.7.12 12th Example
1.7.13 13th Example
1.7.14 14th Example
1.8 Conclusion
2. Second Embodiment
2.1 Examples of Chip Layout and Cross-Sectional Structure
2.1.1 First Example
2.1.2 Second Example
2.1.3 Third Example
2.2 Conclusion
3. Example of Application to Mobile Body
4. Example of Application to Endoscopic Surgery System

### 0. Introduction

As described above, in order to increase an amount of charges that can be accumulated in a photoelectric conversion unit, there has been recently proposed 3D sequential technology in which the photoelectric conversion unit, a transfer transistor, and at least one of an amplification transistor, a selection transistor, and a reset transistor constituting a pixel circuit that outputs a signal (hereinafter, referred to as pixel signal) based on a charge extracted from the photoelectric conversion unit are disposed on separate substrates, and these substrates are bonded to form one chip.

A conventional 3D sequential structure, however, has a smaller range of reduction in wiring density than a flat structure in which the photoelectric conversion unit, the transfer transistor, the reset transistor, the amplification transistor, and the selection transistor are disposed on a single substrate.

Here, the wiring capacitance of the wiring formed on a substrate depends on the wiring density. Therefore, as the wiring density decreases, parasitic capacitance caused by the wiring decreases. Thus, reduction in the parasitic capacitance due to speeding-up of circuit operation and an increase in conversion efficiency is important to improve device characteristics. Since the conventional 3D sequential structure has a small range of reduction in the parasitic capacitance caused by a decrease in the wiring density, the device characteristics may be deteriorated.

Therefore, in the following embodiments, a solid-state imaging device and an electronic device capable of inhibiting deterioration in device characteristics will be described with an example.

In addition, in general, a decrease in the wiring density decreases the degree of difficulty in designing a wiring layout. Thus, the conventional 3D sequential structure has a problem of a risk of an increase in the degree of difficulty in designing the wiring layout caused by an increase in the wiring density.

Therefore, in the following embodiments, a configuration capable of inhibiting an increase in the degree of difficulty in design will also be described.

### 1. First Embodiment

First, a first embodiment of the present disclosure will be described in detail with reference to the drawings.

Incidentally, although, in the present embodiment, a case where technology according to the present embodiment is applied to a complementary metal-oxide-semiconductor (CMOS) type solid-state imaging device (hereinafter, also referred to as image sensor) will be described, this is not a limitation. For example, the technology according to the present embodiment can be applied to various sensors including a photoelectric conversion element, such as a charge coupled device (CCD) type solid-state imaging device, a time of flight (ToF) sensor, and an event-based vision sensor (EVS).

### 1.1 Configuration Example of Electronic Device

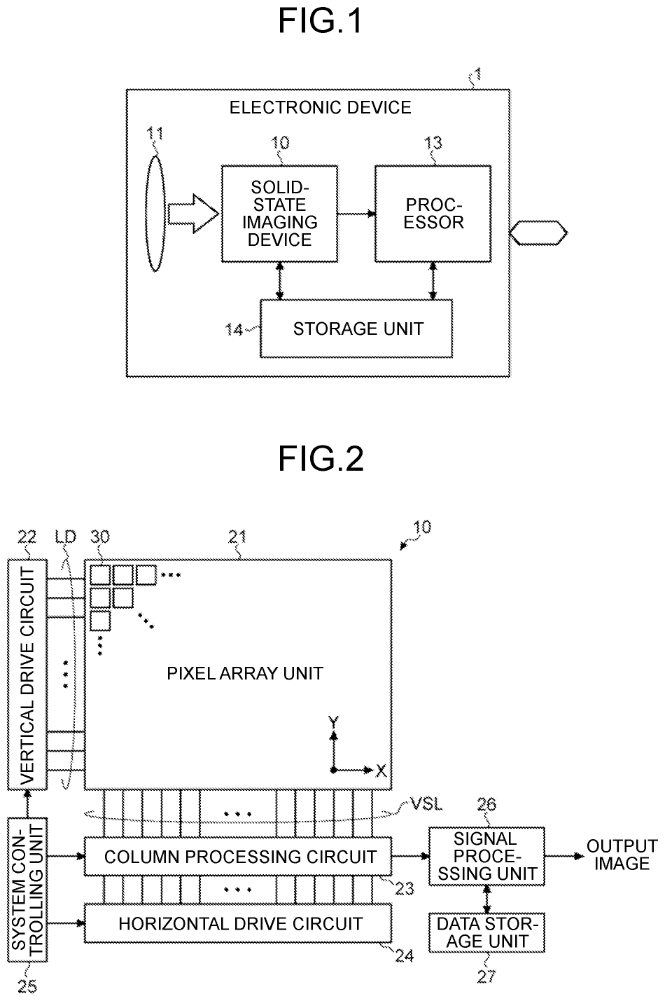

FIG. 1 is a block diagram depicting a schematic configuration example of an electronic device mounted with a solid-state imaging device according to the first embodiment. As depicted in FIG. 1, an electronic device 1 includes, for example, an imaging lens 11, a solid-state imaging device 10, a storage unit 14, and a processor 13.

The imaging lens 11 is an example of an optical system that collects incident light and forms an image thereof on a light receiving surface of the solid-state imaging device 10. The light receiving surface may be a surface on which photoelectric conversion elements of the solid-state imaging device 10 are arranged. The solid-state imaging device 10 photoelectrically converts the incident light to generate image data. In addition, the solid-state imaging device 10 executes predetermined signal processing such as noise removal and white balance adjustment on the generated image data.

The storage unit 14 includes, for example, a flash memory, a dynamic random access memory (DRAM), and a static random access memory (SRAM), and records image data and the like input from the solid-state imaging device 10.

The processor 13 includes, for example, a central processing unit (CPU), and may include an operating system, an application processor that executes various kinds of application software and the like, a graphics processing unit (GPU), and a baseband processor. The processor 13 executes various pieces of processing as necessary on image data input from the solid-state imaging device 10, image data read from the storage unit 14, and the like, displays these pieces of image data to a user, and transmits these pieces of image data to the outside via a predetermined network.

### 1.2 Configuration Example of Solid-State Imaging Device

FIG. 2 is a block diagram depicting a schematic configuration example of a CMOS type solid-state imaging device according to the first embodiment. Here, the CMOS type solid-state imaging device is an image sensor created by applying or partially using a CMOS process. For example, the solid-state imaging device 10 according to the present embodiment includes a back-irradiated type image sensor.

The solid-state imaging device 10 according to the present embodiment has, for example, a stack structure (for example, see FIG. 4) in which a first semiconductor chip 410 (substrate) and a second semiconductor chip 420 (substrate) are stacked. A pixel array unit 21 is disposed on the first semiconductor chip 410. A peripheral circuit is disposed on the second semiconductor chip 420. The peripheral circuit may include, for example, a vertical drive circuit 22, a column processing circuit 23, a horizontal drive circuit 24, and a system controlling unit 25.

The solid-state imaging device 10 further includes a signal processing unit 26 and a data storage unit 27. The signal processing unit 26 and the data storage unit 27 may be provided on the same semiconductor chip as the peripheral circuit is provided on, or may be provided on another semiconductor chip.

The pixel array unit 21 has a configuration in which unit pixels (hereinafter, which may be simply referred to as “pixels”) 30 are disposed in a row direction and a column direction, that is, in a two-dimensional lattice shape in a matrix. The unit pixels 30 includes photoelectric conversion elements that generate and accumulate charges in accordance with an amount of received light. Here, the row direction refers to a direction of arrangement of pixels in a pixel row (horizontal direction in figure). The column direction refers to a direction of arrangement of pixels in a pixel column (vertical direction in figure). A specific circuit configuration of a unit pixel and details of a pixel structure will be described later.

In the pixel array unit 21, for the pixel arrangement in a matrix, pixel drive lines LD are disposed along the row direction for respective pixel rows, and vertical signal lines VSL are disposed along the column direction for respective pixel columns. A pixel drive line LD transmits a drive signal for performing driving at the time of reading a signal from a pixel. Although FIG. 2 depicts the pixel drive line LD as one piece of separate wiring, the pixel drive line LD is not limited to the one piece of separate wiring. One end of the pixel drive line LD is connected to an output end for each row of the vertical drive circuit 22.

The vertical drive circuit 22 includes a shift register and an address decoder, and drives pixels of the pixel array unit 21 at the same time for all pixels or in units of rows. That is, the vertical drive circuit 22 includes a driving unit that controls the operation of each pixel of the pixel array unit 21 together with the system controlling unit 25 that controls the vertical drive circuit 22. Although depiction of a specific configuration of the vertical drive circuit 22 is omitted, the vertical drive circuit 22 generally includes two scanning systems of a readout scanning system and a sweep-out scanning system.

The readout scanning system sequentially scans unit pixels of the pixel array unit 21 selectively in units of rows in order to read out signals from the unit pixels. The signals read out from the unit pixels are analog signals. The sweep-out scanning system performs sweep-out scanning on a readout row on which readout scanning is to be performed by the readout scanning system prior to the readout scanning by an exposure time.

Unnecessary charges are swept out from a photoelectric conversion element of a unit pixel in the readout row by sweep-out scanning of the sweep-out scanning system, which resets the photoelectric conversion element. Then, so-called electronic shutter operation is performed by sweeping out (resetting) unnecessary charges with the sweep-out scanning system. Here, the electronic shutter operation refers to an operation of discarding charges of a photoelectric conversion element and newly starting exposure (starting accumulation of charges).

A signal read out by a readout operation of the readout scanning system corresponds to an amount of light received after an immediately preceding readout operation or electronic shutter operation. Then, a period from readout timing of the immediately preceding readout operation or sweep-out timing of the electronic shutter operation to readout timing of the readout operation of this time corresponds to a charge accumulation period (also referred to as exposure period) in a unit pixel.

A signal output from each unit pixel of a pixel row selectively scanned by the vertical drive circuit 22 is input to the column processing circuit 23 through each of the vertical signal lines VSL for each pixel column. The column processing circuit 23 performs predetermined signal processing on a signal output from each pixel of a selected row through a vertical signal line VSL for each pixel column of the pixel array unit 21, and temporarily holds the pixel signal after the signal processing.

Specifically, the column processing circuit 23 performs at least noise removal processing, for example, correlated double sampling (CDS) processing and double data sampling (DDS) processing, as the signal processing. For example, fixed pattern noise unique to a pixel, such as reset noise and threshold variation of an amplification transistor in a pixel is removed by the CDS processing. The column processing circuit 23 also has, for example, an analog-digital (AD) conversion function. The column processing circuit 23 converts an analog pixel signal read out from the photoelectric conversion element into a digital signal, and outputs the digital signal.

The horizontal drive circuit 24 includes a shift register and an address decoder, and sequentially selects readout circuits (hereinafter, referred to as pixel circuits) for pixel columns of the column processing circuit 23. Pixel signals subjected to signal processing for each pixel circuit in the column processing circuit 23 are sequentially output by the selective scanning of the horizontal drive circuit 24.

The system controlling unit 25 includes a timing generator that generates various timing signals, and performs drive control for the vertical drive circuit 22, the column processing circuit 23, the horizontal drive circuit 24, and the like on the basis of various kinds of timings generated by the timing generator.

The signal processing unit 26 has at least an arithmetic processing function, and performs various kinds of signal processing, such as arithmetic processing, on a pixel signal output from the column processing circuit 23. The data storage unit 27 temporarily stores data necessary for signal processing in the signal processing unit 26.

Incidentally, for example, predetermined processing may be executed on image data output from the signal processing unit 26 in the processor 13 and the like of the electronic device 1 mounted with the solid-state imaging device 10. The image data may be transmitted to the outside via a predetermined network.

### 1.3 Configuration Example of Unit Pixel

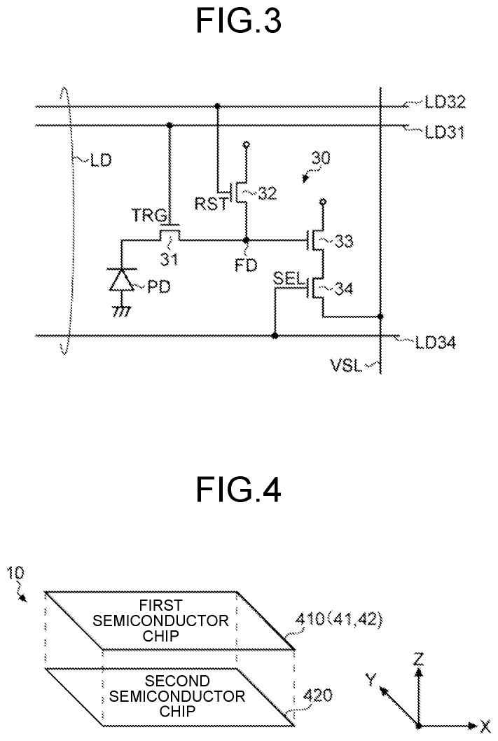

FIG. 3 is a circuit diagram depicting a schematic configuration example of a unit pixel according to the present embodiment. As depicted in FIG. 3, a unit pixel 30 includes a photoelectric conversion unit PD, a transfer transistor 31, a reset transistor 32, an amplification transistor 33, a selection transistor 34, and a floating diffusion region FD.

A selection transistor drive line LD34 included in the pixel drive line LD is connected to a gate of the selection transistor 34. A reset transistor drive line LD32 included in the pixel drive line LD is connected to a gate of the reset transistor 32. A transfer transistor drive line LD31 included in the pixel drive line LD is connected to a gate of the transfer transistor 31. In addition, the vertical signal line VSL is connected to a source of the amplification transistor 33 via the selection transistor 34. One end of the vertical signal line VSL is connected to the column processing circuit 23.

In the following description, the reset transistor 32, the amplification transistor 33, and the selection transistor 34 are also collectively referred to as a pixel circuit. The pixel circuit may include the floating diffusion region FD and/or the transfer transistor 31.

The photoelectric conversion unit PD photoelectrically converts incident light. The transfer transistor 31 transfers charges generated in the photoelectric conversion unit PD. The floating diffusion region FD functions as a charge accumulation unit that accumulates the charges transferred by the transfer transistor 31. The amplification transistor 33 causes a pixel signal having a voltage value corresponding to the charges accumulated in the floating diffusion region FD to appear in the vertical signal line VSL. The reset transistor 32 releases the charges accumulated in the floating diffusion region FD. The selection transistor 34 selects the unit pixel 30 to be read out.

An anode of the photoelectric conversion unit PD is grounded, and a cathode thereof is connected to a source of the transfer transistor 31. A drain of the transfer transistor 31 is connected to a source of the reset transistor 32 and a gate of the amplification transistor 33. A node, which is a connection point thereof, constitutes the floating diffusion region FD. Incidentally, a drain of the reset transistor 32 is connected to a vertical reset input line (not depicted).

A drain of the amplification transistor 33 is connected to a vertical voltage supply line (not depicted). The source of the amplification transistor 33 is connected to a drain of the selection transistor 34. A source of the selection transistor 34 is connected to the vertical signal line VSL.

The potential of the floating diffusion region FD is determined by the charges accumulated therein and the capacitance of the floating diffusion region FD. The capacitance of the floating diffusion region FD is determined by the diffusion layer capacitance of the drain of the transfer transistor 31, the diffusion layer capacitance of the source of the reset transistor 32, and the capacitance of the gate of the amplification transistor 33 in addition to the capacitance to the ground.

### 1.4 Example of Basic Function of Unit Pixel

Next, a basic function of the unit pixel 30 will be described with reference to FIG. 3. The reset transistor 32 controls discharge (reset) of charges accumulated in the floating diffusion region FD in accordance with a reset signal RST supplied from the vertical drive circuit 22 via the reset transistor drive line LD32. Incidentally, charges accumulated in the photoelectric conversion unit PD can be discharged (reset) in addition to the charges accumulated in the floating diffusion region FD by turning on the transfer transistor 31 at the time when the reset transistor 32 is on.

When a high-level reset signal RST is input to the gate of the reset transistor 32, the potential of the floating diffusion region FD is clamped to a voltage applied through the vertical reset input line. This causes the charges accumulated in the floating diffusion region FD to be discharged (reset).

In addition, when a low-level reset signal RST is input to the gate of the reset transistor 32, the floating diffusion region FD is electrically disconnected from the vertical reset input line, and comes in a floating state.

The photoelectric conversion unit PD photoelectrically converts incident light, and generates charges in accordance with an amount of the light. The generated charges are accumulated on a cathode side of the photoelectric conversion unit PD. The transfer transistor 31 controls transfer of charges from the photoelectric conversion unit PD to the floating diffusion region FD in accordance with a transfer control signal TRG supplied from the vertical drive circuit 22 via the transfer transistor drive line LD31.

For example, when a high-level transfer control signal TRG is input to the gate of the transfer transistor 31, the charges accumulated in the photoelectric conversion unit PD is transferred to the floating diffusion region FD. In contrast, a low-level transfer control signal TRG is supplied to the gate of the transfer transistor 31, the transfer of charges from the photoelectric conversion unit PD is stopped.

As described above, the potential of the floating diffusion region FD at the time when the reset transistor 32 is off is determined by an amount of charges transferred from the photoelectric conversion unit PD via the transfer transistor 31 and the capacitance of the floating diffusion region FD.

The amplification transistor 33 functions as an amplifier using potential fluctuation of the floating diffusion region FD connected to the gate thereof as an input signal. An output voltage signal thereof appears as a pixel signal in the vertical signal line VSL via the selection transistor 34.

The selection transistor 34 controls the appearance of a pixel signal to the vertical signal line VSL caused by the amplification transistor 33 in accordance with a selection control signal SEL supplied from the vertical drive circuit 22 via the selection transistor drive line LD34. For example, when a high-level selection control signal SEL is input to the gate of the selection transistor 34, a pixel signal from the amplification transistor 33 appears in the vertical signal line VSL. In contrast, when a low-level selection control signal SEL is input to the gate of the selection transistor 34, the appearance of a pixel signal to the vertical signal line VSL is stopped. This enables extraction of only output of a selected unit pixel 30 in the vertical signal line VSL to which a plurality of unit pixels 30 is connected.

### 1.5 Example of Stacked Structure of Solid-State Imaging Device

FIG. 4 depicts an example of a stacked structure of an image sensor according to the present embodiment. As depicted in FIG. 4, the solid-state imaging device 10 has a structure in which the first semiconductor chip 410 and the second semiconductor chip 420 are vertically stacked. The first semiconductor chip 410 has a structure in which a light receiving chip 41 and a circuit chip 42 are stacked. The light receiving chip 41 is, for example, a semiconductor chip including the pixel array unit 21 in which photoelectric conversion units PD are arranged. The circuit chip 42 is, for example, a semiconductor chip in which pixel circuits are arranged.

The first semiconductor chip 410 and the second semiconductor chip 420 can be bonded by, for example, so-called direct bonding in which bonding surfaces thereof are flattened and bonded by interelectronic force. Note, however, that this is not a limitation. For example, so-called Cu—Cu bonding and bump bonding can be adopted. In the Cu—Cu bonding, electrode pads made of copper (Cu) formed on bonding surfaces are bonded.

In addition, the first semiconductor chip 410 and the second semiconductor chip 420 are electrically connected via, for example, a connection portion such as a through-silicon via (TSV) which is a through contact penetrating a semiconductor substrate. For example, a so-called twin TSV method and a so-called shared TSV method can be adopted for connection using the TSV. In the twin TSV method, two TSVs of a TSV provided on the first semiconductor chip 410 and a TSV provided from the first semiconductor chip 410 to the second semiconductor chip 420 are connected on the outer surface of the chip. In the shared TSV method, the first semiconductor chip 410 and the second semiconductor chip 420 are connected by a TSV penetrating from the first semiconductor chip 410 to the second semiconductor chip 420.

Note, however, that, when the first semiconductor chip 410 and the second semiconductor chip 420 are bonded by the Cu—Cu bonding and the bump bonding, both are electrically connected via a Cu—Cu bonding portion and a bump bonding portion.

### 1.6 Cross-Sectional Structure Example of Unit Pixel

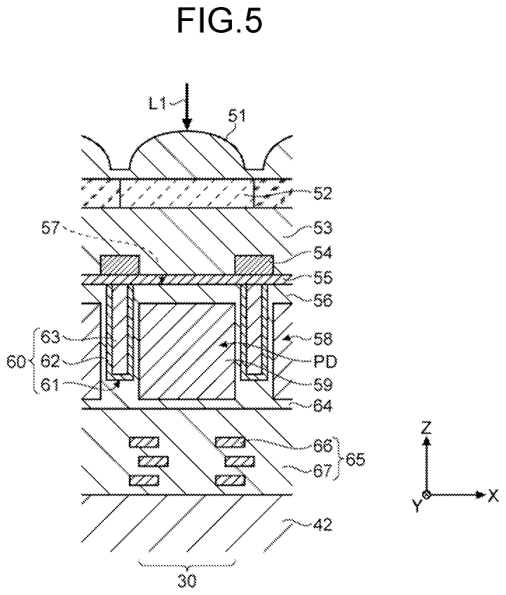

Next, a cross-sectional structure example of the solid-state imaging device 10 according to the first embodiment will be described with reference to FIG. 5. FIG. 5 is a cross-sectional view depicting a cross-sectional structure example of the unit pixel according to the first embodiment. Incidentally, FIG. 5 depicts a cross-sectional structure example of the light receiving chip 41 in which the photoelectric conversion unit PD of the unit pixel 30 is disposed.

As depicted in FIG. 5, in the solid-state imaging device 10, the photoelectric conversion unit PD receives incident light L1 incident from the back surface (upper surface in figure) side of a semiconductor substrate 58. A flattened film 53, a color filter 52, and an on-chip lens 51 are provided above the photoelectric conversion unit PD. The incident light L1 incident from a light receiving surface 57 into the semiconductor substrate 58 sequentially passes through respective components to be subjected to photoelectric conversion.

For example, in the photoelectric conversion unit PD, an N-type semiconductor region 59 is formed as a charge accumulation region that accumulates charges (electrons). In the photoelectric conversion unit PD, the N-type semiconductor region 59 is provided in a region surrounded by P-type semiconductor regions 56 and 64 of the semiconductor substrate 58. The P-type semiconductor region 64 having a higher impurity concentration is provided on the front surface (lower surface) side of the semiconductor substrate 58 of the N-type semiconductor region 59 than on the back surface (upper surface) side. That is, the photoelectric conversion unit PD has a hole-accumulation diode (HAD) structure. The P-type semiconductor regions 56 and 64 are provided on respective interfaces on the upper surface side and the lower surface side of the N-type semiconductor region 59 so as to inhibit generation of dark current.

Pixel isolation portions 60 are provided inside the semiconductor substrate 58. The pixel isolation portions 60 electrically isolate a plurality of unit pixels 30 from each other. The photoelectric conversion unit PD is provided in a region partitioned by the pixel isolation portions 60. In the figure, when the solid-state imaging device 10 is viewed from the upper surface side, the pixel isolation portions 60 are provided in, for example, a lattice shape so as to be interposed between the plurality of unit pixels 30. The photoelectric conversion unit PD is disposed in a region partitioned by the pixel isolation portion 60.

An anode of each photoelectric conversion unit PD is grounded. In the solid-state imaging device 10, signal charges (for example, electrons) accumulated by the photoelectric conversion unit PD are read out via the transfer transistor 31 (not depicted) (see, FIG. 3), and output to the vertical signal line VSL (not depicted) (see, FIG. 3) as electric signals.

A wiring layer 65 is provided on a front surface (lower surface) of the semiconductor substrate 58 opposite to a back surface (upper surface) on which respective components such as a light shielding film 54, the flattened film 53, the color filter 52, and the on-chip lens 51 are provided.

The wiring layer 65 includes wiring 66, an insulating layer 67, and a through electrode (not depicted). An electric signal from the light receiving chip 41 is transmitted to the circuit chip 42 via the wiring 66 and the through electrode (not depicted). Similarly, the substrate potential of the light receiving chip 41 is also applied from the second semiconductor chip 420 via the wiring 66 and the through electrode (not depicted).

For example, the circuit chip 42 depicted in FIG. 4 is bonded on the surface of the wiring layer 65 opposite to the side on which the photoelectric conversion unit PD is provided.

The light shielding film 54 is provided on the back surface (upper surface in figure) side of the semiconductor substrate 58, and blocks a part of the incident light L1 passing from above the semiconductor substrate 58 toward the back surface of the semiconductor substrate 58.

The light shielding film 54 is provided above the pixel isolation portion 60 provided inside the semiconductor substrate 58. Here, the light shielding film 54 is provided so as to protrude in a protrusion shape on the back surface (upper surface) of the semiconductor substrate 58 via an insulating film 55 such as a silicon oxide film. In contrast, the light shielding film 54 is not provided above the photoelectric conversion unit PD provided inside the semiconductor substrate 58, and the upper side is opened so that the incident light L1 is incident on the photoelectric conversion unit PD.

That is, in the figure, when the solid-state imaging device 10 is viewed from the upper surface side, the light shielding film 54 has a plane shape in a lattice, and an opening through which the incident light L1 passes to a light receiving surface 57 is formed.

The light shielding film 54 is formed of a light shielding material that blocks light. For example, the light shielding film 54 is formed by sequentially stacking a titanium (Ti) film and a tungsten (W) film. Alternatively, the light shielding film 54 can be formed by sequentially stacking, for example, a titanium nitride (TiN) film and a tungsten (W) film.

The light shielding film 54 is covered with the flattened film 53. The flattened film 53 is formed of an insulating material that transmits light. For example, silicon oxide (SiO₂) can be used as the insulating material.

The pixel isolation portion 60 includes, for example, a groove portion 61, a fixed charge film 62, and an insulating film 63, and is provided on the back surface (upper surface) side of the semiconductor substrate 58 so as to cover the groove portion 61 partitioning the plurality of unit pixels 30 from each other.

Specifically, the fixed charge film 62 is provided on the semiconductor substrate 58 so as to cover the inner surface of the groove portion 61 formed on the back surface (upper surface) side with a constant thickness. Then, the insulating film 63 is provided so as to be embedded inside the groove portion 61 covered with the fixed charge film 62 (so as to fill inside of groove portion 61).

Here, the fixed charge film 62 is formed of a high dielectric having a negative fixed charge so that a positive charge (hole) accumulation region is formed at an interface portion with the semiconductor substrate 58 and generation of dark current is inhibited. The negative fixed charge of the fixed charge film 62 causes an electric field to be applied to the interface with the semiconductor substrate 58, and the positive charge (hole) accumulation region is formed.

The fixed charge film 62 can be formed of, for example, a hafnium oxide film (HfO₂ film). In addition, the fixed charge film 62 can contain at least one of oxides, such as hafnium, zirconium, aluminum, tantalum, titanium, magnesium, yttrium, and lanthanoids.

Incidentally, the pixel isolation portion 60 is not limited to the above-described configuration, and can be variously modified. For example, the pixel isolation portion 60 can be used as a light reflection structure by using a reflective film that reflects light, such as a tungsten (W) film, instead of the insulating film 63. This enables the incident light L1 entering the photoelectric conversion unit PD to be reflected by the pixel isolation portion 60, so that the optical path length of the incident light L1 in the photoelectric conversion unit PD can be increased. In addition, since the pixel isolation portion 60 having the light reflection structure can reduce leakage of light to adjacent pixels, image quality, distance measurement accuracy, and the like can be further improved. Incidentally, when a metal material such as tungsten (W) is used as a material for the reflective film, an insulating film such as a silicon oxide film can be provided in the groove portion 61 instead of the fixed charge film 62.

In addition, the configuration in which the pixel isolation portion 60 is used as the light reflection structure is not limited to a configuration using a reflective film. For example, the configuration can be implemented by embedding a material having a higher or lower refractive index than the semiconductor substrate 58 in the groove portion 61.

Furthermore, although FIG. 5 depicts the pixel isolation portion 60 having a so-called reverse deep trench isolation (RDTI) structure in which the pixel isolation portion 60 is provided in the groove portion 61 formed from the back surface (upper surface) side of the semiconductor substrate 58, this is not a limitation. The pixel isolation portion 60 having various structures such as a so-called deep trench isolation (DTI) structure and a so-called full trench isolation (FTI) structure can be adopted. In the DTI structure, the pixel isolation portion 60 is provided in the groove portion formed from the front surface (lower surface) side of the semiconductor substrate 58. In the FTI structure, the pixel isolation portion 60 is provided in the groove portion formed so as to penetrate the front and back surfaces of the semiconductor substrate 58.

### 1.7 Examples of Chip Layout and Cross-Sectional Structure

Next, chip layouts of the light receiving chip 41 and the circuit chip 42 according to the present embodiment and a cross-sectional structure of a stacked chip obtained by bonding the light receiving chip 41 and the circuit chip 42 will be described in some examples. Incidentally, in the following description, for the sake of simplicity, depiction of the photoelectric conversion unit PD formed on the semiconductor substrate 58 (corresponding to semiconductor substrate 101 to be described later) and the pixel isolation portion 60 (see FIG. 5) that partitions the photoelectric conversion unit PD is appropriately omitted. In addition, in the following description, detailed description of a configuration similar to that in the previously described example will be omitted in the following example.

### 1.7.1 First Example

In a first example, a case where four unit pixels 30 arranged in two rows and two columns share one floating diffusion region FD will be described.

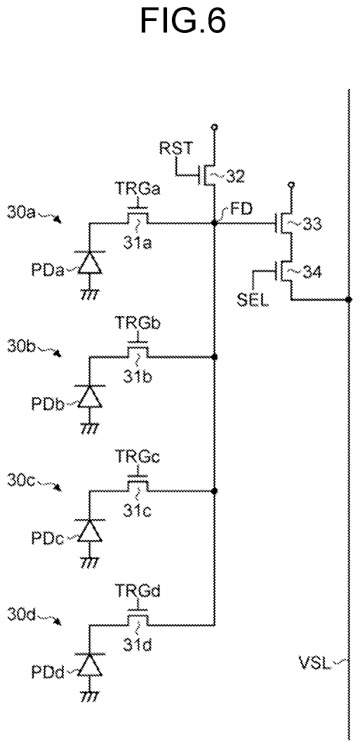

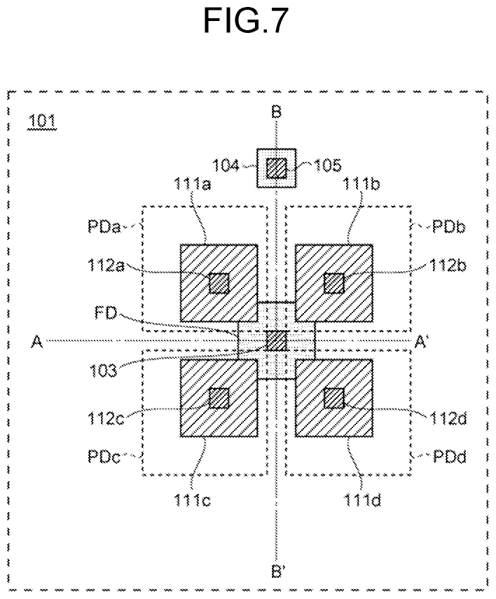

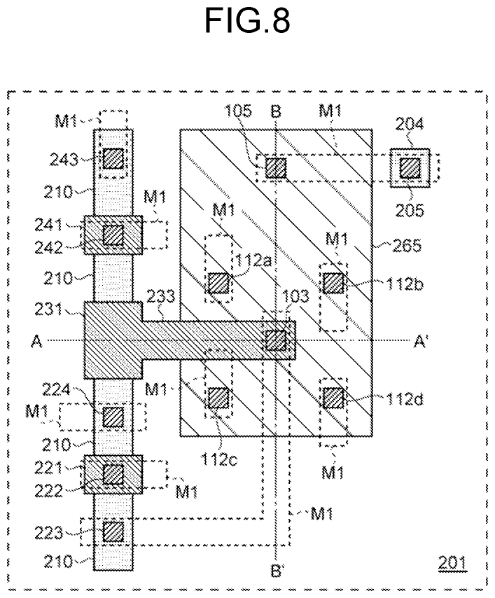

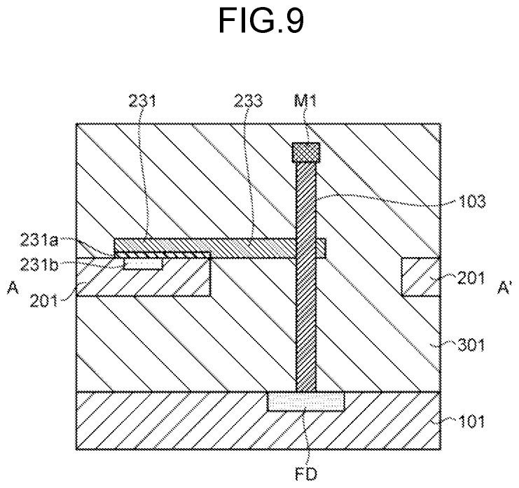

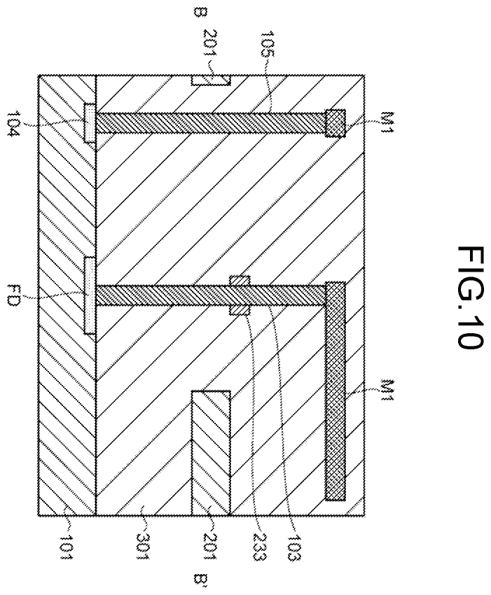

FIG. 6 is a circuit diagram depicting an FD shared circuit configuration example according to the first example. FIG. 7 is a plan view depicting a layout example of a light receiving chip according to the first example. FIG. 8 is a plan view depicting a layout example of a circuit chip according to the first example. FIG. 9 is a cross-sectional view depicting a structural example of an A-A′ cross section according to the first example. FIG. 10 is a cross-sectional view depicting a structural example of a B-B′ cross section according to the first example.

### (FD Shared Configuration)

As depicted in FIG. 6, in an FD shared configuration in which four unit pixels 30a to 30d share one floating diffusion region FD, four photoelectric conversion units PDa to PDd are connected to a common floating diffusion region FD via transfer transistors 31a to 31d, respectively. The four unit pixels 30a to 30d share configurations following the floating diffusion region FD. Therefore, in the present example, the four unit pixels 30a to 30d share the reset transistor 32, the amplification transistor 33, and the selection transistor 34.

### (Layout Example and Cross-Sectional Structure Example of Light Receiving Chip)

In the first example, the photoelectric conversion units PDa to PDd and the transfer transistors 31a to 31d are disposed on the light receiving chip 41. As depicted in FIG. 7, transfer gate electrodes 111a to 111d of the transfer transistors 31a to 31d are disposed in two rows and two columns on an element formation surface (hereinafter, also referred to as front surface) of the semiconductor substrate 101 of the light receiving chip 41. The photoelectric conversion units PDa to PDd are disposed on a light receiving surface (hereinafter, also referred to as back surface) side of the semiconductor substrate 101 so as to overlap the respective transfer gate electrodes 111a to 111d in a substrate thickness direction. Incidentally, the semiconductor substrate 101 can correspond to, for example, the semiconductor substrate 58 in the cross-sectional structure depicted in FIG. 5.

Through electrodes 112a to 112d are connected to the respective transfer gate electrodes 111a to 111d. The through electrodes 112a to 112d penetrate the circuit chip 42, and reach first metal wiring M1 on the circuit chip 42. The through electrodes 112a to 112d are parts of the transfer transistor drive line LD31.

The floating diffusion region FD is disposed at the center of the transfer gate electrodes 111a to 111d arranged in two rows and two columns. A through electrode 103 is connected to the floating diffusion region FD. The through electrode 103 penetrates the circuit chip 42, and reaches the first metal wiring M1 on the circuit chip 42. Incidentally, the floating diffusion region FD is connected to the source of the reset transistor 32 and the gate of the amplification transistor 33 via the through electrode 103 and the first metal wiring M1.

The through electrodes 112a to 112d and 103 penetrate, for example, an interlayer insulating film between the light receiving chip 41 and the circuit chip 42 and an insulating film region 265 (hereinafter, the interlayer insulating film and the insulating film region 265 are collectively referred to as an insulating layer 301) penetrating the circuit chip 42, thereby being connected to the first metal wiring M1 in an upper layer of the circuit chip 42.

In addition, as depicted in FIGS. 7, 8, and 10, a through electrode 105 is connected to a contact portion 104 formed on the element formation surface of the semiconductor substrate 101. That is, the well potential of the semiconductor substrate 101 is controlled via the through electrode 105 that penetrates the circuit chip 42 and reaches the first metal wiring M1 on the circuit chip 42. Incidentally, the contact portion 104 may be, for example, a P+ type diffusion region.

### (Layout Example and Cross-Sectional Structure Example of Circuit Chip)

In the first example, the reset transistor 32, the amplification transistor 33, and the selection transistor 34 are disposed on the circuit chip 42.

In FIGS. 8, 9, and 10, the reset transistor 32 includes a reset gate electrode 221, a gate insulating film, and a channel formation region (not depicted). The amplification transistor 33 includes an amplification gate electrode 231, a gate insulating film 231a, and a channel formation region 231b. The selection transistor 34 includes a selection gate electrode 241, a gate insulating film, and a channel formation region (not depicted). The reset gate electrode 221 is connected to the first metal wiring M1 via a contact plug 222, which is a part of the reset transistor drive line LD32. The selection gate electrode 241 is connected to the first metal wiring M1 via a contact plug 242, which is a part of the selection transistor drive line LD34. In addition, diffusion regions 210 disposed so as to sandwich each gate electrode are, for example, N+ type diffusion regions, and function as a source and a drain of each of the reset transistor 32, the amplification transistor 33, and the selection transistor 34.

A diffusion region 210 functioning as the drain of the reset transistor 32 and the drain of the amplification transistor is connected to a reset voltage line of the first metal wiring M1 via a contact plug 224. The reset voltage line is a voltage line that supplies a reset potential for resetting the floating diffusion region FD, and may be, for example, a power supply line that supplies a power supply voltage VDD.

A diffusion region 210 functioning as the source of the reset transistor 32 is connected to the first metal wiring M1 via a contact plug 223. The first metal wiring M1 is connected to the through electrode 103. The through electrode 103 is connected to the floating diffusion region FD. The amplification gate electrode 231 includes an extending portion 233 extending in a direction of the floating diffusion region FD along an element formation surface of a semiconductor substrate 201, and is short-circuited to the through electrode 103 connected to the floating diffusion region FD via the extending portion 233. This causes the gate of the amplification transistor 33, the source of the reset transistor 32, and the floating diffusion region FD to be electrically connected.

The source of the amplification transistor 33 and the drain of the selection transistor 34 share the same diffusion region 210. The diffusion region 210 functioning as the source of the selection transistor 34 is connected to the first metal wiring M1 via a contact plug 243, which is a part of the vertical signal line VSL.

In addition, in the first example, a contact plug 205 is connected to a contact portion 204 formed on the element formation surface of the semiconductor substrate 201. That is, the well potential of the semiconductor substrate 201 is controlled via the contact plug 205 that reaches the first metal wiring M1. Incidentally, similarly to the contact portion 104, the contact portion 204 may be, for example, a P+ type diffusion region.

### (Conclusion of First Example)

As described above, the amplification gate electrode 231 extends in a direction of the floating diffusion region FD, and is short-circuited to the through electrode 103, which eliminates the need for additional wiring. The number of necessary electrodes can be reduced as compared to that in the conventional 3D sequential structure (in the conventional 3D sequential structure, a total of two electrodes, one for the amplification gate electrode and the other for the floating diffusion region, are necessary). Incidentally, in the present disclosure, the number of electrodes may be, for example, the number of through electrodes and/or the number of contact plugs. This can reduce the wiring density of the circuit chip 42, and can thus decrease a parasitic capacitance caused by the wiring. As a result, the device characteristics can be improved.

In addition, the wiring density of the dense circuit chip 42 is reduced by reducing the number of necessary electrodes, which can decrease the degree of difficulty in designing the wiring layout of the circuit chip 42.

### 1.7.2 Second Example

In a second example, similarly to the first example, a case where four unit pixels 30 arranged in two rows and two columns share one floating diffusion region FD will be described. Incidentally, since an FD shared circuit configuration example and a layout example of the light receiving chip 41 may be similar to the configuration described with reference to FIGS. 6 and 7 in the first example, detailed description thereof will be omitted here.

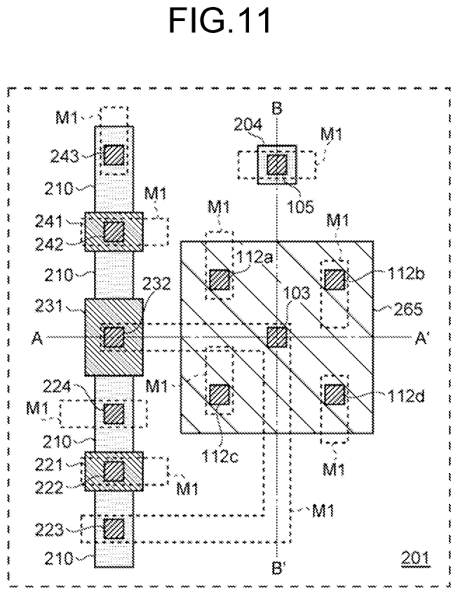

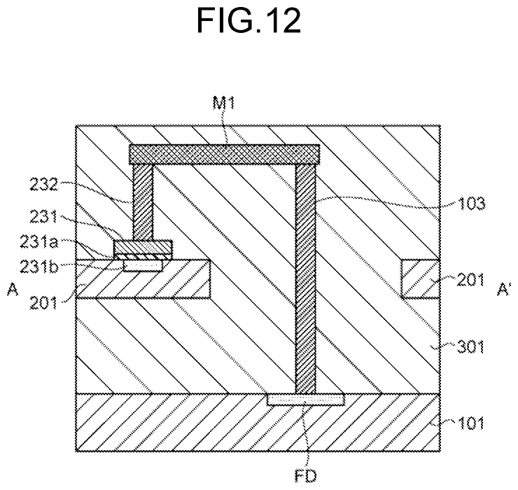

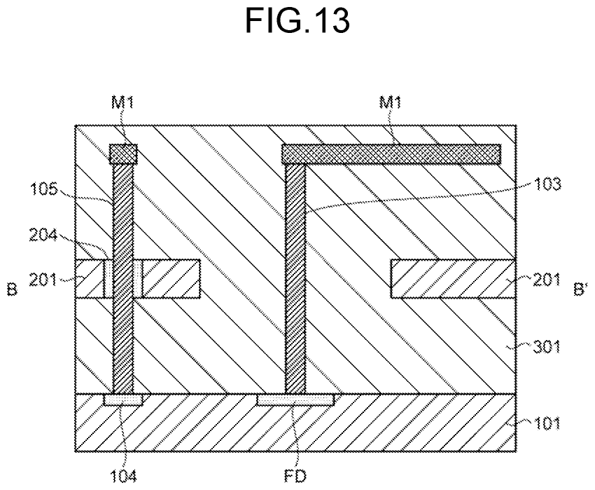

FIG. 11 is a plan view depicting a layout example of a circuit chip according to the second example. FIG. 12 is a cross-sectional view depicting a structural example of an A-A′ cross section according to the second example. FIG. 13 is a cross-sectional view depicting a structural example of a B-B′ cross section according to the second example.

### (Layout Example and Cross-Sectional Structure Example of Circuit Chip)

As depicted in FIGS. 11 to 13, in a layout example and a cross-sectional structure example of the circuit chip 42 according to the second example, in a configuration similar to those according to the first example, the extending portion 233 of the amplification gate electrode 231 is omitted, and instead, the through electrode 103 of the floating diffusion region FD and a contact plug 232 of the amplification gate electrode 231 are connected by the first metal wiring M1 in the upper layer. In the second example, the through electrode 105 penetrates the contact portion 204 formed so as to penetrate the semiconductor substrate 201, and is connected to the contact portion 104 formed on the element formation surface of the semiconductor substrate 101. In other words, the contact portion 104 is electrically short-circuited to the contact portion 204 via the through electrode 105. Therefore, the well potentials of the semiconductor substrates 101 and 201 can be controlled via the through electrode 105 that reaches the first metal wiring M1. Incidentally, similarly to the first example, the contact portions 104 and 204 may be, for example, P+ type diffusion regions.

### (Conclusion of Second Example)

As described above, the number of pieces of wiring to be built in the wiring layer of the circuit chip 42 can be reduced by short-circuiting the contact portion 104 and the contact portion 204 with the through electrode 105 and the first metal wiring M1. This can reduce the wiring density of the circuit chip 42 to improve the device characteristics, and can decrease the degree of difficulty in designing the wiring layout of the circuit chip 42.

### 1.7.3 Third Example

In a third example, similarly to the first example, a case where four unit pixels 30 arranged in two rows and two columns share one floating diffusion region FD will be described. Incidentally, since an FD shared circuit configuration example and a layout example of the light receiving chip 41 may be similar to the configuration described with reference to FIGS. 6 and 7 in the first example, and the A-A′ cross sectional structure may be similar to the structure described with reference to FIG. 9 in the first example, detailed description thereof will be omitted here.

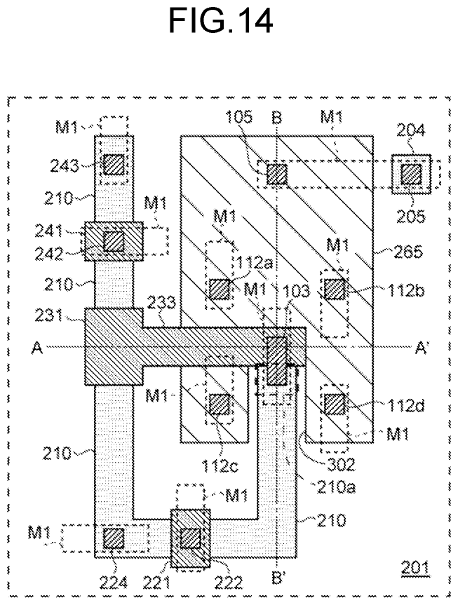

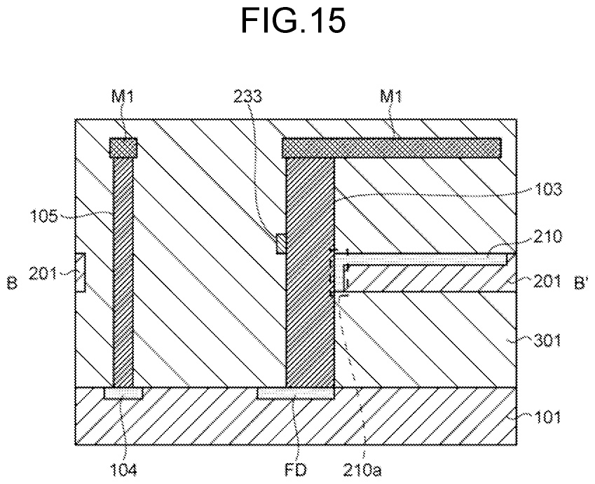

FIG. 14 is a plan view depicting a layout example of a circuit chip according to the third example. FIG. 15 is a cross-sectional view depicting a structural example of a B-B′ cross section according to the third example.

### (Layout Example and Cross-Sectional Structure Example of Circuit Chip)

As depicted in FIGS. 14, 9, and 15, in a layout example and a cross-sectional structure example of the circuit chip 42 according to the third example, in a configuration similar to those according to the first example, a diffusion region 210 functioning as the source of the reset transistor 32 is routed to the through electrode 103 along the element formation surface of the semiconductor substrate 201 to be short-circuited to a diffusion region 210a. The diffusion region 210a formed so as to penetrate the semiconductor substrate 201 is short-circuited to the through electrode 103.

Incidentally, in the third example, in order to bring the diffusion region 210a into contact with the through electrode 103, a recessed groove 302 for exposing a part of a side surface of the through electrode 103 is provided in a part of the insulating film region 265, and the diffusion region 210a is formed on the semiconductor substrate 201 in the groove 302. In the case, in order to easily expose the side surface of the through electrode 103 from the groove 302, the through electrode 103 may have a horizontal cross section having a vertically or horizontally (vertically in FIG. 14) elongated shape.

### (Conclusion of Third Example)

As described above, similarly to the first example, the number of necessary electrodes is reduced and the number of pieces of wiring to be built in the wiring layer of the circuit chip 42 is also reduced by routing the diffusion region 210 functioning as the source of the reset transistor 32 toward the floating diffusion region FD and short-circuiting the diffusion region 210 to the through electrode 103. This can reduce the wiring density of the circuit chip 42 to improve the device characteristics, and can decrease the degree of difficulty in designing the wiring layout of the circuit chip 42.

### 1.7.4 Fourth Example

In a fourth example, similarly to the first example, a case where four unit pixels 30 arranged in two rows and two columns share one floating diffusion region FD will be described. Incidentally, since an FD shared circuit configuration example may be similar to the configuration described with reference to FIG. 6 in the first example, detailed description thereof will be omitted here.

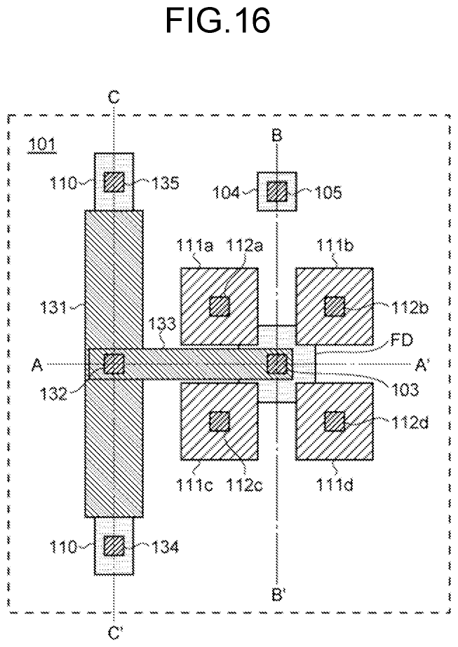

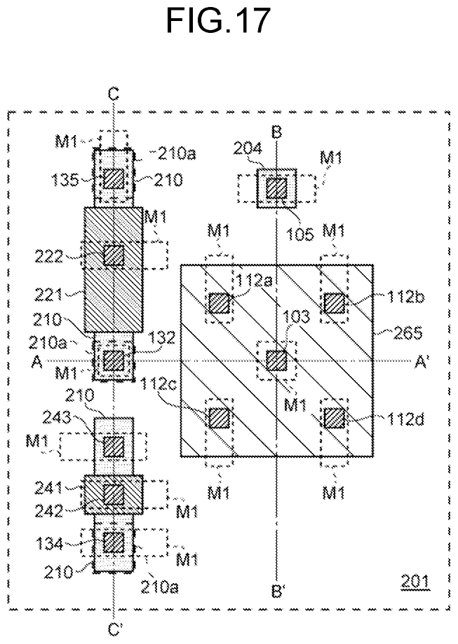

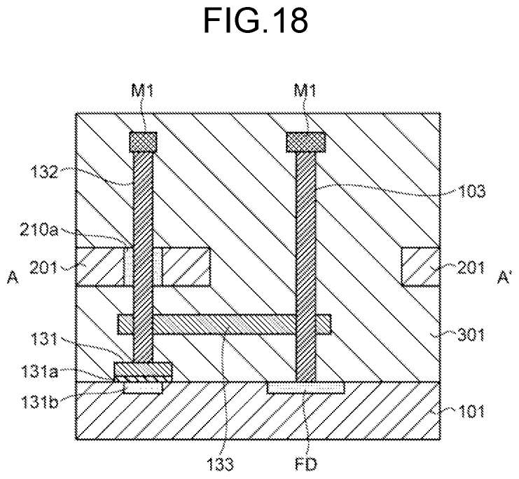

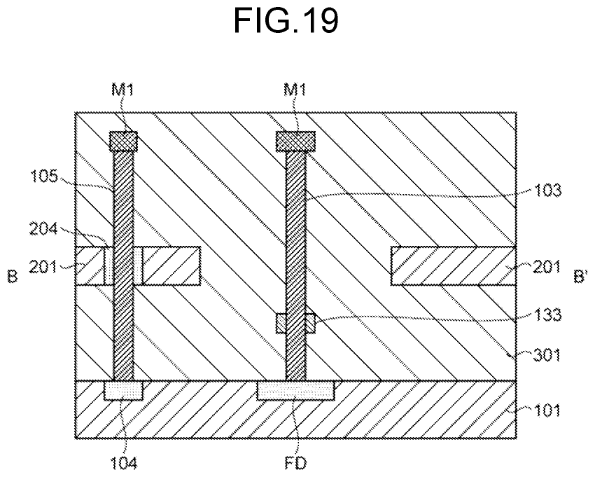

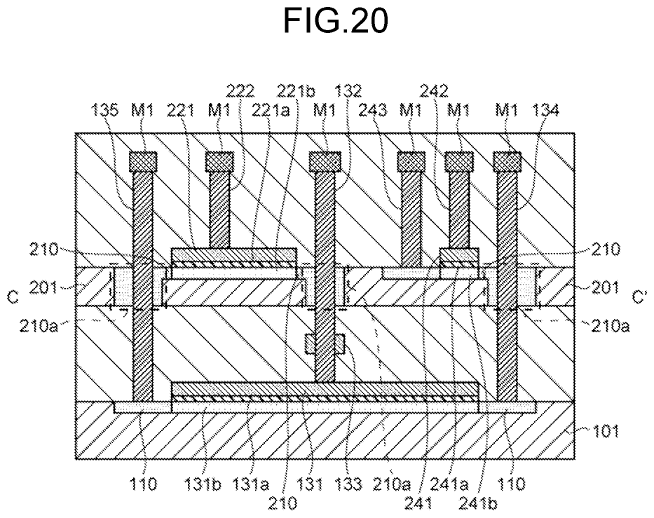

FIG. 16 is a plan view depicting a layout example of a light receiving chip according to the fourth example. FIG. 17 is a plan view depicting a layout example of a circuit chip according to the fourth example. FIG. 18 is a cross-sectional view depicting a structural example of an A-A′ cross section according to the fourth example. FIG. 19 is a cross-sectional view depicting a structural example of a B-B′ cross section according to the fourth example. FIG. 20 is a cross-sectional view depicting a structural example of a C-C′ cross section according to the fourth example.

### (Layout Example and Cross-Sectional Structure Example of Light Receiving Chip)

In the fourth example, the amplification transistor 33 is disposed on the light receiving chip 41 in addition to the photoelectric conversion units PDa to PDd and the transfer transistors 31a to 31d. As depicted in FIGS. 16 and 18 to 20, in a layout example and a cross-sectional structure example of the light receiving chip 41, in a configuration similar to those according to the first example, an amplification gate electrode 131 is disposed at a position adjacent to the transfer gate electrodes 111a to 111d arranged in two rows and two columns, and a pair of diffusion regions 110 functioning the source and the drain of the amplification transistor 33 are disposed in regions sandwiching a channel formation region 131b under the amplification gate electrode 131.

A through electrode 132 connected to the amplification gate electrode 131 penetrates the circuit chip 42 in the upper layer, and is connected to the first metal wiring M1. In addition, in the fourth example, the through electrode 132 connected to the amplification gate electrode 131 and the through electrode 103 connected to the floating diffusion region FD are connected by wiring 133 provided in a wiring layer between the semiconductor substrate 101 and the semiconductor substrate 201. This short-circuits the gate of the amplification transistor 33 and the floating diffusion region FD.

Incidentally, the wiring 133 may include, for example, a conductive material such as polycrystalline silicon (polysilicon) doped with impurities.

### (Layout Example and Cross-Sectional Structure Example of Circuit Chip)

In the fourth example, the reset transistor 32 and the selection transistor 34 are disposed on the circuit chip 42.

As depicted in FIGS. 17 to 20, in a layout example and a cross-sectional structure example of the circuit chip 42, in a configuration similar to those according to the first example, 210a, which is a part of the diffusion region 210 functioning as the source of the reset transistor 32, is formed so as to penetrate the semiconductor substrate 201. Further, the through electrode 132 is disposed so as to penetrate the diffusion region 210a. That is, in the fourth example, the through electrode 132 is integrated with a through electrode connecting the source (diffusion region 210a) of the reset transistor 32 with the first metal wiring M1. The through electrode 132 connects the gate of the amplification transistor 33 (amplification gate electrode 131) with the first metal wiring M1. This causes the gate of the amplification transistor 33 and the floating diffusion region FD and the source of the reset transistor 32 to be short-circuited. Incidentally, although, in the circuit chip 42 in FIGS. 17 to 20, the positional relation between the reset transistor 32 and the selection transistor 34 is replaced from the positional relation between those according to the first example for convenience of description, this is not a limitation. The drain (diffusion region 210a) of the reset transistor 32 is short-circuited to the drain (diffusion region 110) of the amplification transistor 33 via a through electrode 135. The through electrode 135 is connected to a power supply line that supplies the power supply voltage VDD via the first metal wiring M1 in the upper layer. The drain (diffusion region 210a) of the selection transistor 34 is short-circuited to the source (diffusion region 110) of the amplification transistor 33 via a through electrode 134. Similarly to the second example, the contact portion 204 formed on the element formation surface of the semiconductor substrate 201 is short-circuited to the contact portion 104 formed on the element formation surface of the semiconductor substrate 101 via the through electrode 105.

### (Conclusion of Fourth Example)

As described above, the number of elements and the number of pieces of wiring to be disposed on the circuit chip 42 can be reduced by disposing the amplification transistor 33 on the light receiving chip 41, which can reduce the wiring density of the circuit chip 42 to improve the device characteristics, and can decrease the degree of difficulty in designing the wiring layout of the circuit chip 42.

In addition, in the fourth example, the number of necessary electrodes is further reduced by the drain of the amplification transistor 33 short-circuited to the drain of the reset transistor 32 via the through electrode 135 and the source of the amplification transistor 33 short-circuited to the drain of the selection transistor via the through electrode 134 in addition to the through electrode 132 connected to the gate of the amplification transistor 33 (amplification gate electrode 131) doubling as a through electrode connected to the source (diffusion region 210a) of the reset transistor 32. This can reduce the wiring density of the circuit chip 42 to further improve the device characteristics, and can further decrease the degree of difficulty in designing the wiring layout of the circuit chip 42.

### 1.7.5 Fifth Example

In a fifth example, a case will be described in which two configurations each having one floating diffusion region FD shared by four unit pixels 30 arranged in two rows and two columns are provided, the floating diffusion regions FD are short-circuited between the two configurations, and thus a total of eight unit pixels 30 share one floating diffusion region FD. In addition, in the fifth example, a configuration capable of changing the capacitance of the floating diffusion region FD, in other words, changing the dynamic range of each unit pixel 30 will also be described.

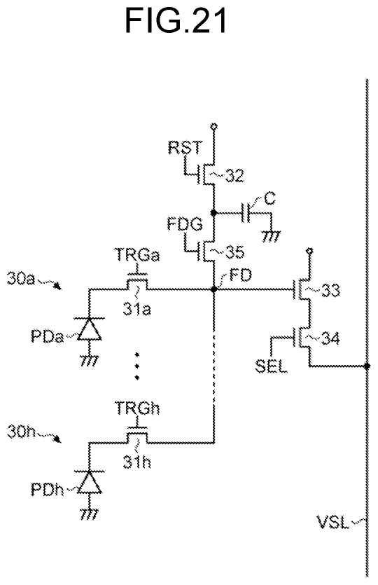

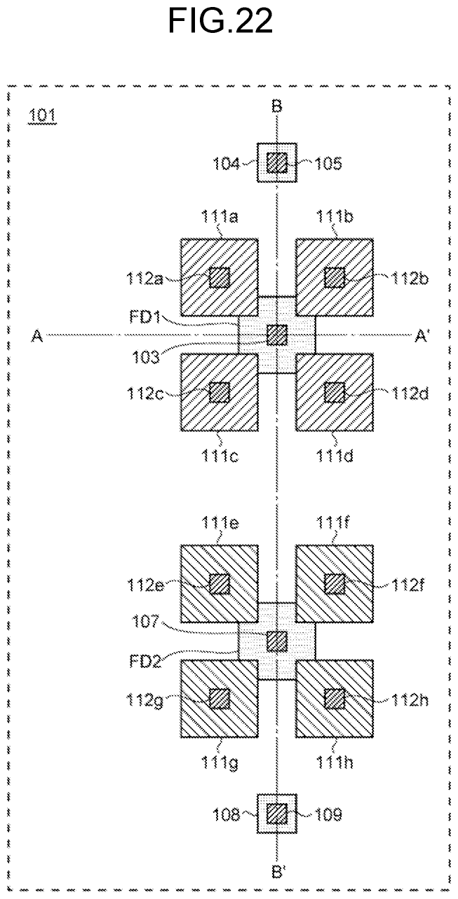

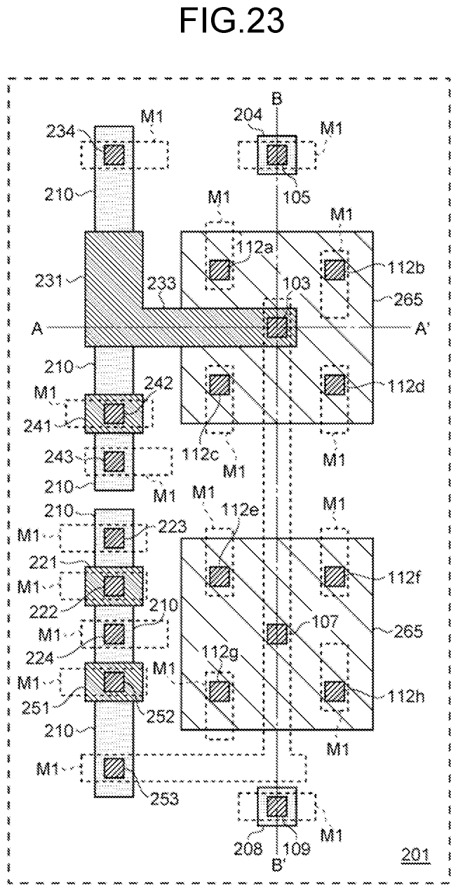

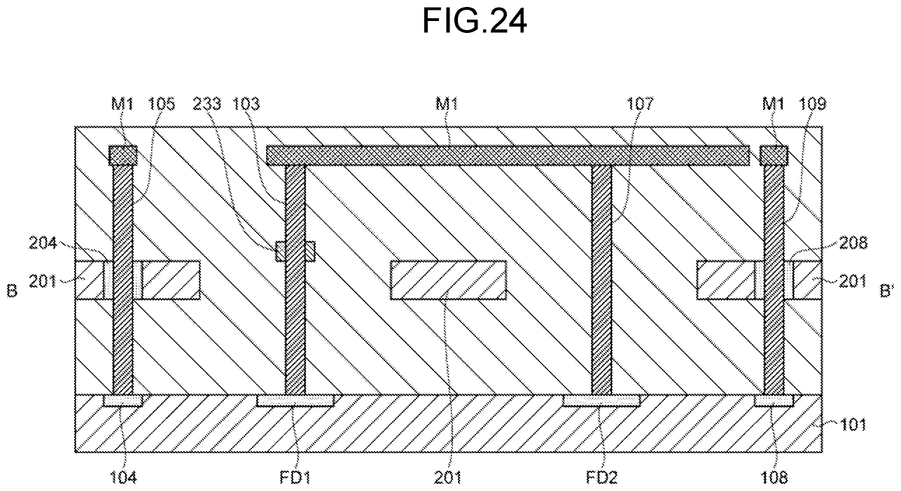

FIG. 21 is a circuit diagram depicting an FD shared circuit configuration example according to the fifth example. FIG. 22 is a plan view depicting a layout example of a light receiving chip according to the fifth example. FIG. 23 is a plan view depicting a layout example of a circuit chip according to the fifth example. FIG. 24 is a cross-sectional view depicting a structural example of a B-B′ cross section according to the fifth example. Incidentally, since an A-A′ cross sectional structure may be similar to the structure described with reference to FIG. 9 in the first example, detailed description thereof will be omitted here.

### (FD Shared Configuration)

As depicted in FIG. 21, in an FD shared configuration in which eight unit pixels 30a to 30h share one floating diffusion region FD, similarly to the circuit configuration described with reference to FIG. 6 in the first example, eight photoelectric conversion units PDa to PDh are connected to a common floating diffusion region FD via transfer transistors 31a to 31h, respectively. The eight unit pixels 30a to 30h share configurations following the floating diffusion region FD. Therefore, in the present example, the eight unit pixels 30a to 30h share the reset transistor 32, the amplification transistor 33, the selection transistor 34, a switching transistor 35, and a capacitor C.

In addition, in the configuration in which the capacitance of the floating diffusion region FD is changed, the switching transistor 35 is connected between the floating diffusion region FD and the source of the reset transistor 32. Then, the capacitor C is connected to a connection node between the source of the reset transistor 32 and a drain of the switching transistor 35. For example, the capacitor C may be a capacitance intentionally added by using metal wiring and the like, or may be a parasitic capacitance and the like formed between the connection node and a substrate.

In such a configuration, a capacitance for accumulating charges transferred from each of the photoelectric conversion units PDa to PDh can be switched to any of a capacitance of the floating diffusion region FD alone and a capacitance obtained by adding the capacitance of the capacitor C to the capacitance of the floating diffusion region FD by controlling on/off of the switching transistor 35. This enables the voltage applied to the gate of the amplification transistor 33 to be controlled, so that the dynamic range of each unit pixel 30 can be switched. Incidentally, although, in practice, a parasitic capacitance and the like of wiring and the like connected to the floating diffusion region FD is also included in the capacitance for accumulating charges transferred from each of the photoelectric conversion units PDa to PDh, the parasitic capacitance and the like of wiring and the like connected to the floating diffusion region FD is not considered here for the sake of simplicity.

### (Layout Example and Cross-Sectional Structure Example of Light Receiving Chip)

In the fifth example, the photoelectric conversion units PDa to PDh and the transfer transistors 31a to 31h are disposed on the light receiving chip 41. As depicted in FIGS. 22, 9, and 24, in the fifth example, the transfer gate electrodes 111a to 111d of the transfer transistors 31a to 31d are disposed in two rows and two columns, and a floating diffusion region FD1 is disposed at the center of the arrangement. In addition, transfer gate electrodes 111e to 111h of transfer transistors 31e to 31h are disposed in two rows and two columns, and a floating diffusion region FD2 is disposed at the center of the arrangement. Therefore, as a whole, an FD shared pixel has a configuration in which eight unit pixels 30 are arranged in four rows and two columns.

The transfer gate electrodes 111a to 111h are connected to the first metal wiring M1 via through electrodes 112a to 112h, respectively. In addition, the floating diffusion region FD1 is connected to the first metal wiring M1 via the through electrode 103. The floating diffusion region FD2 is connected to the first metal wiring M1 via a through electrode 107. In other words, the floating diffusion region FD1 and the floating diffusion region FD2 are short-circuited via the first metal wiring M1. As a result, the eight unit pixels 30 share the floating diffusion region FD.

Incidentally, although, in the fifth example, a case is described in which two sets of the contact portion 104 and the through electrode 105 and a contact portion 108 and a through electrode 109 are provided for controlling the well potential of the semiconductor substrate 101, this is not a limitation. One set or three or more sets may be provided.

### (Layout Example and Cross-Sectional Structure Example of Circuit Chip)

In the fifth example, the reset transistor 32, the amplification transistor 33, the selection transistor 34, and the switching transistor 35 are disposed on the circuit chip 42.

As depicted in FIGS. 23, 9, and 24, in the fifth example, in the configuration similar to the layout example and the cross-sectional structure example of the circuit chip 42 according to the first example, the amplification transistor 33, the selection transistor 34, the reset transistor 32, and the switching transistor 35 are arranged in this order. The diffusion region 210 disposed between the amplification gate electrode 231 and the selection gate electrode 241 functions as the source of the amplification transistor 33 and the drain of the selection transistor 34. The diffusion region 210 disposed between a switching gate electrode 251 and the reset gate electrode 221 functions as a drain of the switching transistor 35 and the source of the reset transistor 32.

The diffusion region 210 functioning as the drain of the amplification transistor 33 is connected to the first metal wiring M1 via a contact plug 234. The diffusion region 210 functioning as a source of the switching transistor 35 is connected to the first metal wiring M1 via a contact plug 253.

In such a configuration, similarly to the first example, the amplification gate electrode 231 includes the extending portion 233 extending toward the floating diffusion region FD1. The extending portion 233 is connected to the through electrode 103, so that the gate of the amplification transistor 33 and the floating diffusion region FD1 are short-circuited.

In addition, the contact plug 253 connected to the diffusion region 210 functioning as the source of the switching transistor 35 is connected to the through electrode 107 of the floating diffusion region FD2 and the through electrode 103 of the floating diffusion region FD1 via the first metal wiring M1. This causes the gate of the amplification transistor 33, the floating diffusion regions FD1 and FD2, and the source of the switching transistor 35 to be short-circuited.

Incidentally, although, in the fifth example, a case is described in which two sets of the contact portion 204 and the through electrode 105 and a contact portion 208 and a through electrode 109 are provided for controlling the well potential of the semiconductor substrate 201, this is not a limitation. One set or three or more sets may be provided.

### (Conclusion of Fifth Example)

As described above, similarly to the first example, the number of necessary electrodes is reduced by causing the amplification gate electrode 231 to extend in the direction of the floating diffusion region FD and short-circuiting the amplification gate electrode 231 to the through electrode 103. This can reduce the wiring density of the circuit chip 42 to improve the device characteristics, and can decrease the degree of difficulty in designing the wiring layout of the circuit chip 42.

### 1.7.6 Sixth Example

In a sixth example, similarly to the fifth example, a case where eight unit pixels 30 arranged in four rows and two columns share one floating diffusion region FD will be described. Incidentally, since an FD shared circuit configuration example may be similar to the configuration described with reference to FIG. 21 in the fifth example, detailed description thereof will be omitted here.

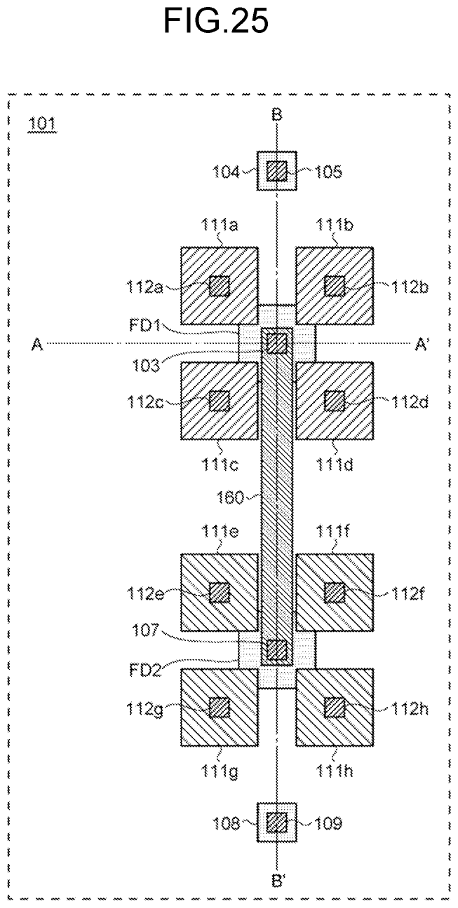

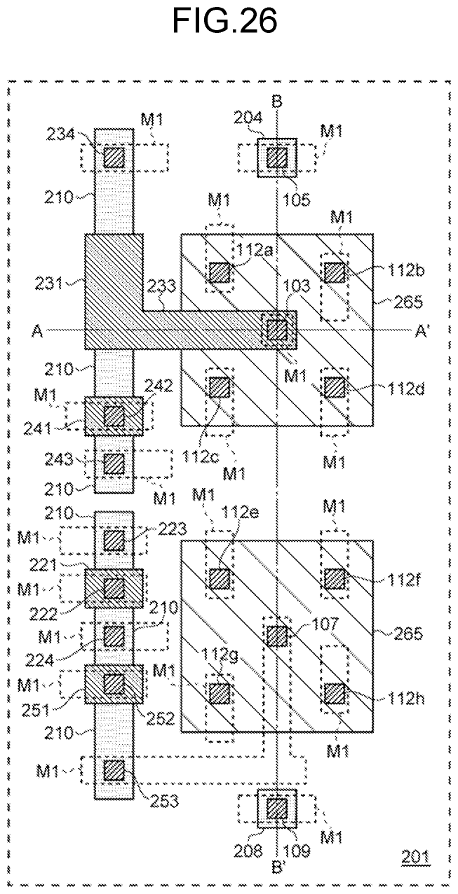

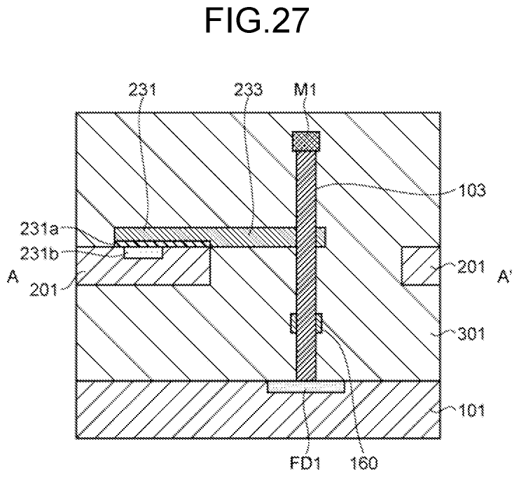

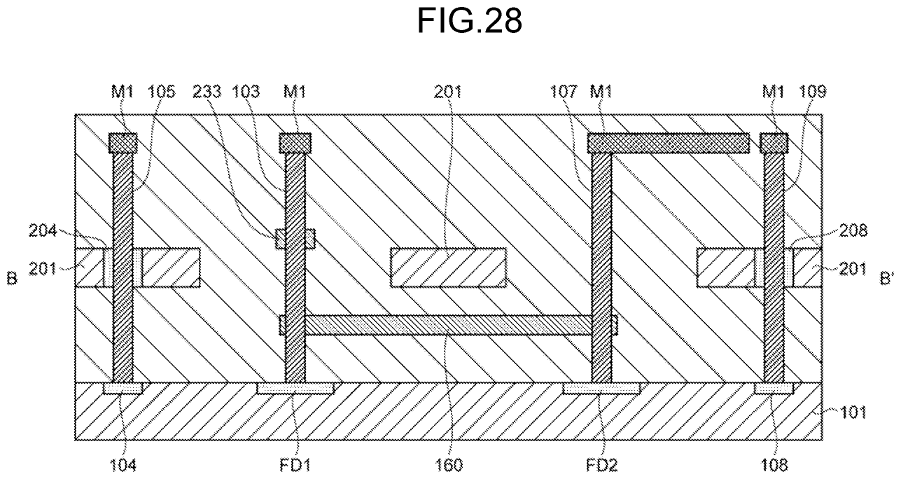

FIG. 25 is a plan view depicting a layout example of a light receiving chip according to the sixth example. FIG. 26 is a plan view depicting a layout example of a circuit chip according to the sixth example. FIG. 27 is a cross-sectional view depicting a structural example of an A-A′ cross section according to the sixth example. FIG. 28 is a cross-sectional view depicting a structural example of a B-B′ cross section according to the sixth example.

### (Layout Example and Cross-Sectional Structure Example of Light Receiving Chip)

As depicted in FIGS. 25, 27, and 28, in a layout example and a cross-sectional structure example of the light receiving chip 41 according to the sixth example, in a configuration similar to those according to the fifth example, the through electrode 103 and the through electrode 107 are connected by wiring 160, so that the floating diffusion region FD1 and the floating diffusion region FD2 are electrically connected. The wiring 160 may include, for example, a conductive material such as polysilicon doped with impurities.

### (Layout Example and Cross-Sectional Structure Example of Circuit Chip)

As depicted in FIGS. 26 to 28, in a layout example and a cross-sectional structure example of the circuit chip 42, in a configuration similar to those according to the fifth example, the first metal wiring M1 connecting the contact plug 253 connected to the source of the switching transistor 35, the through electrode 103, and the through electrode 107 is replaced with the first metal wiring M1 connecting the contact plug 253 and the through electrode 107.

### (Conclusion of Sixth Example)

Also in the sixth example, similarly to the fifth example, the number of necessary electrodes is reduced by causing the amplification gate electrode 231 to extend in the direction of the floating diffusion region FD and short-circuiting the amplification gate electrode 231 to the through electrode 103. In addition, the area of the first metal wiring M1 in the upper layer of the circuit chip 42 is reduced as compared to that in the fifth example by short-circuiting the floating diffusion region FD1 to the floating diffusion region FD2 via the wiring 160, the through electrode 103, and the through electrode 107. The above-described configuration can reduce the wiring density of the circuit chip 42 to improve the device characteristics, and can decrease the degree of difficulty in designing the wiring layout of the circuit chip 42.

### 1.7.7 Seventh Example

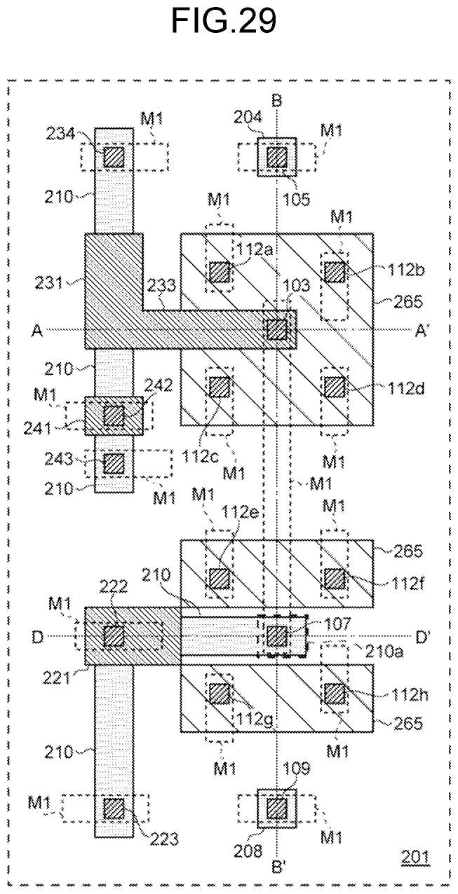

In a seventh example, similarly to the fifth example, a case where eight unit pixels 30 arranged in four rows and two columns share one floating diffusion region FD will be described. Incidentally, since an FD shared circuit configuration example and a layout example of the light receiving chip 41 may be similar to the configuration described with reference to FIGS. 21 and 22 in the fifth example, and the A-A′ cross sectional structure of the circuit chip 42 in FIG. 29 may be similar to the structure described with reference to FIG. 9 in the first example, detailed description thereof will be omitted here. Note, however, that, in the seventh example, the switching transistor 35 in a pixel circuit is omitted.

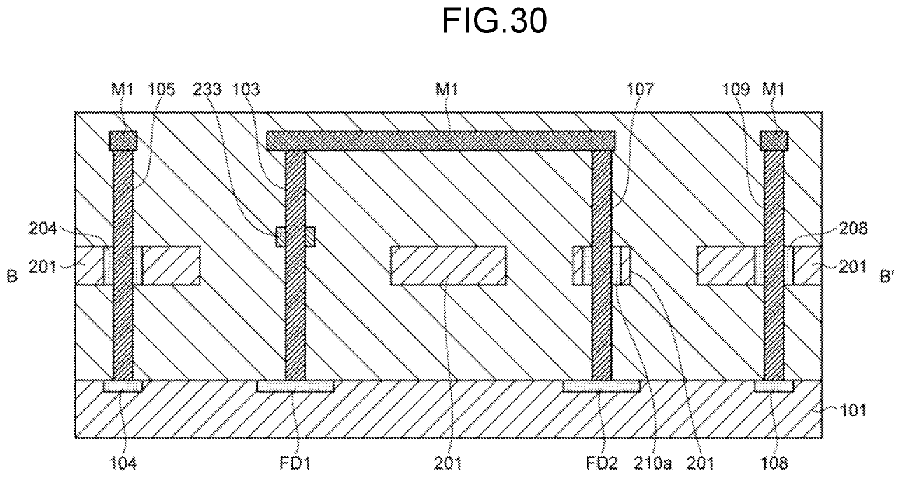

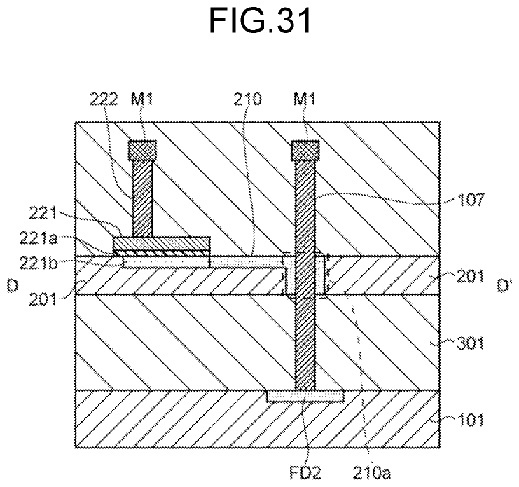

FIG. 29 is a plan view depicting a layout example of a circuit chip according to the seventh example. FIG. 30 is a cross-sectional view depicting a structural example of a B-B′ cross section according to the seventh example. FIG. 31 is a cross-sectional view depicting a structural example of a D-D′ cross section according to the seventh example.

### (Layout Example and Cross-Sectional Structure Example of Circuit Chip)

As depicted in FIGS. 29, 9, 30, and 31, in a layout example and a cross-sectional structure example of the circuit chip 42, the diffusion region 210 functioning as the source of the reset transistor 32 extends toward the floating diffusion region FD2, and is short-circuited to the diffusion region 210a. Further, the diffusion region 210a is in contact with the through electrode 107. This causes the source of the reset transistor 32, the gate of the amplification transistor, and the floating diffusion regions FD1 and FD2 to be short-circuited via the through electrodes 103 and 107, the first metal wiring M1 connecting these electrodes, and the extending portion 233.

Incidentally, in the seventh example, the diffusion region 210a which is a part of the diffusion region 210 functioning as the source of the reset transistor 32 penetrates the semiconductor substrate 201. Further, in order to bring the diffusion region 210a into contact with the through electrode 107, the insulating film region 265 for penetrating through electrodes 112e to 112h is divided into two regions along the extending direction of the diffusion region 210a.

### (Conclusion of Seventh Example)

Also in the seventh example, similarly to the fifth example, the number of necessary electrodes is reduced by causing the amplification gate electrode 231 to extend in the direction of the floating diffusion region FD1 and short-circuiting the amplification gate electrode 231 to the through electrode 103. Further, the area of the first metal wiring M1 in the upper layer of the circuit chip 42 is reduced as compared to that in the fifth example by short-circuiting the diffusion region 210a functioning as the source of the reset transistor 32 to the floating diffusion region FD2 via the through electrode 107. The above-described configuration can reduce the wiring density of the circuit chip 42 to improve the device characteristics, and can decrease the degree of difficulty in designing the wiring layout of the circuit chip 42.

### 1.7.8 Eighth Example

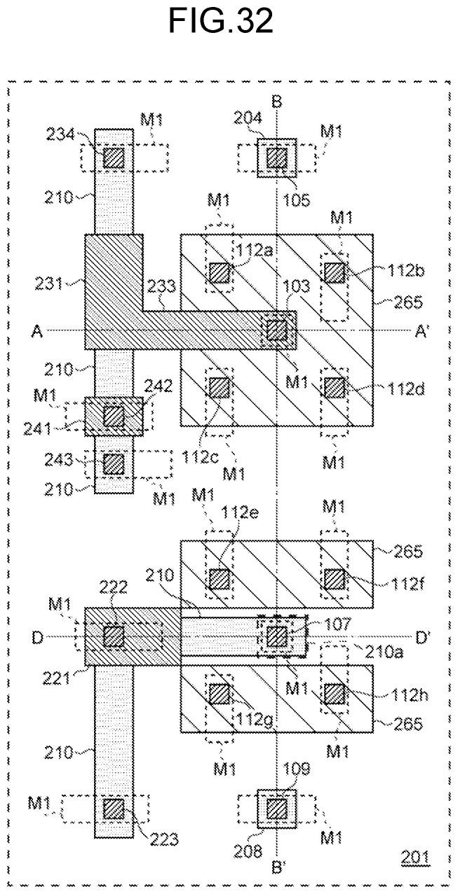

In an eighth example, similarly to the fifth example, a case where eight unit pixels 30 arranged in four rows and two columns share one floating diffusion region FD will be described. Incidentally, an FD shared circuit configuration example may be similar to the configuration described with reference to FIG. 21 in the fifth example. A layout example of the light receiving chip 41 may be similar to the layout example described with reference to FIG. 25 in the sixth example. An A-A′ cross sectional structure of the circuit chip 42 in FIG. 32 may be similar to the configuration described with reference to FIG. 27 in the sixth example. Thus, detailed description thereof will be omitted here. Note, however, that, in the eighth example, the switching transistor 35 in a pixel circuit is omitted.

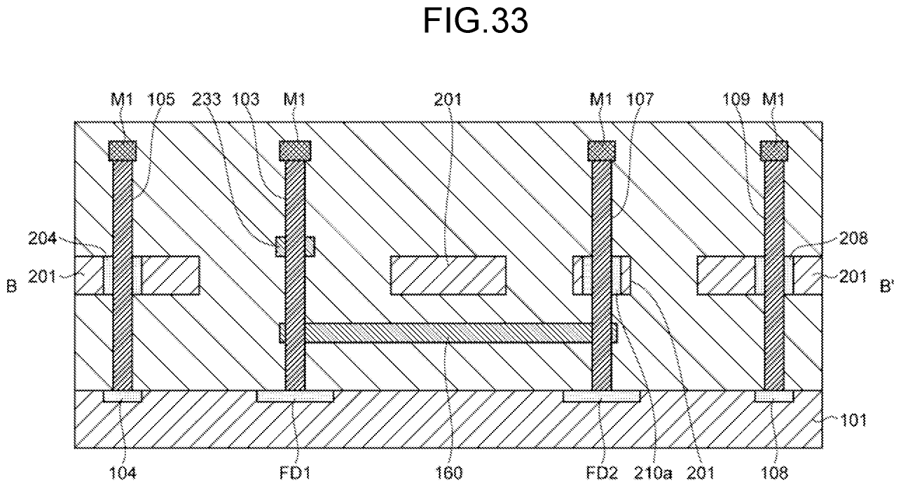

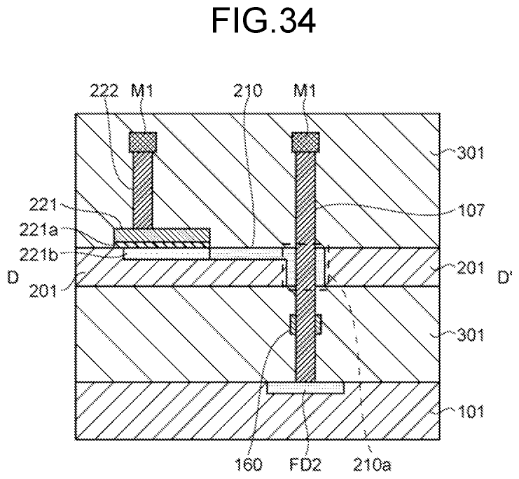

FIG. 32 is a plan view depicting a layout example of a circuit chip according to the eighth example. FIG. 33 is a cross-sectional view depicting a structural example of a B-B′ cross section according to the eighth example. FIG. 34 is a cross-sectional view depicting a structural example of a D-D′ cross section according to the eighth example.

### (Layout Example and Cross-Sectional Structure Example of Circuit Chip)

As depicted in FIGS. 32, 27, 33, and 34, in a layout example and a cross-sectional structure example of the circuit chip 42, in a configuration similar to those according to the seventh example, the through electrode 103 is short-circuited to the through electrode 107 via the first metal wiring M1 in the seventh example, whereas the through electrode 103 is short-circuited to the through electrode 107 via the wiring 160 in the eighth example.

### (Conclusion of Eighth Example)

Also in the eighth example, similarly to the fifth example, the number of necessary electrodes is reduced by causing the amplification gate electrode 231 to extend in the direction of the floating diffusion region FD1 and short-circuiting the amplification gate electrode 231 to the through electrode 103. In addition, the area of the first metal wiring M1 in the upper layer of the circuit chip 42 is reduced as compared to that in the seventh example by short-circuiting the floating diffusion region FD1 to the floating diffusion region FD2 via the wiring 160, the through electrode 103, and the through electrode 107. The above-described configuration can reduce the wiring density of the circuit chip 42 to improve the device characteristics, and can decrease the degree of difficulty in designing the wiring layout of the circuit chip 42.

### 1.7.9 Ninth Example

In a ninth example, similarly to the fifth example, a case where eight unit pixels 30 arranged in four rows and two columns share one floating diffusion region FD will be described. Incidentally, since an FD shared circuit configuration example may be similar to the configuration described with reference to FIG. 21 in the fifth example, detailed description thereof will be omitted here. Note, however, that, in the ninth example, the switching transistor 35 in a pixel circuit is omitted.

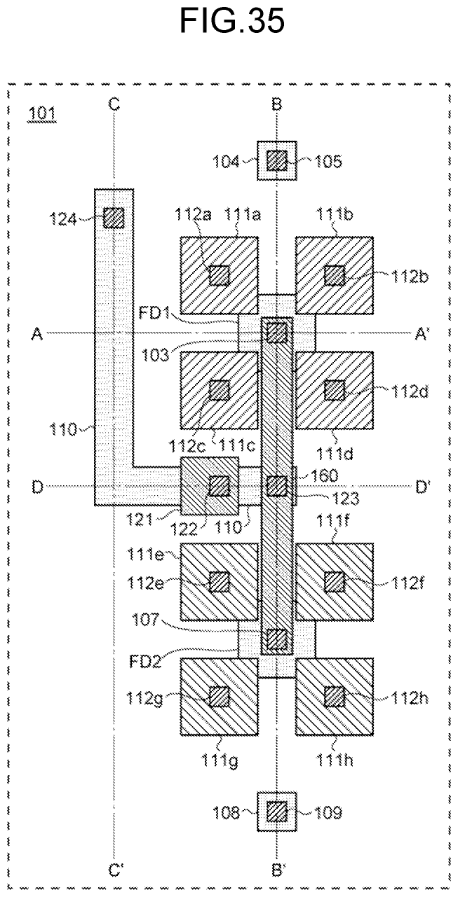

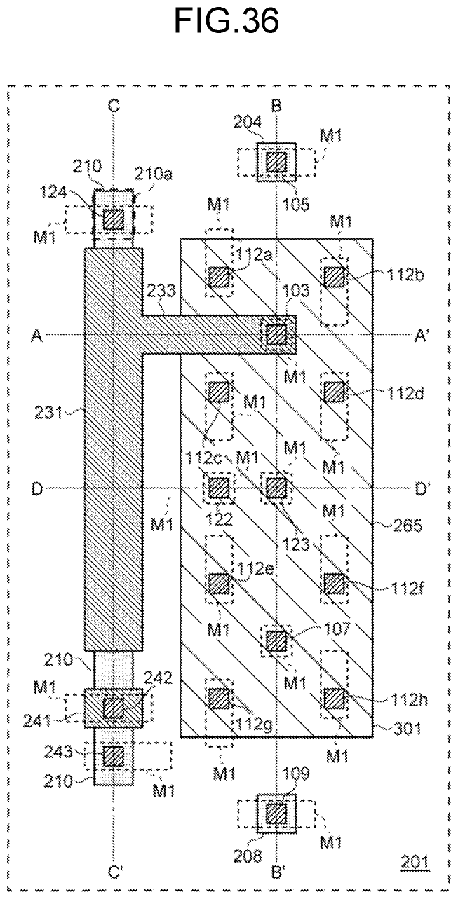

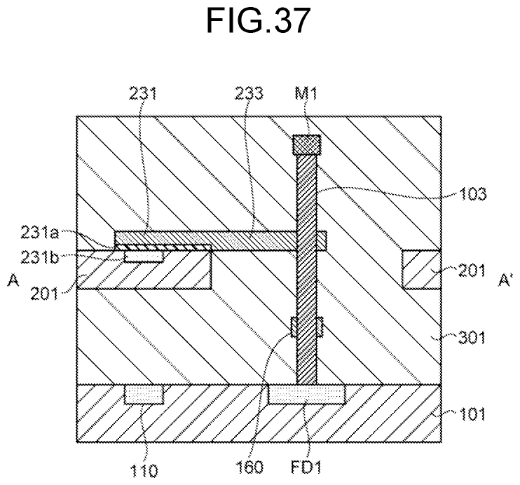

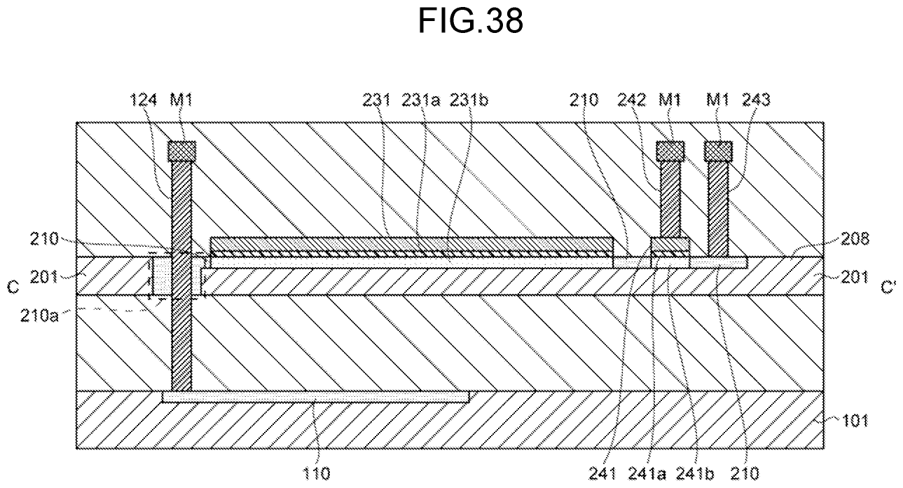

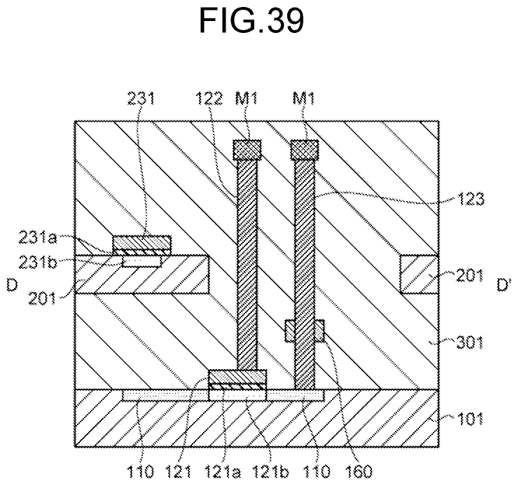

FIG. 35 is a plan view depicting a layout example of a light receiving chip according to the ninth example. FIG. 36 is a plan view depicting a layout example of a circuit chip according to the ninth example. FIG. 37 is a cross-sectional view depicting a structural example of an A-A′ cross section according to the ninth example. FIG. 38 is a cross-sectional view depicting a structural example of a C-C′ cross section according to the ninth example. FIG. 39 is a cross-sectional view depicting a structural example of a D-D′ cross section according to the ninth example.

### (Layout Example and Cross-Sectional Structure Example of Light Receiving Chip)

In the ninth example, the reset transistor 32 is disposed on the light receiving chip 41 in addition to the photoelectric conversion units PDa to PDh and the transfer transistors 31a to 31h. As depicted in FIGS. 35 and 37 to 39, in a layout example and a cross-sectional structure example of the light receiving chip 41, in a configuration similar to those according to the sixth example, a reset gate electrode 121, a gate insulating film 121a, a channel formation region 121b, and a pair of diffusion regions 110, which constitute the reset transistor 32, are provided on the element formation surface of the semiconductor substrate 101. The reset gate electrode 121 is connected to the first metal wiring M1 via a through electrode 122. The diffusion regions 110 functioning as the drain of the reset transistor 32 is short-circuited to the diffusion region 210a, which is a part of the drain of the amplification transistor 33, via a through electrode 124.

In addition, the diffusion region 110 functioning as the source of the reset transistor 32 is disposed so as to overlap the wiring 160 in the substrate thickness direction. A through electrode 123 penetrates the wiring 160 to be connected to the diffusion region 110. Similarly, the through electrode 103 and the through electrode 107 are respectively connected to the floating diffusion region FD1 and the floating diffusion region FD2 through the wiring 160. As a result, the diffusion region 110 and the floating diffusion regions FD1 and FD2 are short-circuited via the wiring 160 and the through electrodes 103, 107, and 123. Incidentally, the wiring 160 may include, for example, a conductive material such as polysilicon doped with impurities.

### (Layout Example and Cross-Sectional Structure Example of Circuit Chip)

In the ninth example, the amplification transistor 33 and the selection transistor 34 are disposed on the circuit chip 42. As depicted in FIGS. 36 and 37 to 39, the amplification gate electrode 231 of the amplification transistor 33 includes the extending portion 233 similar to that in the first example, and is connected to the through electrode 103 connected to the floating diffusion region FD1 via the extending portion 233. This causes the source of the reset transistor 32, the gate of the amplification transistor 33, and the floating diffusion regions FD1 and FD2 to be short-circuited via the through electrodes 103, 107, and 123, the extending portion 233, and the wiring 160.

### (Conclusion of Ninth Example)

Also in the ninth example, similarly to the fifth example, the number of necessary electrodes is reduced by causing the amplification gate electrode 231 to extend in the direction of the floating diffusion region FD1 and short-circuiting the amplification gate electrode 231 to the through electrode 103. This can reduce the wiring density of the circuit chip 42 to improve the device characteristics, and can decrease the degree of difficulty in designing the wiring layout of the circuit chip 42.

In addition, a region where an amplification transistor can be disposed on the circuit chip is increased by disposing the reset transistor 32 on the light receiving chip 41. In other words, the gate area of the amplification transistor can be increased, and as a result, characteristics such as random noise can be improved as compared to that in the fifth example.

### 1.7.10 10th Example

In a 10th example, similarly to the fifth example, a case where eight unit pixels 30 arranged in four rows and two columns share one floating diffusion region FD will be described. Incidentally, since an FD shared circuit configuration example may be similar to the configuration described with reference to FIG. 21 in the fifth example, detailed description thereof will be omitted here. Note, however, that, in the 10th example, the switching transistor 35 in a pixel circuit is omitted.

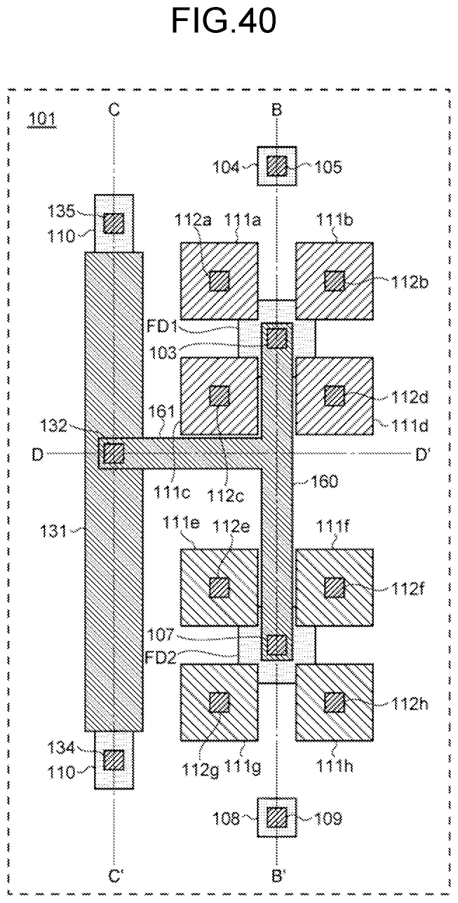

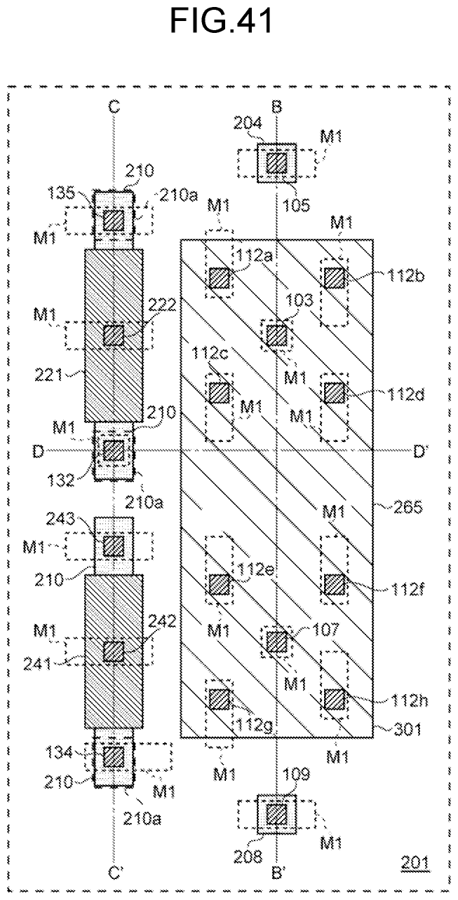

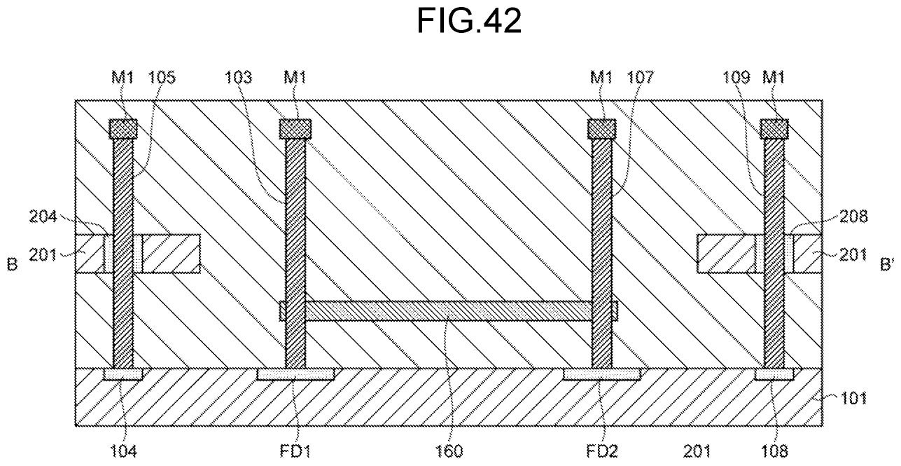

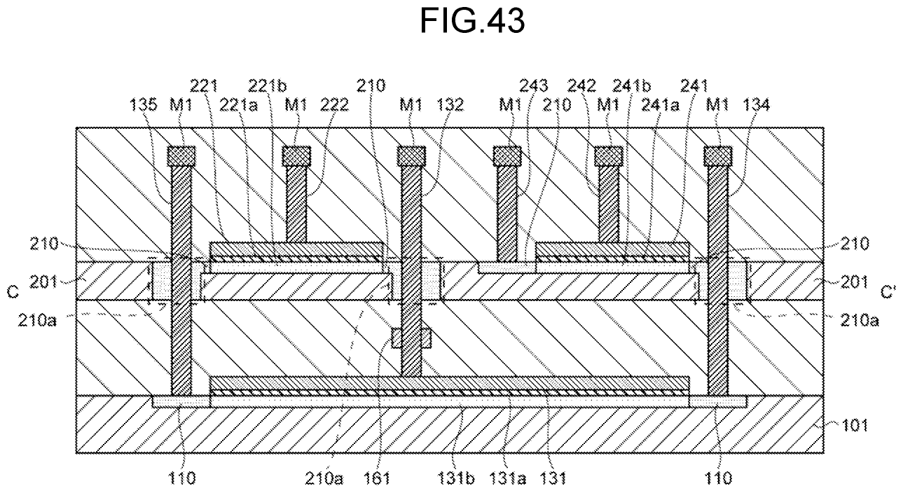

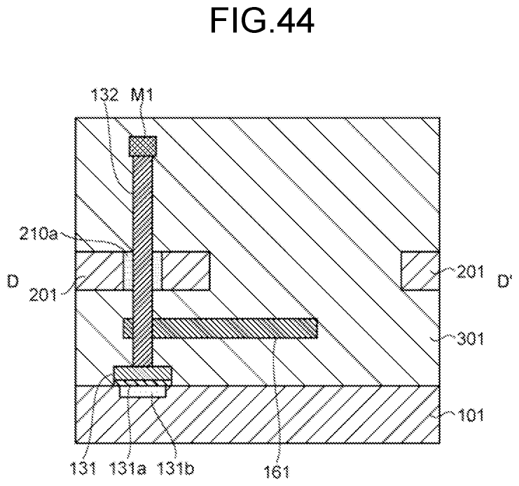

FIG. 40 is a plan view depicting a layout example of a light receiving chip according to the 10th example. FIG. 41 is a plan view depicting a layout example of a circuit chip according to the 10th example. FIG. 42 is a cross-sectional view depicting a structural example of a B-B′ cross section according to the 10th example. FIG. 43 is a cross-sectional view depicting a structural example of a C-C′ cross section according to the 10th example. FIG. 44 is a cross-sectional view depicting a structural example of a D-D′ cross section according to the 10th example.

### (Layout Example and Cross-Sectional Structure Example of Light Receiving Chip)

In the 10th example, the amplification transistor 33 is disposed on the light receiving chip 41 in addition to the photoelectric conversion units PDa to PDh and the transfer transistors 31a to 31h. As depicted in FIGS. 40 and 42 to 44, in a layout example and a cross-sectional structure example of the light receiving chip 41, in a configuration similar to those according to the fifth example, as depicted in the fourth example, an amplification gate electrode 131 is disposed at a position adjacent to the transfer gate electrodes 111a to 111h arranged in four rows and two columns, and a pair of diffusion regions 110 functioning the source and the drain of the amplification transistor 33 are arranged in regions sandwiching the channel formation region 131b under the amplification gate electrode 131.

Similarly to the sixth example, the through electrode 103 connected to the floating diffusion region FD1 and the through electrode 107 connected to the floating diffusion region FD2 are connected by the wiring 160. The wiring 160 includes an extending portion 161 extending in parallel to the element formation surface toward the amplification gate electrode 131. The extending portion 161 is connected to the through electrode 132 connected to the amplification gate electrode 131. Incidentally, the extending portion 161 may include the same material as that of the wiring 160, for example, a conductive material such as polysilicon doped with impurities.

### (Layout Example and Cross-Sectional Structure Example of Circuit Chip)

In the 10th example, the reset transistor 32 and the selection transistor 34 are disposed on the circuit chip 42. As depicted in FIGS. 41 and 42 to 44, the through electrode 132 connected to the amplification gate electrode 131 of the amplification transistor 33 penetrates the diffusion region 210a functioning as the source of the reset transistor 32. This causes the source of the reset transistor 32, the gate of the amplification transistor 33, and the floating diffusion regions FD1 and FD2 to be short-circuited via the through electrodes 103, 107, and 132 and the wiring 160 including the extending portion 161. Similarly, the drain (diffusion region 210a) of the reset transistor 32 is short-circuited to the drain (diffusion region 110) of the amplification transistor 33 via a through electrode 135. The through electrode 135 is connected to a power supply line that supplies the power supply voltage VDD via the first metal wiring M1 in the upper layer. The drain (diffusion region 210a) of the selection transistor 34 is short-circuited to the source (diffusion region 110) of the amplification transistor 33 via a through electrode 134.

### (Conclusion of 10th Example)

Also in the 10th example, similarly to the fourth example, the number of elements and the number of pieces of wiring to be disposed on the circuit chip 42 can be reduced by disposing the amplification transistor 33 on the light receiving chip 41, which can reduce the wiring density of the circuit chip 42 to improve the device characteristics, and can decrease the degree of difficulty in designing the wiring layout of the circuit chip 42.

In addition, also in the 10th example, similarly to the fourth example, the number of necessary electrodes is further reduced by the drain of the amplification transistor 33 short-circuited to the drain of the reset transistor 32 via the through electrode 135 and the source of the amplification transistor 33 short-circuited to the drain of the selection transistor via the through electrode 134 in addition to the through electrode 132 connected to the gate of the amplification transistor 33 (amplification gate electrode 131) doubling as a through electrode connected to the source (diffusion region 210a) of the reset transistor 32. This can reduce the wiring density of the circuit chip 42 to further improve the device characteristics, and can further decrease the degree of difficulty in designing the wiring layout of the circuit chip 42.

### 1.7.11 11th Example

In an 11th example, similarly to the fifth example, a case where eight unit pixels 30 arranged in four rows and two columns share one floating diffusion region FD will be described. Incidentally, an FD shared circuit configuration example may be similar to the configuration described with reference to FIG. 21 in the fifth example. A B-B′ cross-sectional structure may be similar to the structure described with reference to FIG. 42 in the 10th example. A D-D′ cross-sectional structure may be similar to the structure described with reference to FIG. 44 in the 10th example. Thus, detailed description thereof will be omitted here. Note, however, that, in the 11th example, the pixel circuit includes the switching transistor 35.

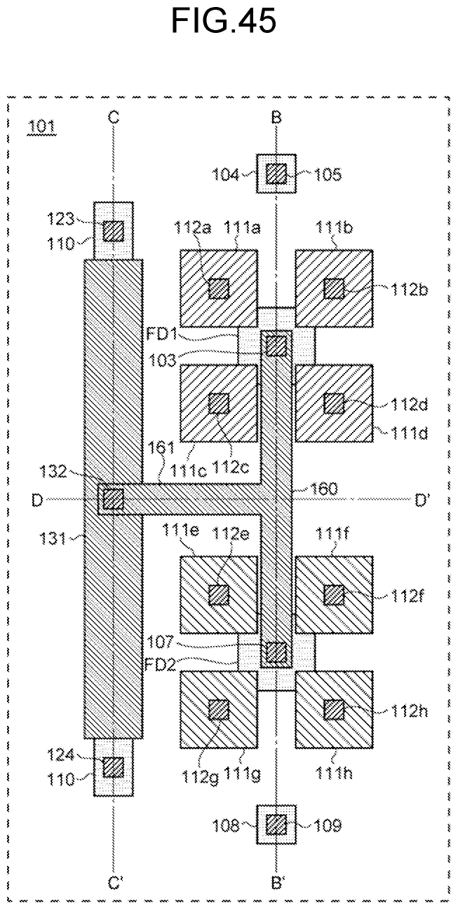

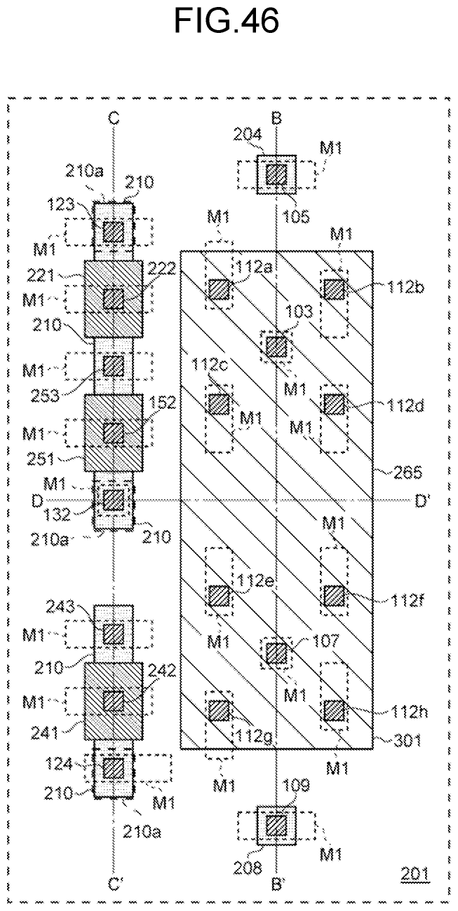

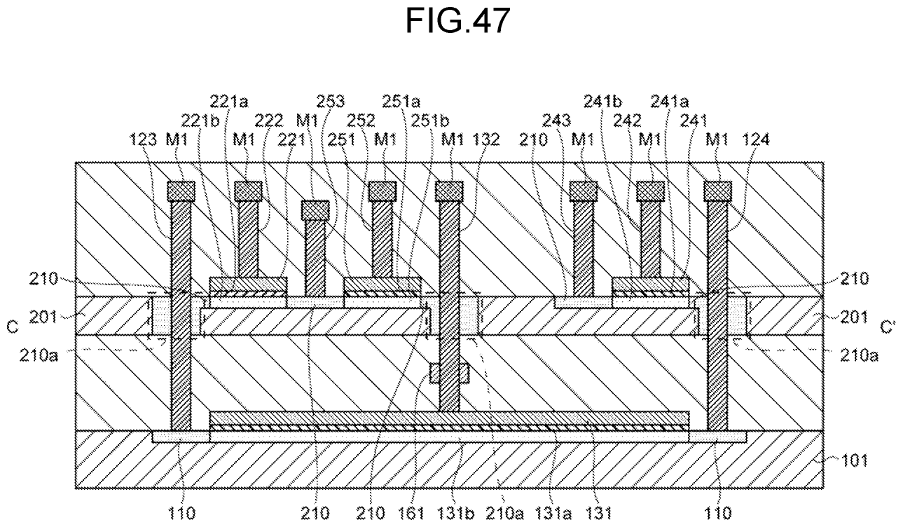

FIG. 45 is a plan view depicting a layout example of a light receiving chip according to the 11th example. FIG. 46 is a plan view depicting a layout example of a circuit chip according to the 11th example. FIG. 47 is a cross-sectional view depicting a structural example of a C-C′ cross section according to the 11th example.

### (Layout Example and Cross-Sectional Structure Example of Light Receiving Chip)

In the 11th example, similarly to the 10th example, the amplification transistor 33 is disposed on the light receiving chip 41 in addition to the photoelectric conversion units PDa to PDh and the transfer transistors 31a to 31h. Note, however, that, as depicted in FIGS. 45, 42, 44, and 47, in the 11th example, the position where the extending portion 161 protrudes from the wiring 160 is adjusted in accordance with the position of the diffusion region 210a functioning as the source of the switching transistor 35 on the circuit chip 42.

### (Layout Example and Cross-Sectional Structure Example of Circuit Chip)

In the 11th example, the reset transistor 32, the selection transistor 34, and the switching transistor 35 are disposed on the circuit chip 42. As depicted in FIGS. 46, 42, 44, and 47, the through electrode 132 connected to the amplification gate electrode 131 of the amplification transistor 33 penetrates the diffusion region 210a functioning as the source of the switching transistor 35. This causes the source of the switching transistor 35, the gate of the amplification transistor 33, and the floating diffusion regions FD1 and FD2 to be short-circuited via the through electrodes 103, 107, and 132 and the wiring 160 including the extending portion 161. Similarly, the drain (diffusion region 210a) of the reset transistor 32 is short-circuited to the drain (diffusion region 110) of the amplification transistor 33 via the through electrode 123. The through electrode 123 is connected to a power supply line that supplies the power supply voltage VDD via the first metal wiring M1 in the upper layer. The drain (diffusion region 210a) of the selection transistor 34 is short-circuited to the source (diffusion region 110) of the amplification transistor 33 via the through electrode 124.

### (Conclusion of 11th Example)

Also in the 11th example, similarly to the fourth example, the number of elements and the number of pieces of wiring to be disposed on the circuit chip 42 can be reduced by disposing the amplification transistor 33 on the light receiving chip 41, which can reduce the wiring density of the circuit chip 42 to improve the device characteristics, and can decrease the degree of difficulty in designing the wiring layout of the circuit chip 42.

In addition, also in the 11th example, similarly to the fourth example, the number of necessary electrodes is further reduced by the drain of the amplification transistor 33 short-circuited to the drain of the reset transistor 32 via the through electrode 123 and the source of the amplification transistor 33 short-circuited to the drain of the selection transistor via the through electrode 124 in addition to the through electrode 132 connected to the gate of the amplification transistor 33 (amplification gate electrode 131) doubling as a through electrode connected to the source (diffusion region 210a) of the switching transistor 35. This can reduce the wiring density of the circuit chip 42 to further improve the device characteristics, and can further decrease the degree of difficulty in designing the wiring layout of the circuit chip 42.

### 1.7.12 12th Example

In a 12th example, similarly to the fifth example, a case where eight unit pixels 30 arranged in four rows and two columns share one floating diffusion region FD will be described. Note, however, that, in the 12th example, a case where two or more unit pixels 30 share one on-chip lens 51 and one color filter 52 will be described.

Incidentally, an FD shared circuit configuration example may be similar to the configuration described with reference to FIG. 21 in the fifth example. A C-C′ cross-sectional structure may be similar to the structure described with reference to FIG. 43 in the 10th example. A D-D′ cross-sectional structure may be similar to the structure described with reference to FIG. 44 in the 10th example. Thus, detailed description thereof will be omitted here. Note, however, that, in the 12th example, the switching transistor 35 in a pixel circuit is omitted.

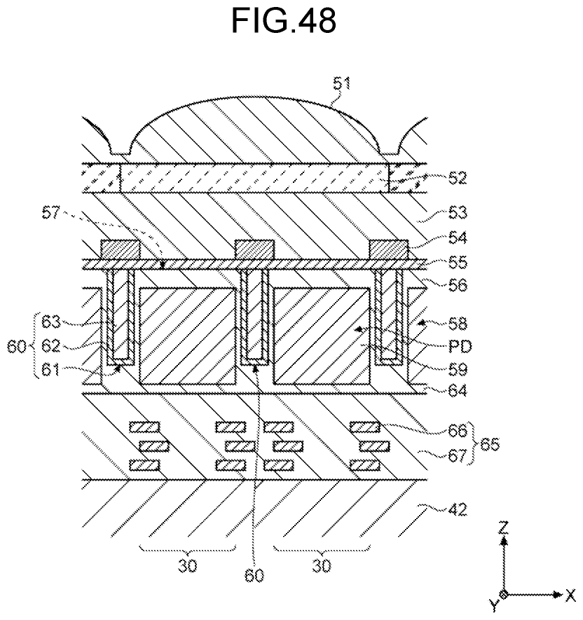

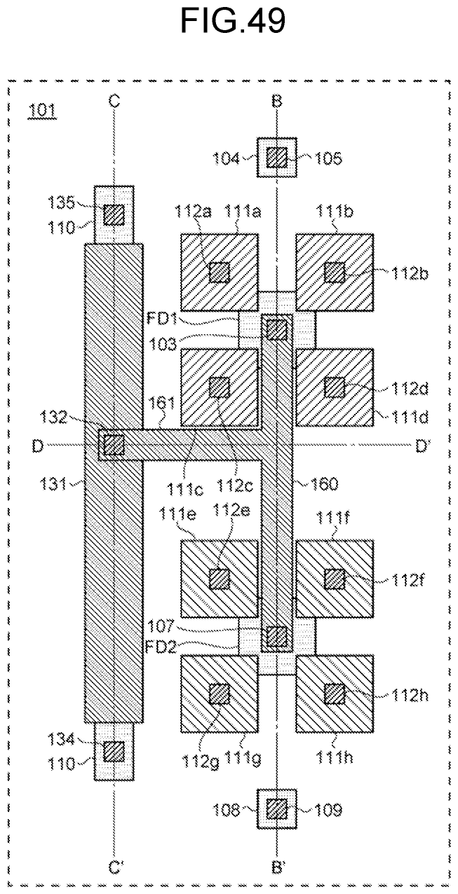

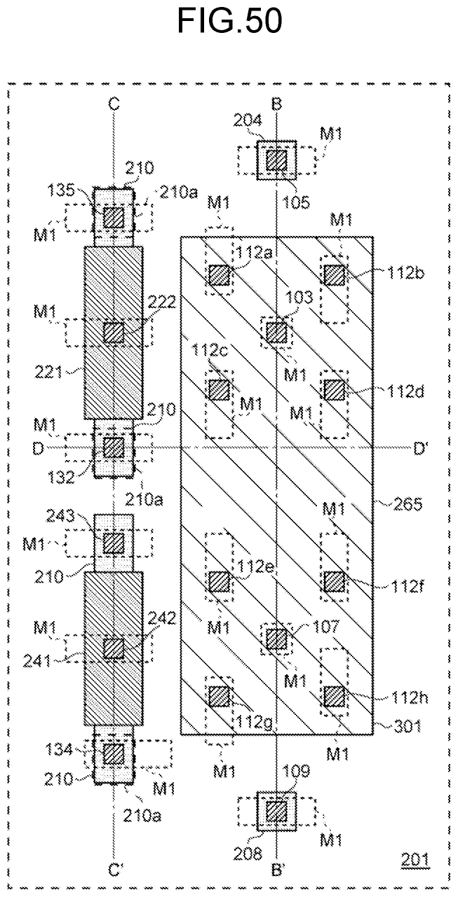

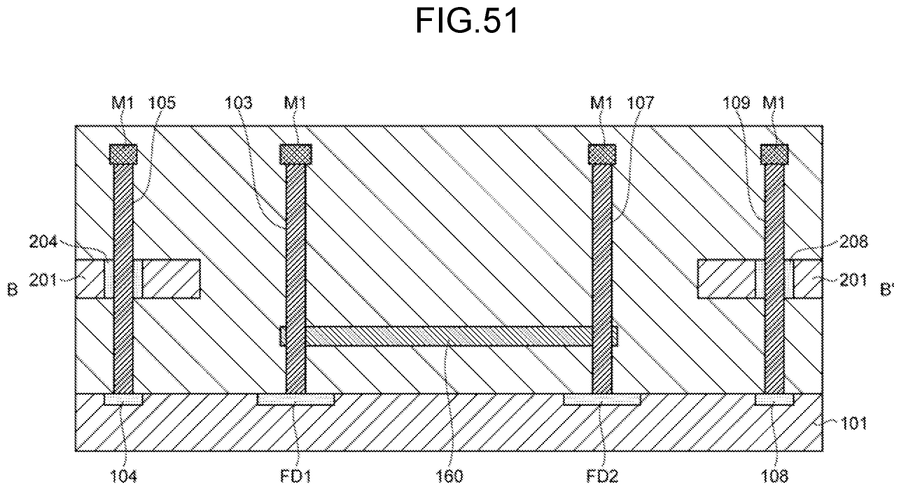

FIG. 48 is a cross-sectional view depicting a cross-sectional structure example of a unit pixel according to the 12th example. FIG. 49 is a plan view depicting a layout example of a light receiving chip according to the 12th example. FIG. 50 is a plan view depicting a layout example of a circuit chip according to the 12th example. FIG. 51 is a cross-sectional view depicting a structural example of a B-B′ cross section according to the 12th example. Incidentally, similarly to FIG. 5, FIG. 48 depicts a cross-sectional structure example of the light receiving chip 41 in which the photoelectric conversion unit PD of the unit pixel 30 is disposed.

### (Cross-Sectional Structure Example of Unit Pixel)

As depicted in FIG. 48, in the 12th example, one on-chip lens 51 and one color filter 52 are disposed so as to straddle two or more unit pixels 30 arranged in the row direction or the column direction. This causes the one on-chip lens 51 and the one color filter 52 to be shared in the two or more unit pixels 30 arranged in the row direction and the column direction.

### (Layout Example and Cross-Sectional Structure Example of Light Receiving Chip)

In the 12th example, similarly to the 10th example, the amplification transistor 33 is disposed on the light receiving chip 41 in addition to the photoelectric conversion units PDa to PDh and the transfer transistors 31a to 31h.

### (Layout Example and Cross-Sectional Structure Example of Circuit Chip)

In the 12th example, similarly to the 10th example, the reset transistor 32 and the selection transistor 34 are disposed on the circuit chip 42.

### (Conclusion of 12th Example)

Also in the 12th example, similarly to the fourth example, the number of elements and the number of pieces of wiring to be disposed on the circuit chip 42 can be reduced by disposing the amplification transistor 33 on the light receiving chip 41, which can reduce the wiring density of the circuit chip 42 to improve the device characteristics, and can decrease the degree of difficulty in designing the wiring layout of the circuit chip 42.

In addition, also in the 12th example, similarly to the fourth example, the number of necessary electrodes is further reduced by the through electrode 132 connected to the gate of the amplification transistor 33 (amplification gate electrode 131) doubling a through electrode connected to the source (diffusion region 210a) of the reset transistor 32. This can reduce the wiring density of the circuit chip 42 to further improve the device characteristics, and can further decrease the degree of difficulty in designing the wiring layout of the circuit chip 42.

Incidentally, the configuration described in the 12th example in which one on-chip lens 51 and one color filter 52 are shared by two or more unit pixels 30 is suitable to, for example, a case where a color filter arrangement such as Quad Bayer (also referred to as Quadra) is adopted as arrangement of the color filter 52 and a case where the solid-state imaging device 10 has a mechanism of automatically adjusting a focus on the basis of the phase difference between adjacent pixels. Note, however, that these are not limitations.

### 1.7.13 13th Example

In a 13th example, similarly to the first example, a case where eight unit pixels 30 arranged in two rows and two columns share one floating diffusion region FD will be described. Note, however, that, in the 13th example, a case where a pixel isolation portion 170 having an FTI structure is adopted as the pixel isolation portion 60 that partitions the photoelectric conversion unit PD of each unit pixel 30 will be described.

Incidentally, since an FD shared circuit configuration example may be similar to the configuration described with reference to FIG. 6 in the first example, detailed description thereof will be omitted here.

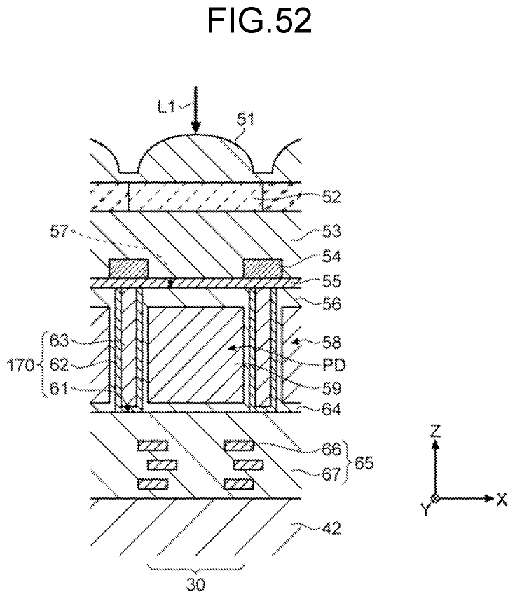

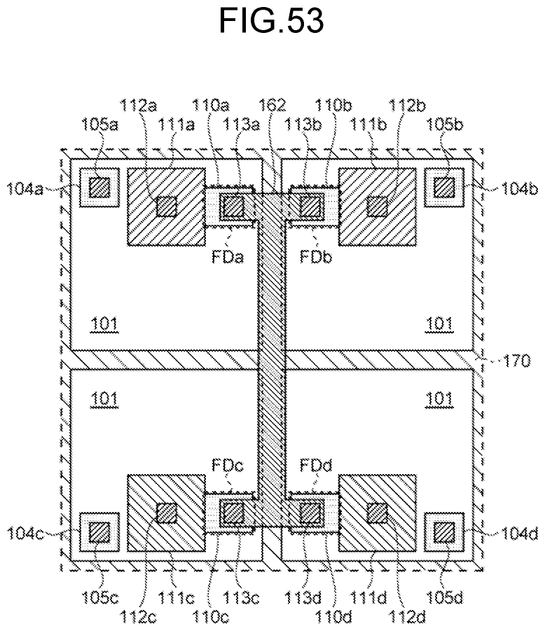

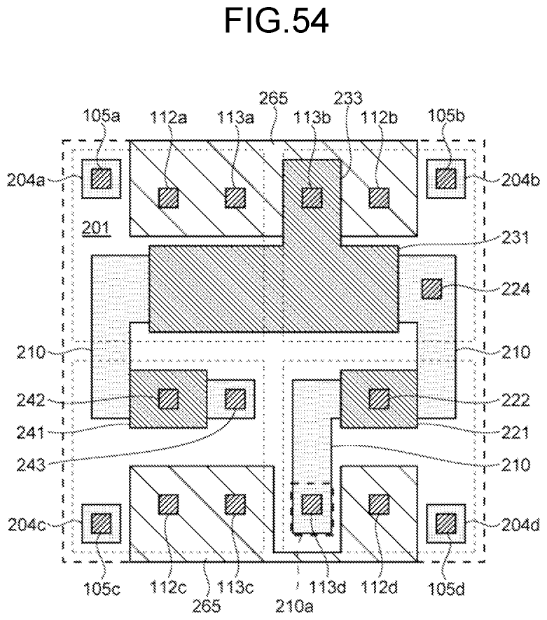

FIG. 52 is a cross-sectional view depicting a cross-sectional structure example of a unit pixel according to the 13th example. FIG. 53 is a plan view depicting a layout example of a light receiving chip according to the 13th example. FIG. 54 is a plan view depicting a layout example of a circuit chip according to the 13th example.

### (Cross-Sectional Structure Example of Unit Pixel)

As depicted in FIG. 52, in the 13th example, there is provided a structure in which the photoelectric conversion unit PD of each unit pixel 30 is partitioned by the pixel isolation portion 170 having the groove portion 61 penetrating the semiconductor substrate 58 (corresponding to semiconductor substrate 101) instead of the pixel isolation portion 60 having the RDTI structure depicted in FIG. 5.

### (Layout Example of Light Receiving Chip)

As depicted in FIG. 53, in the 13th example, similarly to the first example, the photoelectric conversion units PDa to PDd and the transfer transistors 31a to 31d are disposed on the light receiving chip 41. The photoelectric conversion units PDa to PDd and the transfer transistors 31a to 31d are disposed in regions (hereinafter, referred to as pixel regions) partitioned by the pixel isolation portion 170 in the semiconductor substrate 101.

In addition, diffusion regions 110a to 110d respectively functioning as drains of the transfer transistors 31a to 31d are provided in the pixel regions partitioned by the pixel isolation portion 170. The diffusion regions 110a to 110d also function as floating diffusion regions FDa to FDd. The floating diffusion regions FDa to FDd are short-circuited via wiring 162 and through electrodes 113a to 113d penetrating the wiring 162. In the 13th example, parasitic capacitances formed by the wiring 162 and the floating diffusion regions FDa to FDd with the semiconductor substrate 101 and/or the semiconductor substrate 201 function as capacitances of the floating diffusion regions FDa to FDd. The wiring 162 may include, for example, a conductive material such as polysilicon doped with impurities.

Incidentally, when a pixel region in which each of the photoelectric conversion units PDa to PDd is disposed is partitioned by the pixel isolation portion 170 having the FTI structure, contact portions 104a to 104d are provided in each pixel region, and the contact portions 104a to 104d are connected to the first metal wiring M1 via through electrodes 105a to 105d, so that the well potential of each pixel region is controlled.

### (Layout Example and Cross-Sectional Structure Example of Circuit Chip)

As depicted in FIG. 54, in the 13th example, the reset transistor 32, the amplification transistor 33, and the selection transistor 34 are disposed on the circuit chip 42. The amplification gate electrode 231 includes the extending portion 233 which any of the through electrodes 113a to 113d (through electrode 113b in FIG. 54) penetrates. The through electrode (through electrode 113b in FIG. 54) penetrating the extending portion 233 is connected to any of the floating diffusion regions FDa to FDd (floating diffusion region FDb in FIG. 53). In addition, any of the through electrodes 113a to 113d (through electrode 113d in FIG. 54) penetrates the diffusion region 210a functioning as the source of the reset transistor 32. This causes the source (diffusion region 210a) of the reset transistor 32, the gate of the amplification transistor 33 (amplification gate electrode 231), and the floating diffusion regions FDa to FDd to be short-circuited.

### (Conclusion of 13th Example)

As described above, similarly to the first example, the number of necessary electrodes is reduced and the number of pieces of wiring to be built in the wiring layer of the circuit chip 42 is reduced by short-circuiting each of the amplification gate electrode 231 of the amplification transistor 33 and the diffusion region 210a functioning as the source of the reset transistor 32 to the floating diffusion regions FDa to FDd via the through electrodes 113b and 113d. This can reduce the wiring density of the circuit chip 42 to improve the device characteristics, and can decrease the degree of difficulty in designing the wiring layout of the circuit chip 42.

### 1.7.14 14th Example

In a 14th example, similarly to the first example, a case where eight unit pixels 30 arranged in two rows and four columns share one floating diffusion region FD will be described. Incidentally, in the 14th example, a case will be described in which two unit pixels 30 arranged in the row direction share one on-chip lens 51 and one color filter 52 and a phase difference detection pixel for detecting a phase difference is formed between the two unit pixels 30.

Incidentally, since an FD shared circuit configuration example may be similar to the configuration described with reference to FIG. 21 in the fifth example, detailed description thereof will be omitted here. Note, however, that, in the 14th example, the switching transistor 35 in a pixel circuit is omitted.

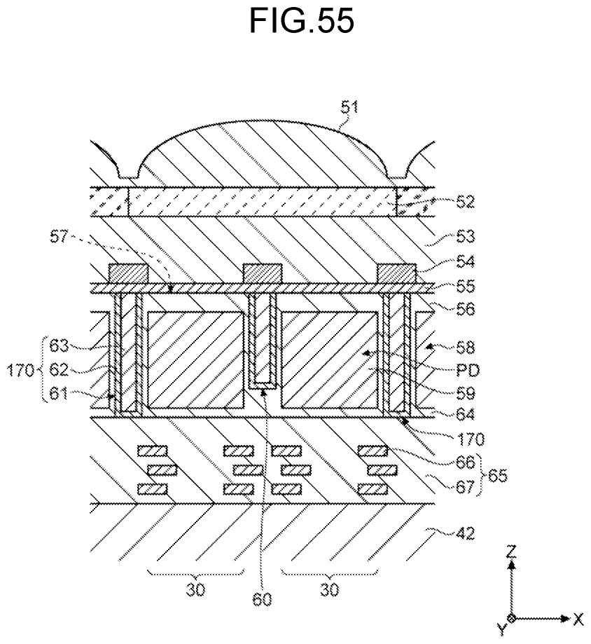

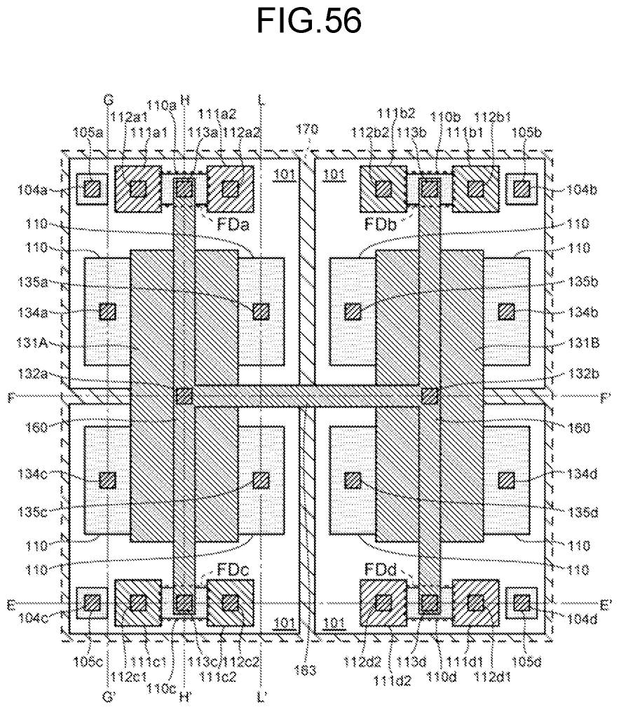

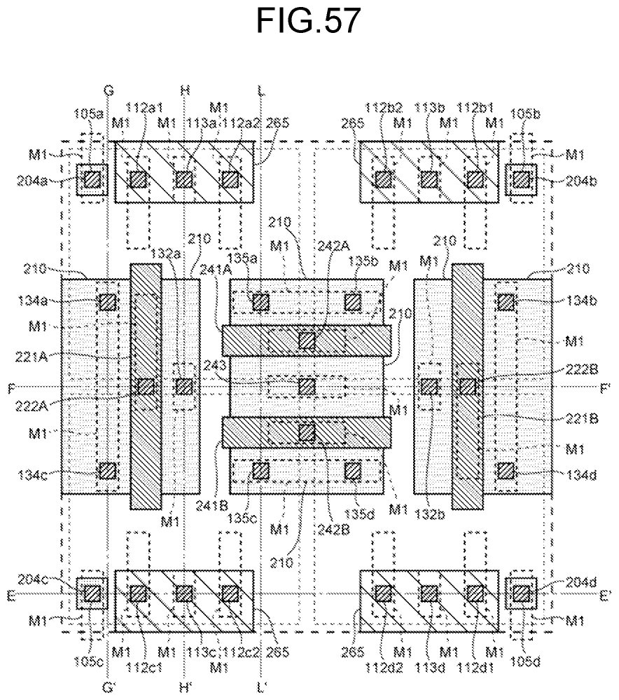

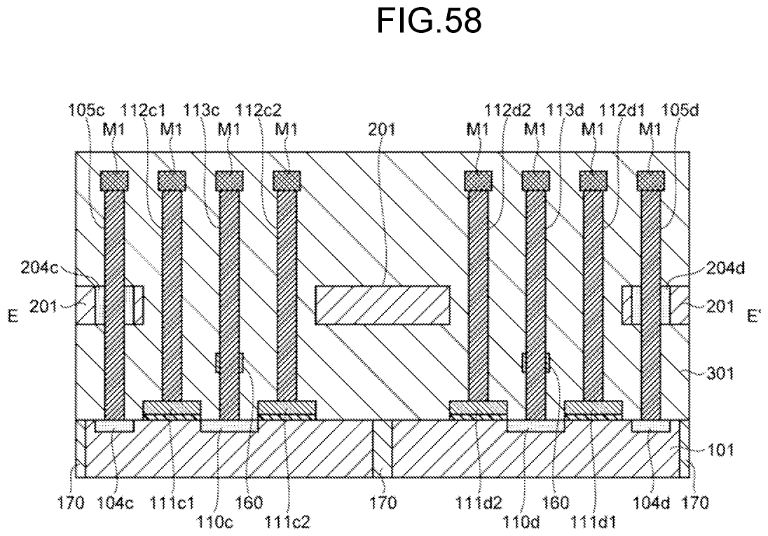

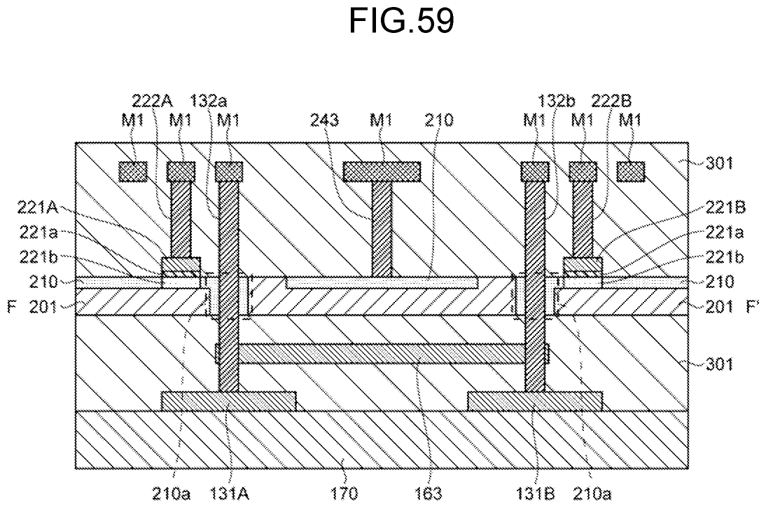

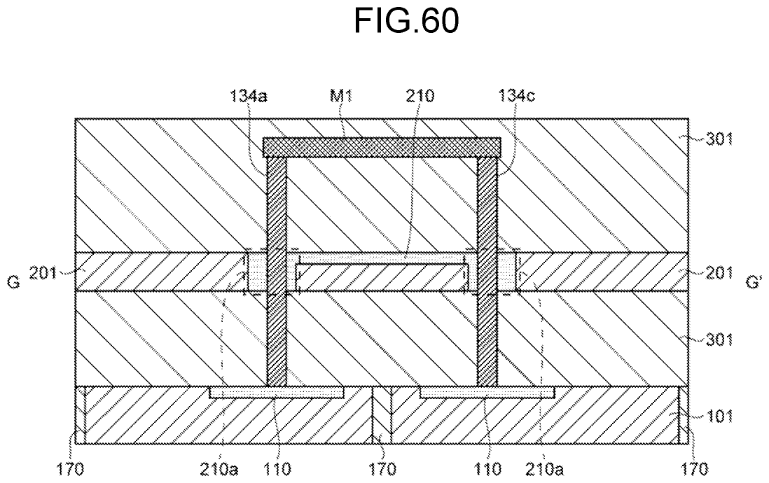

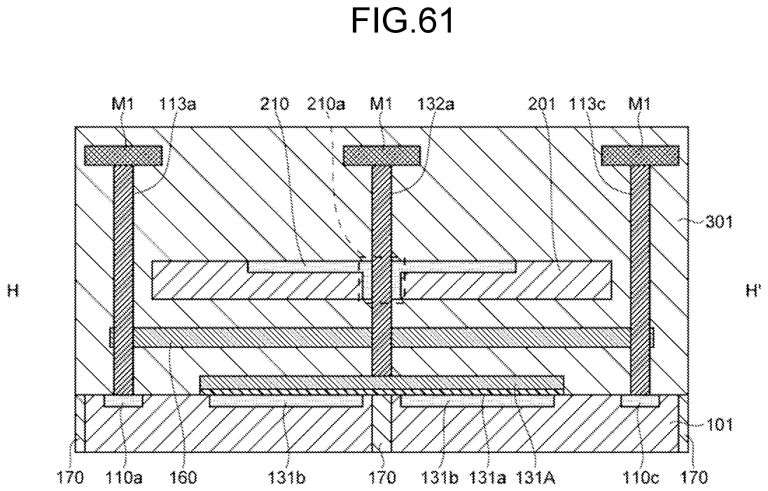

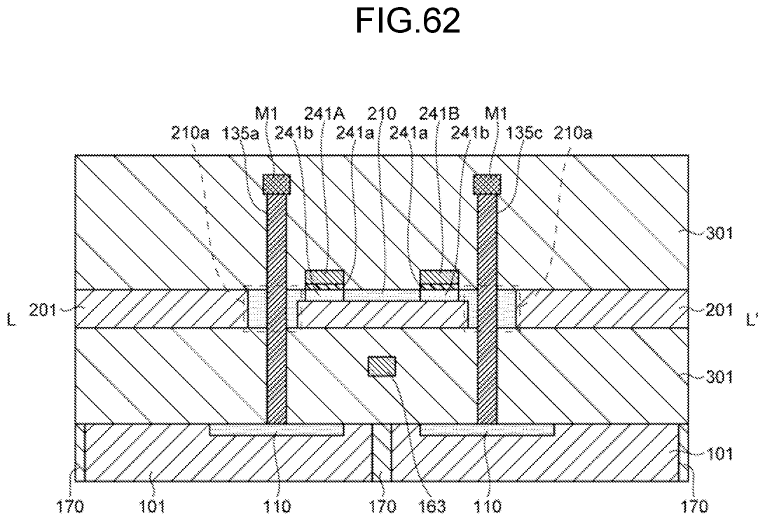

FIG. 55 is a cross-sectional view depicting a cross-sectional structure example of a unit pixel according to the 14th example. FIG. 56 is a plan view depicting a layout example of a light receiving chip according to the 14th example. FIG. 57 is a plan view depicting a layout example of a circuit chip according to the 14th example. FIG. 58 is a cross-sectional view depicting a structural example of an E-E′ cross section according to the 14th example. FIG. 59 is a cross-sectional view depicting a structural example of an F-F′ cross section according to the 14th example. FIG. 60 is a cross-sectional view depicting a structural example of a G-G′ cross section according to the 14th example. FIG. 61 is a cross-sectional view depicting a structural example of an H-H′ cross section according to the 14th example. FIG. 62 is a cross-sectional view depicting a structural example of an L-L′ cross section according to the 14th example.

### (Cross-Sectional Structure Example of Unit Pixel)

As depicted in FIG. 55, in the 14th example, in a structure similar to the cross-sectional structure of the unit pixel 30 described with reference to FIG. 48 in the 12th example, the pixel isolation portion that isolates the two unit pixels 30 sharing one on-chip lens 51 and one color filter 52 from each other is replaced with an RDTI type pixel isolation portion 60. Therefore, in the 14th example, an FTI type pixel isolation portion 170 partitions the region where the eight unit pixels 30 arranged in two rows and four columns are disposed into regions (hereinafter, also referred to as phase difference pixel regions) for respective phase difference detection pixels including two unit pixels 30 arranged in the row direction. The RDTI type pixel isolation portion 60 partitions the phase difference pixel regions into pixel regions for respective unit pixels 30.

### (Layout Example and Cross-Sectional Structure Example of Light Receiving Chip)

As depicted in FIGS. 56 and 58 to 62, in the 14th example, similarly to the 10th example, the photoelectric conversion units PDa to PDh, the transfer transistors 31a to 31h, and the amplification transistor 33 are disposed on the light receiving chip 41. Note, however, that, in the 14th example, an amplification gate electrode constituting the amplification transistor 33 is isolated into an amplification gate electrode 131A and an amplification gate electrode 131B. The diffusion region 110 functioning as a source and a drain is disposed in each of the amplification gate electrodes 131A and 131B.

Transfer gate electrodes 111a1, 111a2, 111b1, 111b2, 111c1, 111c2, 111d1, and 111d2 disposed in respective pixel regions are connected to the first metal wiring M1 via through electrodes 112a1, 112a2, 112b1, 112b2, 112c1, 112c2, 112d1, and 112d2, respectively.

Diffusion regions 110a, 110b, 110c, and 110d functioning as the drains of the transfer transistors 31a to 31h are respectively disposed between a pair of transfer gate electrodes 111al and 111a2, a pair of transfer gate electrodes 111b1 and 111b2, a pair of transfer gate electrodes 111cl and 111c2, and a pair of transfer gate electrodes 111d1 and 111d2, which are disposed in respective phase difference pixel regions. The diffusion regions 110a, 110b, 110c, and 110d are respectively shared between transfer transistors 31a and 31b, transfer transistors 31c and 31d, transfer transistors 31e and 31f, and transfer transistors 31g and 31h, which are formed in the same phase difference pixel region. The diffusion regions 110a, 110b, 110c, and 110d also function as the floating diffusion regions FDa to FDd.

The diffusion regions 110a, 110b, 110c, and 110d are connected to the first metal wiring M1 via the through electrodes 113a, 113b, 113c, and 113d. The amplification gate electrodes 131A and 131B are connected to the first metal wiring M1 via through electrodes 132a and 132b.

In addition, the through electrodes 113a, 113b, 113c, 113d, 132a, and 132b are short-circuited via the wiring 160 and wiring 163. The above-described configuration enables FDa, FDb, FDc, and FDd and the amplification gate electrodes 131A and 131B to be short-circuited.

Incidentally, the contact portions 104a to 104d are provided in respective phase difference pixel regions, and the contact portions 104a to 104d are connected to the first metal wiring M1 via through electrodes 105a to 105d, so that the well potential of each pixel region is controlled.

### (Layout Example and Cross-Sectional Structure Example of Circuit Chip)

As depicted in FIGS. 57 to 62, in the 14th example, the reset transistor 32 and the selection transistor 34 are disposed on the circuit chip 42. Note, however, that, in the 14th example, a reset gate electrode constituting the reset transistor 32 is isolated into a reset gate electrode 221A and a reset gate electrode 221B. The diffusion regions 210 and 210a functioning as a source and a drain are disposed in the reset gate electrodes 221A and 221B. In addition, a selection gate electrode constituting the selection transistor 34 is isolated into a selection gate electrode 241A and a selection gate electrode 241B. The diffusion regions 210 and 210a functioning as a source and a drain are disposed in the selection gate electrodes 241A and 241B.

The diffusion region 210a, which is isolated into two regions, functioning as the source of the reset transistor 32 is connected to the first metal wiring M1 via the through electrodes 132a and 132b connected to the amplification gate electrodes 131A and 131B. That is, the through electrodes 132a and 132b connected to the amplification gate electrodes 131A and 131B double through electrodes connecting the source of the reset transistor 32 to the first metal wiring M1. This causes the source of the reset transistor 32, the gate of the amplification transistor 33, and the floating diffusion regions FDa to FDd to be short-circuited.

In addition, the diffusion regions 210 and 210a, which are isolated into two regions, functioning as the drains of the reset transistor 32 are connected to the first metal wiring M1 via through electrodes 134a to 134d connected to the diffusion regions 110 functioning as the drain of the amplification transistor 33. That is, the through electrodes 134a to 134d connected to the drain of the amplification transistor 33 double through electrodes connecting the drain of the reset transistor 32 to the first metal wiring M1.

Further, the diffusion region 210a, which is isolated into two regions, functioning as the drain of the selection transistor 34 is connected to the first metal wiring M1 via through electrodes 135a to 135d connected to the diffusion region 110 functioning as source of the amplification transistor 33. That is, the through electrodes 135a to 135d connected to the source of the amplification transistor 33 double through electrodes connecting the drain of the selection transistor 34 to the first metal wiring M1.

### (Conclusion of 14th Example)

Also in the 14th example, similarly to the fourth example, the number of elements and the number of pieces of wiring to be disposed on the circuit chip 42 can be reduced by disposing the amplification transistor 33 on the light receiving chip 41, which can reduce the wiring density of the circuit chip 42 to improve the device characteristics, and can decrease the degree of difficulty in designing the wiring layout of the circuit chip 42.

In addition, also in the 14th example, similarly to the fourth example, the number of necessary electrodes is further reduced by the through electrodes 132a and 132b connected to the gate of the amplification transistor 33 (amplification gate electrodes 131A and 131B) doubling a through electrode connected to the source (diffusion region 210a) of the reset transistor 32, the through electrodes 134a to 134d connected to the drain of the amplification transistor 33 doubling a through electrode connected to the drain of the reset transistor 32, and the through electrodes 135a to 135d connected to the source of the amplification transistor 33 doubling a through electrode connected to the drain of the selection transistor 34. This can reduce the wiring density of the circuit chip 42 to further improve the device characteristics, and can further decrease the degree of difficulty in designing the wiring layout of the circuit chip 42.

### 1.8 Conclusion

As described above, according to the present embodiment, the amplification gate electrodes 231/131 are electrically connected to the through electrodes 103/107 connected to the floating diffusion region FD via the pieces of wiring 133/160 (and 161 or 163)/162 provided in the extending portion 233 extending from the amplification gate electrode 231 or the light receiving chip 41 or the first metal wiring M1 in the upper layer. This can reduce the number of electrodes and/or the number of pieces of wiring to be disposed on the circuit chip 42, so that the wiring density can be reduced. As a result, a parasitic capacitance caused by the wiring can be reduced, so that the device characteristics can be improved. In addition, reducing the wiring density can decrease the degree of difficulty in designing the wiring layout.

### 2. Second Embodiment

Next, a second embodiment of the present disclosure will be described in detail with reference to the drawings.

Incidentally, in the following description, configurations, operations, and effects similar to those of the above-described embodiment or variations thereof are cited, and redundant description thereof will be omitted.

Not just in the solid-state imaging device described in the above-described first embodiment but in a common solid-state imaging device, in order to improve the device characteristics, it is important to reduce a capacitance of coupling of wiring connected to an amplification gate electrode and the floating diffusion region FD (hereinafter, also referred to as FD wiring) and another piece of wiring (for example power supply line (hereinafter, also referred to as VDD wiring) and wiring connected to reset gate electrode (hereinafter, also referred to as RST control line)). In addition, since the FD wiring and the amplification gate electrodes 231/131 are electrically short-circuited, reduction in the capacitance of coupling of an amplification gate electrode and another piece of wiring is similarly important.

In contrast, in the 3D sequential structure, the proportion of an area of an amplification gate electrode in a pixel region tends to be larger than that in a conventional structure. Thus, there is a problem that the capacitance of coupling of an amplification gate electrode and another piece of wiring easily increases as compared to that in the conventional structure.

Capacitance coupling between an amplification gate electrode and another piece of wiring can be prevented by shielding the peripheries of the FD wiring and the amplification gate electrode with a ground line and VSS wiring (hereinafter, collectively referred to as VSS wiring). In recent years, however, design of the VSS wiring for shielding has become difficult with miniaturization of pixels.

Therefore, in the second embodiment, similarly to the first embodiment, a solid-state imaging device and an electronic device capable of inhibiting deterioration in device characteristics and an increase in the degree of difficulty in design will be described with an example.

More specifically, in the present embodiment, there is proposed a structure in which at least a part of an amplification gate electrode and FD wiring is covered with a conductive shield electrode. In the case, an insulating film is disposed between the amplification gate electrode and the FD wiring and the shield electrode in order to avoid an electrical short circuit therebetween. In addition, the shield electrode is connected to the VSS wiring. Such a structure can reduce a capacitance of coupling formed by the amplification gate electrode and the FD wiring with another piece of wiring, so that the wiring density is reduced. This reduces a parasitic capacitance caused by the wiring, so that deterioration in the device characteristics and an increase in the degree of difficulty in designing the wiring layout can be inhibited.

Incidentally, the configuration of the electronic device (see FIG. 1) according to the present embodiment, the configuration (see FIG. 2) and the stacked structure (see FIG. 4) of the solid-state imaging device, the configuration and the basic function of a unit pixel (see, for example, FIGS. 3, 6, and 21), and the cross-sectional structure (see, for example, FIGS. 5, 48, 52, and 55) may be similar to those in the above-described first embodiment.

### 2.1 Examples of Chip Layout and Cross-Sectional Structure

Subsequently, chip layouts of the light receiving chip 41 and the circuit chip 42 according to the present embodiment and a cross-sectional structure of a stacked chip obtained by bonding the light receiving chip 41 and the circuit chip 42 will be described in some examples. Incidentally, in the following description, similarly to the first embodiment, depiction of the photoelectric conversion unit PD formed on the semiconductor substrate 58 (corresponding to semiconductor substrate 101 to be described later) and the pixel isolation portion 60 (see FIG. 5) that partitions the photoelectric conversion unit PD is appropriately omitted. In addition, in the following description, detailed description of a configuration similar to that in the previously described example (including first embodiment) will be omitted in the following example.

### 2.1.1 First Example

In a first example, a case where eight unit pixels 30 arranged in two rows and four columns share one floating diffusion region FD will be described. In addition, a circuit configuration described with reference to FIG. 21 in the first embodiment will be cited as the circuit configuration of the unit pixel 30.

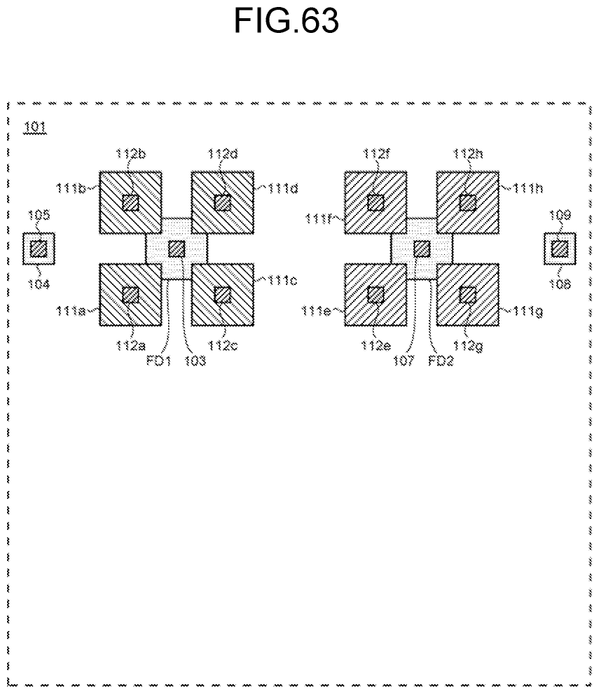

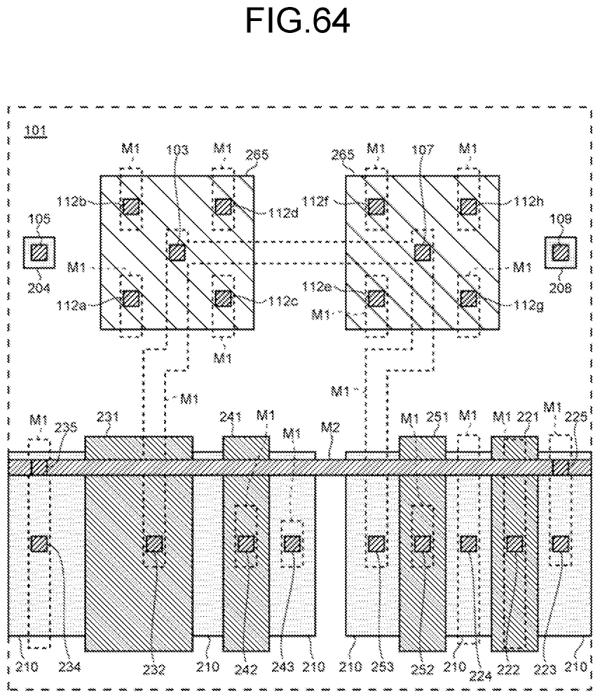

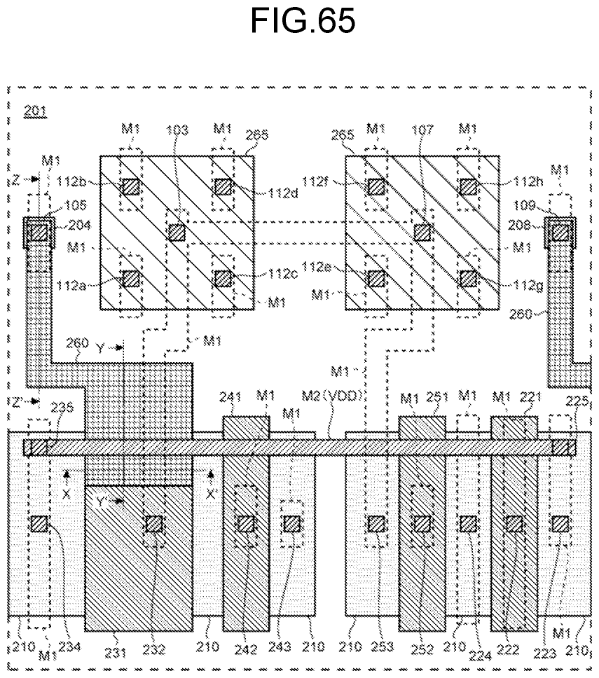

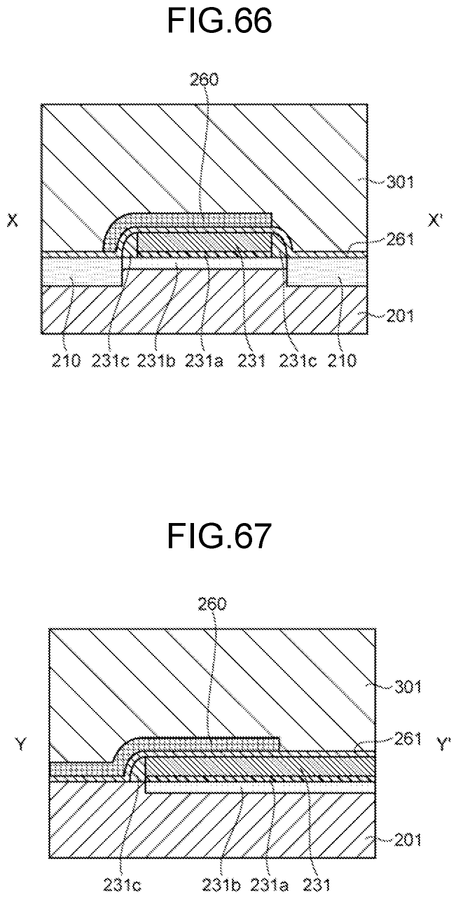

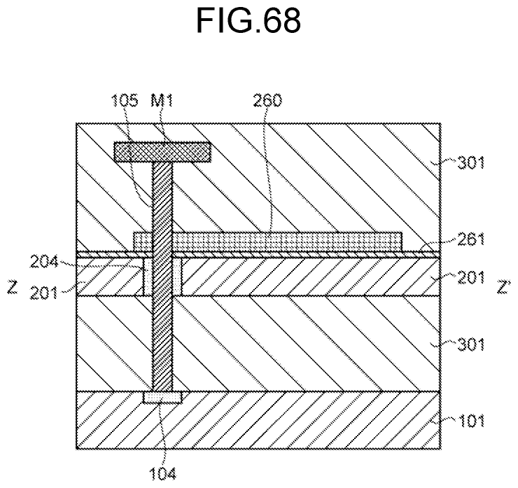

FIG. 63 is a plan view depicting a layout example of a light receiving chip according to the first example. FIG. 64 is a plan view depicting a layout example of a circuit chip according to a comparative example. FIG. 65 is a plan view depicting a layout example of a circuit chip according to the first example. FIG. 66 is a partial cross-sectional view depicting a partial structural example of an X-X′ cross section according to the first example. FIG. 67 is a partial cross-sectional view depicting a partial structural example of a Y-Y′ cross section according to the first example. FIG. 68 is a cross-sectional view depicting a structural example of a 2-2′ cross section according to the first example.

### (Layout Example of Light Receiving Chip)

In the first example, the photoelectric conversion units PDa to PDh and the transfer transistors 31a to 31h are disposed on the light receiving chip 41. As depicted in FIG. 63, the layout example of the light receiving chip 41 according to the first example may be similar to that described with reference to FIG. 22 in the fifth example of the first embodiment. Note, however, that, in FIG. 63, for convenience of description, the layout example depicted in FIG. 22 is rotated by 90 degrees (90 degrees in left direction in FIG. 63).

### (Layout Example of Circuit Chip According to Comparative Example)

In the comparative example, the reset transistor 32, the amplification transistor 33, the selection transistor 34, and the switching transistor 35 are disposed on the circuit chip 42. As depicted in FIG. 64, a planar layout example of the circuit chip 42 according to the comparative example may be similar to that described with reference to FIG. 23 in the fifth example of the first embodiment. Note, however, that, in the first example, the extending portion 233 extending from the amplification gate electrode 231 is omitted, and instead, the gate of the amplification transistor 33 (amplification gate electrode 231), the floating diffusion regions FD1 and FD2, the source (diffusion region 210) of the switching transistor 35 are connected via the through electrodes 103 and 107 and the first metal wiring M1. In addition, in FIG. 64, the gate widths of the reset transistor 32, the amplification transistor 33, the selection transistor 34, and the switching transistor 35 are enlarged. Further, in FIG. 64, for convenience of description, the layout example depicted in FIG. 23 is rotated by 90 degrees (90 degrees in left direction in FIG. 64).

In such a layout example, as depicted in FIG. 64, for example, second metal wiring M2 in the upper layer of the first metal wiring M1 overlaps the amplification gate electrode 231 in the substrate thickness direction. The second metal wiring M2 is connected to the diffusion region 210 functioning as the drain of the amplification transistor 33 via the contact plug 234, the first metal wiring M1, and a via hole 235, and is connected to the diffusion region 210 functioning as the drain of the reset transistor 32 via the contact plug 223, the first metal wiring M1, and a via hole 225. Therefore, the second metal wiring M2 is VDD wiring.

When the second metal wiring M2 which is VDD wiring overlaps the amplification gate electrode 231 in this manner, the capacitance of coupling of the amplification gate electrode 231 and the second metal wiring M2 increases as described above. As a result, image quality is degraded. In contrast, design while inhibiting the capacitance of coupling of the second metal wiring M2 and the amplification gate electrode 231 leads to an increase in the wiring density of another portion, which increases the degree of difficulty in design.

### (Layout Example of Circuit Chip According to First Example)

Therefore, in the first example, as depicted in FIG. 65, a shield electrode 260 is interposed between the second metal wiring M2 and the amplification gate electrode 231. The shield electrode 260 covers at least a part of a region in which the second metal wiring M2 overlaps the amplification gate electrode 231 in the substrate thickness direction. The shield electrode 260 may include, for example, a conductive material such as polysilicon doped with impurities.

The shield electrode 260 is connected to, for example, the through electrode 105 (or through electrode 109) connected to the VSS wiring to be maintained at a potential lower than a power supply potential (for example, ground potential or VSS potential). This can inhibit the capacitance of coupling of the amplification gate electrode 231 and the second metal wiring M2, so that deterioration in the device characteristics can be inhibited. Incidentally, the layout example of the circuit chip 42 according to the first example may be similar to the comparative example in FIG. 64 in a portion except for the shield electrode 260.

### (Cross-Sectional Structure Example of Shield Electrode)

As depicted in FIGS. 66 to 68, the amplification transistor 33 formed on the semiconductor substrate 201 includes, for example, the gate insulating film 231a, the amplification gate electrode 231, and a pair of diffusion regions 210 (source/drain). The gate insulating film 231a covers a part of the surface of the semiconductor substrate 201. The amplification gate electrode 231 is disposed above the gate insulating film 231a. The pair of diffusion regions 210 sandwich the channel formation region 231b below the amplification gate electrode 231. A sidewall 231c may be provided on the side surface of the amplification gate electrode 231. The sidewall 231c secures the distance between the diffusion regions 210 functioning as a source and a drain and the amplification gate electrode 231. The sidewall 231c may be, for example, an insulating film such as a silicon oxide film. Incidentally, such a transistor structure may also be applied to the reset transistor 32, the selection transistor 34, and the switching transistor 35.

An insulating film 261 covers a region, in which at least the shield electrode 260 is to be formed, on the upper surface of the semiconductor substrate 201 on which the amplification transistor 33 is formed. This prevents the shield electrode 260 from being short-circuited to the semiconductor substrate 201 and the amplification transistor 33.

### (Conclusion of First Example)

As described above, the capacitance of coupling of the amplification gate electrode 231 and the VDD wiring is inhibited by covering at least a part of a region in which the second metal wiring M2 overlaps the amplification gate electrode 231 in the substrate thickness direction with the shield electrode 260 maintained at the ground potential or the VSS potential. As a result, an increase in noise is inhibited, and image quality can be improved. In addition, since the amplification gate electrode 231 is shielded from the VDD wiring without using metal wiring, the wiring density of the circuit chip is reduced as compared to that in a conventional structure, and the degree of difficulty in designing the wiring layout can be decreased.

### (Variation of First Example)

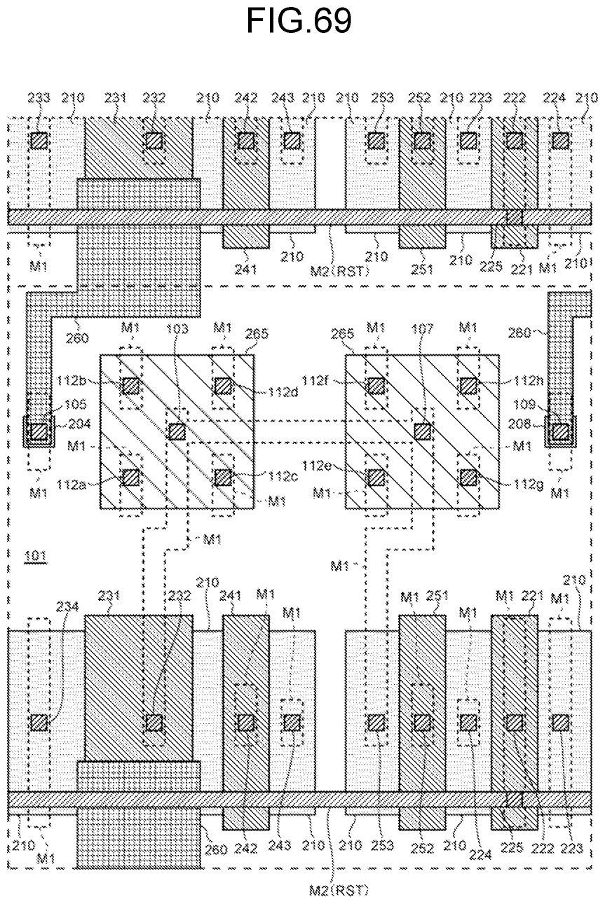

FIG. 69 is a plan view depicting a layout example of a circuit chip according to a variation of the first example. In the above-described first example, a case where the capacitance coupling between the VDD wiring and the amplification gate electrode 231 is inhibited has been described. Note, however, that an inhibition target of the capacitance coupling is not limited to the VDD wiring and the amplification gate electrode 231. For example, as depicted in FIG. 69, the shield electrode 260 may be disposed so as to inhibit the capacitance coupling between the second metal wiring M2 connected to the reset gate electrode 221 and the amplification gate electrode 231. In that case, the shield electrode 260 is provided between the second metal wiring M2 and the amplification gate electrode 231. The shield electrode 260 covers at least a part of a region in which the second metal wiring M2 overlaps the amplification gate electrode 231 in the substrate thickness direction. This inhibits the capacitance coupling between the amplification gate electrode 231 and the second metal wiring M2 connected to the reset gate electrode 221, so that the parasitic capacitance caused by the capacitance coupling of the wiring decreases. As a result, the device characteristics can be improved, and the degree of difficulty in designing the wiring layout can be decreased.

Incidentally, although, in the first example, a case has been described in which the shield electrode 260 disposed to the amplification gate electrode 231 shared by eight unit pixels 30 (hereinafter, referred to as shared pixel group) sharing the floating diffusion region FD is connected to the through electrodes 105/109 for controlling the well potential of the shared pixel group, the connection destination of the shield electrode 260 is not limited thereto. For example, as depicted in FIG. 69, the shield electrode 260 may be connected to the through electrodes 105/109 for controlling the well potentials of adjacent shared pixel groups.

### 2.1.2 Second Example

In a second example, a case where four unit pixels 30 arranged in two rows and two columns share one floating diffusion region FD will be described. In addition, a circuit configuration described with reference to FIG. 6 in the first embodiment will be cited as the circuit configuration of the unit pixel 30.

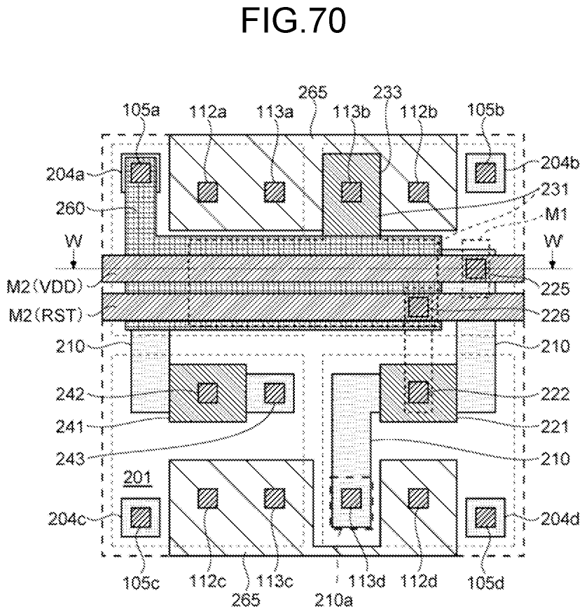

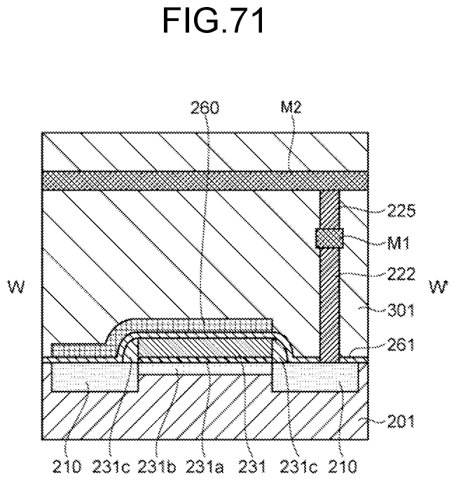

FIG. 70 is a plan view depicting a layout example of a circuit chip according to the second example. FIG. 71 is a cross-sectional view depicting a structural example of a W-W′ cross section according to the second example. Incidentally, the layout example of the light receiving chip 41 according to the second example may be similar to the layout example described with reference to FIG. 53 in the 13th example of the first embodiment.

### (Layout Example of Circuit Chip)

In the second example, the reset transistor 32, the amplification transistor 33, and the selection transistor 34 are disposed on the circuit chip 42. As depicted in FIG. 70, in the layout example of the circuit chip 42 according to the second example, in a layout similar to the layout example described with reference to FIG. 54 in the 13th example of the first embodiment, the second metal wiring M2 (VDD) serving as VDD wiring and the second metal wiring M2 (RST) connected to the reset gate electrode 221 are provided on the amplification gate electrode 231.

Therefore, in the second example, in the substrate thickness direction, the shield electrode 260 is disposed so as to cover at least a part of a region in which the amplification gate electrode 231 overlaps the second metal wiring M2 (VDD) and/or M2 (RST). Incidentally, the second metal wiring M2 (VDD) is connected to the first metal wiring M1 short-circuited to the diffusion region 210 functioning as the drain of the reset transistor 32 via the via hole 225. The second metal wiring M2 (RST) is connected to the first metal wiring M1 short-circuited to the reset gate electrode 221 via a via hole 226.

The shield electrode 260 is connected to any one or more of the through electrodes 105a to 105d (in FIG. 70, through electrode 105a) to be maintained at a potential lower than the power supply potential (for example, ground potential or VSS potential). This can inhibit the capacitance coupling between the amplification gate electrode 231 and the second metal wiring M2 (VDD) and/or M2 (RST), so that deterioration in the device characteristics can be inhibited.

### (Cross-Sectional Structure Example of Shield Electrode)

As depicted in FIG. 71, the shield electrode 260 is disposed on the amplification gate electrode 231 via the insulating film 261 so as to cover at least a part of the amplification gate electrode 231. A region where the shield electrode 260 is disposed may be correspond to at least a part of the region in which the amplification gate electrode 231 overlaps the second metal wiring M2 (VDD) and/or M2 (RST).

### (Conclusion of Second Example)

As described above, the capacitance coupling between the amplification gate electrode 231 and the VDD wiring and/or reset gate electrode 221 is inhibited by covering at least a part of a region in which the second metal wiring M2 (VDD) and/or M2 (RST) overlaps the amplification gate electrode 231 in the substrate thickness direction with the shield electrode 260 maintained at the ground potential or the VSS potential. This reduces a parasitic capacitance caused by the capacitance coupling between the pieces of wiring, so that the device characteristics can be improved, and the degree of difficulty in designing the wiring layout can be decreased.

### 2.1.3 Third Example

In a third example, a case where four unit pixels 30 arranged in two rows and two columns share one floating diffusion region FD will be described. In addition, a circuit configuration described with reference to FIG. 6 in the first embodiment will be cited as the circuit configuration of the unit pixel 30.

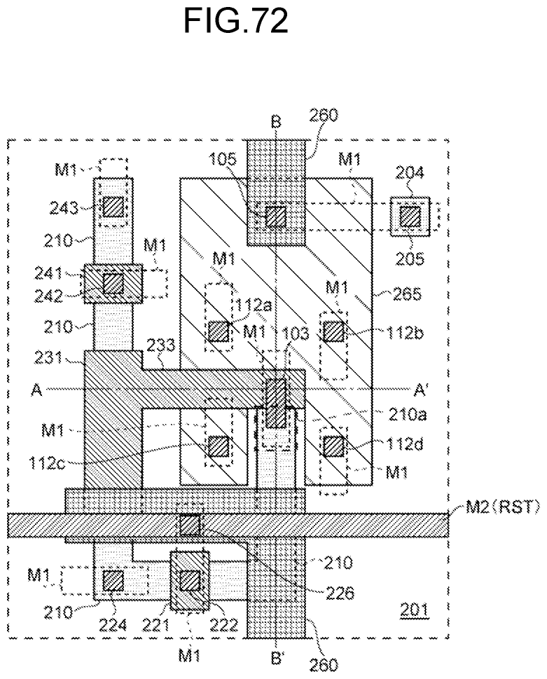

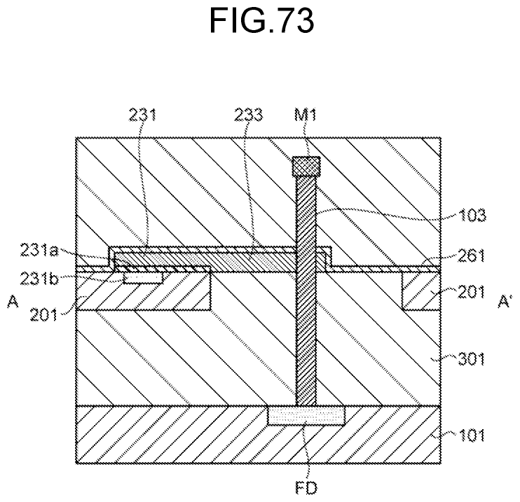

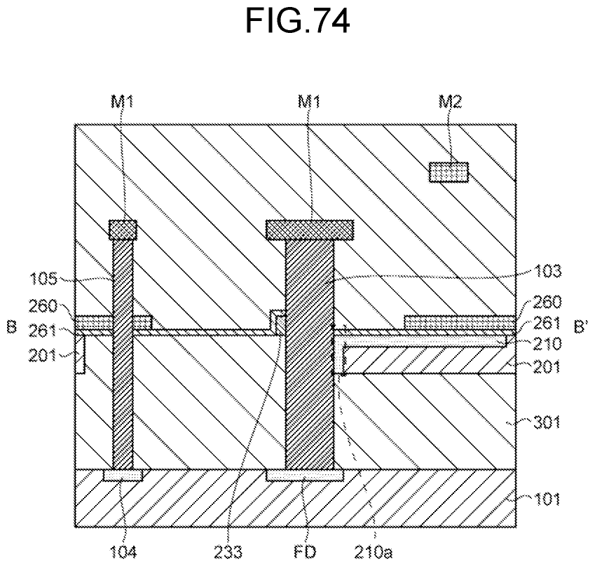

FIG. 72 is a plan view depicting a layout example of a circuit chip according to the third example. FIG. 73 is a cross-sectional view depicting a structural example of an A-A′ cross section according to the third example. FIG. 74 is a cross-sectional view depicting a structural example of a B-B′ cross section according to the third example. Incidentally, the layout example of the light receiving chip 41 according to the third example may be similar to the layout example described with reference to FIG. 7 in the first example of the first embodiment.

### (Layout Example and Cross-Sectional Structure Example of Circuit Chip)

In the third example, the reset transistor 32, the amplification transistor 33, and the selection transistor 34 are disposed on the circuit chip 42. As depicted in FIGS. 72 to 74, in the layout example of the circuit chip 42 according to the third example, in a layout similar to the layout example described with reference to FIG. 14 in the third example of the first embodiment, the second metal wiring M2 (RST) connected to the reset gate electrode 221 is provided so as to straddle the diffusion region 210 (corresponding to FD wiring) functioning as the source of the reset transistor 32 and the amplification gate electrode 231.

Therefore, in the third example, in the substrate thickness direction, the shield electrode 260 is disposed so as to cover at least a part of a region in which the diffusion region 210 and/or the amplification gate electrode 231 overlaps the second metal wiring M2 (RST). The shield electrode 260 is connected to the through electrode 105 for controlling the well potential of the adjacent shared pixel groups to be maintained at a potential lower than the power supply potential (for example, ground potential or VSS potential). This can inhibit the capacitance coupling between the diffusion region 210 and/or the amplification gate electrode 231 and the second metal wiring M2 (RST), so that deterioration in the device characteristics can be inhibited.

### (Conclusion of Third Example)

As described above, the capacitance coupling between the floating diffusion region FD and/or the amplification gate electrode 231 and the second metal wiring M2 (RST) connected to the reset gate electrode 221 is inhibited by covering at least a part of a region in which the diffusion region 210 and/or the amplification gate electrode 231 overlaps the second metal wiring M2 (RST) in the substrate thickness direction with the shield electrode 260 maintained at the ground potential or the VSS potential. This reduces a parasitic capacitance caused by the capacitance coupling between the pieces of wiring, so that the device characteristics can be improved, and the degree of difficulty in designing the wiring layout can be decreased.

### 2.2 Conclusion

As described above, according to the present embodiment, at least a part of the amplification gate electrode and the FD wiring is covered with the shield electrode 260 maintained at the ground potential or the VSS potential, so that capacitance coupling between the amplification gate electrode 231 and the FD wiring and another piece of wiring such as the second metal wiring M2 is inhibited. This reduces a parasitic capacitance caused by the capacitance coupling between the pieces of wiring, so that deterioration in the device characteristics and an increase in the degree of difficulty in designing the wiring layout can be inhibited.

### 3. Example of Application to Mobile Body

The technology according to the present disclosure (present technology) can be applied to various products. For example, the technology according to the present disclosure may be implemented as a device mounted in a mobile body of any type of an automobile, an electric vehicle, a hybrid electric vehicle, a motorcycle, a bicycle, a personal mobility, an airplane, a drone, a ship, a robot, and the like.

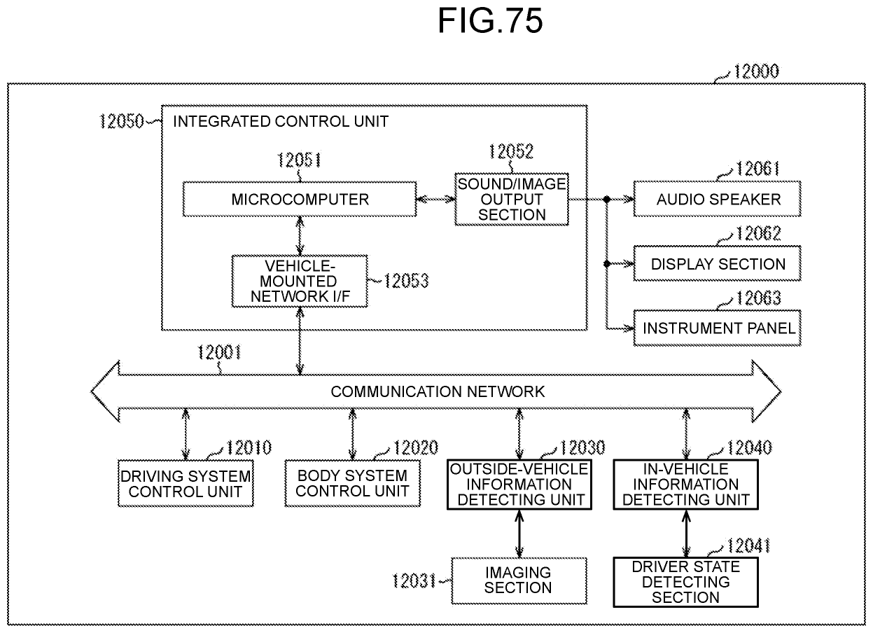

FIG. 75 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 75, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 75, an audio speaker 12061, a display section 12062, and an instrument panel 12063 are illustrated as the output device. The display section 12062 may, for example, include at least one of an on-board display and a head-up display.

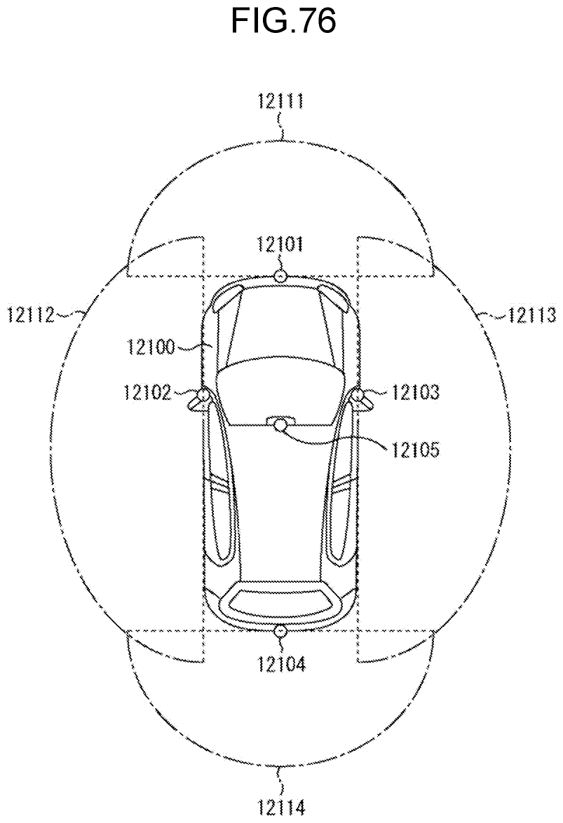

FIG. 76 is a diagram depicting an example of the installation position of the imaging section 12031.

In FIG. 76, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 76 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the above-described configurations. A more easily viewable captured image can be obtained by applying the technology according to the present disclosure to the imaging section 12031, so that fatigue of a driver can be mitigated.

### 4. Example of Application to Endoscopic Surgery System

The technology according to the present disclosure (present technology) can be applied to various products. For example, the technology according to the present disclosure may be applied to an endoscopic surgery system.

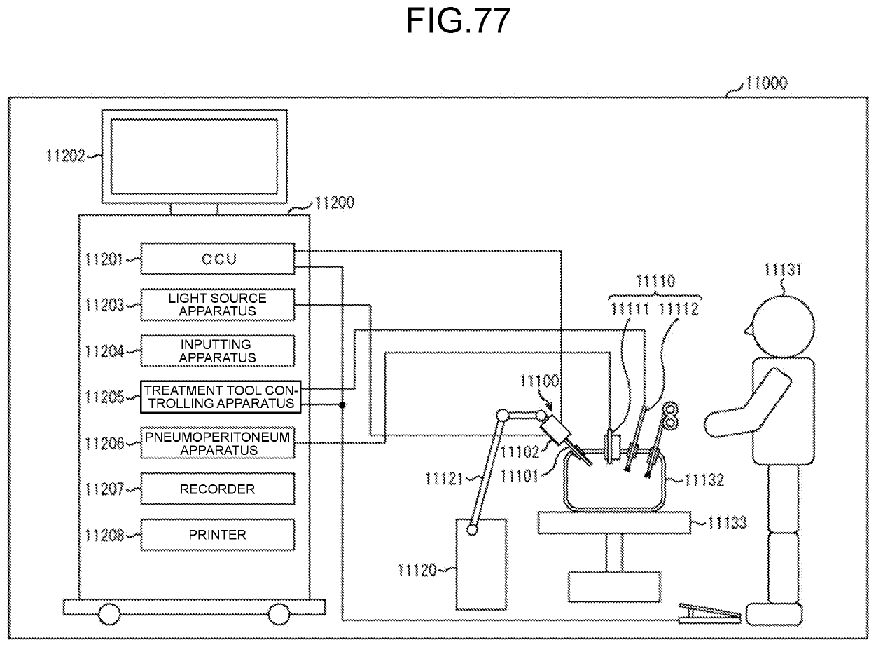

FIG. 77 is a view depicting an example of a schematic configuration of an endoscopic surgery system to which the technology according to an embodiment of the present disclosure (present technology) can be applied.

In FIG. 77, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

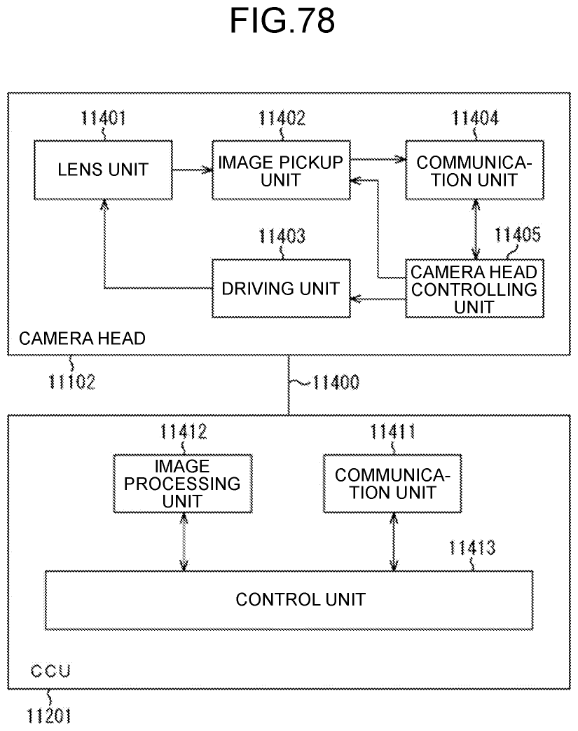

FIG. 78 is a block diagram depicting an example of a functional configuration of the camera head 11102 and the CCU 11201 depicted in FIG. 77.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to, for example, the image pickup unit 11402 of the camera head 11102 among the above-described configurations. A clearer image of a surgical region can be obtained by applying the technology according to the present disclosure to the camera head 11102, so that the surgeon can reliably confirm the surgical region.

Incidentally, although the endoscopic surgery system has been described here in one example, the technology according to the present disclosure may be applied to, for example, a microscopic surgery system.

Although the embodiments of the present disclosure have been described above, the technical scope of the present disclosure is not limited to the above-described embodiments as it is, and various modifications can be made without departing from the gist of the present disclosure. In addition, components of different embodiments and variations may be appropriately combined.

In addition, the effects in the embodiment described in the present specification are merely examples and not limitations. Other effects may be exhibited.

Incidentally, the present technology can also have the configurations as follows.

(1)

A solid-state imaging device including:
a first substrate including a photoelectric conversion unit that generates a charge by photoelectrically converting incident light;
a second substrate bonded to the first substrate and including at least a part of a pixel circuit that generates a voltage signal based on the charge generated at the photoelectric conversion unit; and
first metal wiring disposed on a side opposite to the first substrate with the second substrate sandwiched between the first substrate and the first metal wiring,
wherein the pixel circuit includes:
a charge accumulation unit that accumulates a charge generated at the photoelectric conversion unit;
an amplification transistor that converts the charge accumulated in the charge accumulation unit into a voltage of a voltage value in accordance with a charge amount of the charge;
a reset transistor that releases the charge accumulated in the charge accumulation unit;
a first through electrode that penetrates the second substrate from the first metal wiring to be connected to the charge accumulation unit; and
first wiring that connects a gate electrode of the amplification transistor with the first through electrode.
   (2)

The solid-state imaging device according to (1), wherein the first wiring is an extending portion extending from a gate electrode of the amplification transistor.

(3)

The solid-state imaging device according to (1),
wherein the pixel circuit further includes a second through electrode connected to a gate electrode of the amplification transistor, and
the first wiring connects the first through electrode with a second through electrode.
   (4)

The solid-state imaging device according to (3), wherein the amplification transistor is disposed on the first substrate.

(5)

The solid-state imaging device according to (1), wherein the first wiring includes a part of the first metal wiring.

(6)

The solid-state imaging device according to any one of (1) to (5),
wherein the pixel circuit further includes second wiring that connects a source of the reset transistor with the charge accumulation unit.
   (7)

The solid-state imaging device according to (6),
wherein the second wiring includes a part of the first metal wiring.
   (8)

The solid-state imaging device according to (6),
wherein the reset transistor is disposed on the second substrate, and
the second wiring is a second diffusion region continuous with a first diffusion region functioning as the source of the reset transistor.
   (9)

The solid-state imaging device according to (6),
wherein the amplification transistor is disposed on the first substrate,
the pixel circuit further includes a second through electrode connected to a gate electrode of the amplification transistor, and
the second wiring includes the second through electrode and at least a part of the first wiring.
   (10)

The solid-state imaging device according to any one of (1) to (9),
wherein the first substrate includes a plurality of photoelectric conversion units, and
the plurality of photoelectric conversion units is connected to the charge accumulation unit.
   (11)

The solid-state imaging device according to (10), wherein the pixel circuit further includes:
the plurality of charge accumulation units; and
third wiring that connects the plurality of charge accumulation units.
   (12)

The solid-state imaging device according to (11),
wherein the third wiring includes a part of the first metal wiring that connects first through electrodes connected to the plurality of charge accumulation units with each other.
   (13)

The solid-state imaging device according to (11),
wherein the third wiring includes fourth wiring that is provided on the first substrate and that connects the first through electrodes connected to the plurality of charge accumulation units with each other.
   (14)

An electronic device including:
the solid-state imaging device according to any one of (1) to (13); and
a processor that processes an image signal output from the solid-state imaging device.
   (15)

A solid-state imaging device including:
a photoelectric conversion unit that generates a charge by photoelectrically converting incident light; and
a pixel circuit that generates a voltage signal based on the charge generated at the photoelectric conversion unit,
wherein the photoelectric conversion unit is disposed on a first substrate,
at least a part of the pixel circuit is disposed on a second substrate bonded to the first substrate,
the pixel circuit includes:
a charge accumulation unit that accumulates a charge generated at the photoelectric conversion unit;
an amplification transistor that converts the charge accumulated in the charge accumulation unit into a voltage of a voltage value in accordance with a charge amount of the charge; and
a reset transistor that releases the charge accumulated in the charge accumulation unit,
the amplification transistor is disposed on the second substrate, and
the second substrate further includes:
second metal wiring disposed on a side opposite to the first substrate with the second substrate sandwiched between the first substrate and the second metal wiring; and
a shield electrode disposed at at least a part between the second metal wiring and a gate electrode of the amplification transistor.
   (16)

The solid-state imaging device according to (15),
wherein the second metal wiring is a power supply line to which a power supply voltage is applied.
   (17)

The solid-state imaging device according to (15),
wherein the second metal wiring is connected to a gate electrode of the reset transistor.
   (18)

The solid-state imaging device according to any one of (15) to (17),
wherein the shield electrode is further disposed at at least a part between the charge accumulation unit and the second metal wiring.
   (19)

The solid-state imaging device according to any one of (15) to (18),
wherein the shield electrode is connected to a well of the second substrate.
   (20)

An electronic device including:
the solid-state imaging device according to any one of (15) to (19); and
a processor that processes an image signal output from the solid-state imaging device.

### REFERENCE SIGNS LIST

1 ELECTRONIC DEVICE
10 SOLID-STATE IMAGING DEVICE
11 IMAGING LENS
13 PROCESSOR
14 STORAGE UNIT
21 PIXEL ARRAY UNIT
22 VERTICAL DRIVE CIRCUIT
23 COLUMN PROCESSING CIRCUIT
24 HORIZONTAL DRIVE CIRCUIT
25 SYSTEM CONTROLLING UNIT
26 SIGNAL PROCESSING UNIT
27 DATA STORAGE UNIT
30, 30a to 30h UNIT PIXEL
31, 31a to 31h TRANSFER TRANSISTOR
32 RESET TRANSISTOR
33 AMPLIFICATION TRANSISTOR
34 SELECTION TRANSISTOR
35 SWITCHING TRANSISTOR
41 LIGHT RECEIVING CHIP
42 CIRCUIT CHIP
51 ON-CHIP LENS
52 COLOR FILTER
53 FLATTENED FILM
54 LIGHT SHIELDING FILM
55, 63, 261 INSULATING FILM
56, 64 P-TYPE SEMICONDUCTOR REGION
57 LIGHT RECEIVING SURFACE
58, 101, 201 SEMICONDUCTOR SUBSTRATE
59 N-TYPE SEMICONDUCTOR REGION
60, 170 PIXEL ISOLATION PORTION
61 GROOVE PORTION
62 FIXED CHARGE FILM
66 WIRING
65 WIRING LAYER
67, 301 INSULATING LAYER
103, 105, 105a to 105d, 107, 109, 112a to 112h, 112al to 112d1, 112a2 to 112d2, 113a to 113d, 122, 123, 124, 132, 132a, 132b, 134, 134a to 134d, 135, 135a to 135d THROUGH ELECTRODE
104, 104a to 104d, 108, 204, 204a to 204d, 208 CONTACT PORTION
110, 110a to 110d, 210, 210a DIFFUSION REGION
111a to 111h, 111a1 to 111d1, 111a2 to 111d2 TRANSFER GATE ELECTRODE
121, 221, 221A, 221B RESET GATE ELECTRODE
131, 131A, 131B, 231 AMPLIFICATION GATE ELECTRODE
133, 160, 162, 163 WIRING
161, 233 EXTENDING PORTION
121a, 131b, 221a, 231a, 241a, 251a GATE INSULATING FILM
121b, 131b, 221b, 231b, 241b, 251b CHANNEL FORMATION REGION
205, 222, 222A, 222B, 223, 224, 232, 234, 242, 242A, 242B, 243, 252, 253 CONTACT PLUG
225, 226, 235 VIA HOLE
231c SIDEWALL
241, 241A, 241B SELECTION GATE ELECTRODE
251 SWITCHING GATE ELECTRODE
260 SHIELD ELECTRODE
265 INSULATING FILM REGION
410 FIRST SEMICONDUCTOR CHIP
420 SECOND SEMICONDUCTOR CHIP
C CAPACITOR
FD, FD1, FD2, FDa to FDd FLOATING DIFFUSION REGION
LD PIXEL DRIVE LINE
LD31 TRANSFER TRANSISTOR DRIVE LINE
LD32 RESET TRANSISTOR DRIVE LINE
LD34 SELECTION TRANSISTOR DRIVE LINE
M1 FIRST METAL WIRING
M2 SECOND METAL WIRING
PD, PDa to PDh PHOTOELECTRIC CONVERSION UNIT
VSL VERTICAL SIGNAL LINE

1. A solid-state imaging device including:
a first substrate including a photoelectric conversion unit that generates a charge by photoelectrically converting incident light;
a second substrate bonded to the first substrate and including at least a part of a pixel circuit that generates a voltage signal based on the charge generated at the photoelectric conversion unit; and
first metal wiring disposed on a side opposite to the first substrate with the second substrate sandwiched between the first substrate and the first metal wiring,
wherein the pixel circuit includes:
a charge accumulation unit that accumulates a charge generated at the photoelectric conversion unit;
an amplification transistor that converts the charge accumulated in the charge accumulation unit into a voltage of a voltage value in accordance with a charge amount of the charge;
a reset transistor that releases the charge accumulated in the charge accumulation unit;
a first through electrode that penetrates the second substrate from the first metal wiring to be connected to the charge accumulation unit; and
first wiring that connects a gate electrode of the amplification transistor with the first through electrode.

2. The solid-state imaging device according to claim 1,
wherein the first wiring is an extending portion extending from a gate electrode of the amplification transistor.

3. The solid-state imaging device according to claim 1,
wherein the pixel circuit further includes a second through electrode connected to a gate electrode of the amplification transistor, and
the first wiring connects the first through electrode with a second through electrode.

4. The solid-state imaging device according to claim 3,
wherein the amplification transistor is disposed on the first substrate.

5. The solid-state imaging device according to claim 1,
wherein the first wiring includes a part of the first metal wiring.

6. The solid-state imaging device according to claim 1,
wherein the pixel circuit further includes second wiring that connects a source of the reset transistor with the charge accumulation unit.

7. The solid-state imaging device according to claim 6,
wherein the second wiring includes a part of the first metal wiring.

8. The solid-state imaging device according to claim 6,
wherein the reset transistor is disposed on the second substrate, and
the second wiring is a second diffusion region continuous with a first diffusion region functioning as the source of the reset transistor.

9. The solid-state imaging device according to claim 6,
wherein the amplification transistor is disposed on the first substrate,
the pixel circuit further includes a second through electrode connected to a gate electrode of the amplification transistor, and
the second wiring includes the second through electrode and at least a part of the first wiring.

10. The solid-state imaging device according to claim 1,
wherein the first substrate includes a plurality of photoelectric conversion units, and
the plurality of photoelectric conversion units is connected to the charge accumulation unit.

11. The solid-state imaging device according to claim 10,
wherein the pixel circuit further includes:
the plurality of charge accumulation units; and
third wiring that connects the plurality of charge accumulation units.

12. The solid-state imaging device according to claim 11,
wherein the third wiring includes a part of the first metal wiring that connects first through electrodes connected to the plurality of charge accumulation units with each other.

13. The solid-state imaging device according to claim 11,
wherein the third wiring includes fourth wiring that is provided on the first substrate and that connects the first through electrodes connected to the plurality of charge accumulation units with each other.

14. An electronic device including:
the solid-state imaging device according to claim 1; and
a processor that processes an image signal output from the solid-state imaging device.

15. A solid-state imaging device including:
a photoelectric conversion unit that generates a charge by photoelectrically converting incident light; and
a pixel circuit that generates a voltage signal based on the charge generated at the photoelectric conversion unit,
wherein the photoelectric conversion unit is disposed on a first substrate,
at least a part of the pixel circuit is disposed on a second substrate bonded to the first substrate,
the pixel circuit includes:
a charge accumulation unit that accumulates a charge generated at the photoelectric conversion unit;
an amplification transistor that converts the charge accumulated in the charge accumulation unit into a voltage of a voltage value in accordance with a charge amount of the charge; and
a reset transistor that releases the charge accumulated in the charge accumulation unit,
the amplification transistor is disposed on the second substrate, and
the second substrate further includes:
second metal wiring disposed on a side opposite to the first substrate with the second substrate sandwiched between the first substrate and the second metal wiring; and
a shield electrode disposed at at least a part between the second metal wiring and a gate electrode of the amplification transistor.

16. The solid-state imaging device according to claim 15,
wherein the second metal wiring is a power supply line to which a power supply voltage is applied.

17. The solid-state imaging device according to claim 15,
wherein the second metal wiring is connected to a gate electrode of the reset transistor.

18. The solid-state imaging device according to claim 15,
wherein the shield electrode is further disposed at at least a part between the charge accumulation unit and the second metal wiring.

19. The solid-state imaging device according to claim 15,
wherein the shield electrode is connected to a well of the second substrate.

20. An electronic device including:
the solid-state imaging device according to claim 15; and
a processor that processes an image signal output from the solid-state imaging device.
